(19) United States
(12) Patent Application Publication
(10) Pub. No.: US 2026/0339784 A1
(43) Pub. Date: Oct. 29, 2026

(54) Multi-Dimensional Failure Protection In A Storage System

(71) Applicant: EVERPURE, INC., SANTA CLARA, CA (US)

(72) Inventors: PETER KIRKPATRICK, LOS ALTOS, CA (US); RONALD KARR, PALO ALTO, CA (US); JOHN COLGROVE, LOS ALTOS, CA (US); GORDON JAMES COLEMAN, LOS ALTOS, CA (US)

(21) Appl. No.: 19/728,009

(22) Filed: Jul. 1, 2026

Related U.S. Application Data
(63) Continuation-in-part of application No. 18/951,383, filed on Nov. 18, 2024.
Application No. 18/951,383 is a continuation-in-part of application No. 18/828,376, filed on Sep. 9, 2024, now abandoned.
Application No. 18/828,376 is a continuation of application No. 18/350,629, filed on Jul. 11, 2023, now Pat. No. 12,086,029.
Application No. 18/350,629 is a continuation of application No. 17/403,631, filed on Aug. 16, 2021, now Pat. No. 11,714,708.
Application No. 17/403,631 is a continuation of application No. 16/553,387, filed on Aug. 28, 2019, now Pat. No. 11,093,324.
Application No. 16/553,387 is a continuation of application No. 15/665,128, filed on Jul. 31, 2017, now Pat. No. 10,402,266.

(51) Int. Cl. G06F 11/10; G11C 29/52

(52) U.S. Cl. CPC G06F 11/1068; G11C 29/52

(57) ABSTRACT

Systems and methods for multi-dimensional failure protection include receiving units of data to be stored at a storage system; writing the units of data across a plurality of zones in the storage system; generating first parity data based on the units of data in a first dimension across the plurality of zones; and generating second parity data in a second dimension within the plurality of zones based at least in part on the units of data and one or more additional units of data in the plurality of zones.

### CROSS REFERENCE TO RELATED APPLICATIONS

This is a continuation in-part application for patent entitled to a filing date and claiming benefit of earlier-filed U.S. Patent Application No. 18/951,383, filed Nov. 18, 2024, which is a continuation in-part of U.S. Patent Application No. 18/828,376, filed Sept. 9, 2024, which is a continuation of U.S. Patent Application No. 18/350,629, filed Jul. 11, 2023, now U.S. Patent No. 12,086,029, issued on Sept. 10, 2024, which is a continuation of U.S. Patent Application No. 17/403,631, filed Aug. 16, 2021, now U.S. Patent No. 11,714,708, issued on Aug. 1, 2023, which is a continuation of U.S. Patent Application No. 16/553,387, filed Aug. 28, 2019, now U.S. Patent No. 11,093,324, issued Aug. 17, 2021, which is a continuation of U.S. Patent Application No. 15/665,128, filed Jul. 31, 2017, now U.S. Patent No. 10,402,266, issued Sept. 3, 2019, all of which are hereby incorporated herein by reference in their entirety.

### BACKGROUND

Storage systems, such as enterprise storage systems, may include a centralized or de-centralized repository for data that provides common data management, data protection, and data sharing functions, for example, through connections to computer systems.

### BRIEF DESCRIPTION OF THE DRAWINGS

The present disclosure is illustrated by way of example, and not by way of limitation, and can be more fully understood with reference to the following detailed description when considered in connection with the figures as described below.

FIG. 1A illustrates a first example system for data storage.

FIG. 1B illustrates a second example system for data storage.

FIG. 1C illustrates a third example system for data storage.

FIG. 1D illustrates a fourth example system for data storage.

FIG. 2A is a perspective view of a storage cluster with multiple storage nodes and internal storage coupled to each storage node to provide network attached storage.

FIG. 2B is a block diagram showing an interconnect switch coupling multiple storage nodes in accordance with some embodiments.

FIG. 2C is a multiple level block diagram, showing contents of a storage node and contents of one of the non-volatile solid state storage units.

FIG. 2D shows a storage server environment, which uses embodiments of the storage nodes and storage units of some previous figures in accordance with some embodiments.

FIG. 2E is a blade hardware block diagram, showing a control plane, compute and storage planes, and authorities interacting with underlying physical resources.

FIG. 2F depicts elasticity software layers in blades of a storage cluster.

FIG. 2G depicts authorities and storage resources in blades of a storage cluster.

FIG. 3A sets forth a diagram of a storage system that is coupled for data communications with a cloud services provider in accordance with some embodiments of the present disclosure.

FIG. 3B sets forth a diagram of a storage system.

FIG. 3C sets forth an example of a cloud-based storage system.

FIG. 3D illustrates an exemplary computing device that may be specifically configured to perform one or more of the processes described herein.

FIG. 3E illustrates an example of a fleet of storage systems for providing storage services (also referred to herein as ‘data services’).

FIG. 3F illustrates an example of a container system.

FIG. 3G illustrates an example of a storage node for a large-scale storage platform, in accordance with embodiments of the disclosure.

FIG. 4 illustrates an example system for RAID in a direct-mapped storage system, in accordance with some implementations.

FIG. 5 illustrates an example system for RAID in a direct-mapped storage system, in accordance with some implementations.

FIG. 6 illustrates an example storage device layout, in accordance with some implementations.

FIG. 7 illustrates a flow diagram for RAID in a direct-mapped storage system, in accordance with some implementations.

FIG. 8 is an illustration of an example of a storage device of a storage system storing data shards of a data segment and intra-device parity data, in accordance with embodiments of the disclosure.

FIG. 9 is an example method to utilize intra-device recovery data to protect against latent errors in accordance with embodiments of the disclosure.

FIG. 10 illustrates a storage system configured to perform delayed fault protection, zone-based fault protection, and multi-dimensional parity operations, in accordance with embodiments of the disclosure.

FIG. 11 illustrates a storage system controller configured to delay fault protection and subsequently group data units for parity generation, in accordance with embodiments of the disclosure.

FIGS. 12A and 12B illustrate examples of delayed fault protection, including formation of fault protection groups and regrouping in response to invalidation of data units, in accordance with embodiments of the disclosure.

FIG. 13 illustrates a storage system controller configured to group zones indicated as full into protected zone sets and generate parity data, in accordance with embodiments of the disclosure.

FIG. 14 illustrates an example of protected zone sets, including grouping of zones indicated as full and storage of parity data in separate parity zones, in accordance with embodiments of the disclosure.

FIG. 15 illustrates a storage system configured to perform multi-dimensional fault protection using parity groupings across zones and within zones, in accordance with embodiments of the disclosure.

FIG. 16 illustrates a method of delaying fault protection and subsequently applying fault protection to data units, in accordance with embodiments of the disclosure.

FIG. 17 illustrates a method of regrouping data units and reapplying fault protection based on expiration of prior fault protection, in accordance with embodiments of the disclosure.

FIG. 18 illustrates a method of generating parity data for zones indicated as full and storing the parity data in a separate parity zone, in accordance with embodiments of the disclosure.

FIG. 19 illustrates a method of regrouping zones and generating new parity data prior to reset, reclamation, or reuse operations affecting zones, in accordance with embodiments of the disclosure.

FIG. 20 illustrates a method of generating parity data in multiple dimensions across zones and within zones, in accordance with embodiments of the disclosure.

FIG. 21 illustrates a method of grouping data units into multiple groups corresponding to different dimensions and generating parity data for each group, in accordance with embodiments of the disclosure.

FIG. 22 illustrates a method of performing multi-dimensional fault protection with overflow erase blocks shared among zones, in accordance with embodiments of the disclosure.

### DETAILED DESCRIPTION

To protect against data loss, storage devices may include error detection and correction mechanisms. Often these mechanisms take the form of error correcting codes which are generated by the devices and stored within the devices themselves. In addition, distributed storage systems may also utilize decentralized algorithms to distribute data among a collection of storage devices. However, the difficult task remains of distributing data among multiple storage devices with varying capacities, input/output (I/O) characteristics and reliability issues.

Conventional hard drives (HDD) differ from solid state drives (SSD) in various aspects relating to protection against data loss. An SSD may emulate a HDD interface, but a SSD utilizes solid-state memory to store persistent data rather than the electromechanical devices found in a HDD. For example, an SSD may include banks of Flash memory. Without moving parts or mechanical delays, an SSD may have a lower access time and latency than a HDD. However, SSD typically have significant write latencies. In addition to different input/output (I/O) characteristics, an SSD experiences different failure modes than a HDD. Accordingly, high performance and high reliability may not be achieved in systems comprising SSDs for storage while utilizing distributed data placement algorithms developed for HDDs.

To resolve the above deficiencies, in one implementation, processing logic may determine that data is to be written across a direct-mapped storage system that includes a plurality of flash storage devices. A plurality of available allocation units across the plurality of flash storage devices may be selected as the allocation units to where the data will be written. The plurality of allocation units may be dynamically associated together in a stripe, so that any future lost data may be recovered in view of the association. The processing logic then writes the data to a first subset of the allocation units. When data is modified and is to be rewritten, stripes are not written back into their original location. Instead, a new set of allocation units is selected and the data is written to the new stripe. Advantageously, this allows new parities to be created instead of reading each of the existing allocation units in the stripe to recalculate what the new parity should be. The data that is written to the first set of allocation units includes verification signatures (checksums) corresponding to the data. Using the verification data, processing logic can determine if any data has been lost or corrupted.

Erasure codes (e.g., parity bits ‘P’ and ‘Q’) corresponding to the data written to the first subset of allocation units may then be calculated and written to a second subset of allocation units. Parity bits may also be written to the allocation unit itself. Advantageously, this allows for the recovery of a bad block inside of an allocation unit from the internal parity, instead of relying on a parity stored on a second drive. Storing the erasure codes ensures that data lost on one or two drives is recoverable. In the case that an allocation unit fails or is corrupted, the failure or corruption is detected by comparing data in the allocation unit with the verification signatures (checksums). In response to the data being lost or corrupted, the data may be recovered from the corresponding allocation unit based on the data written to the first subset of allocation units (the other, healthy data) and the erasure codes.

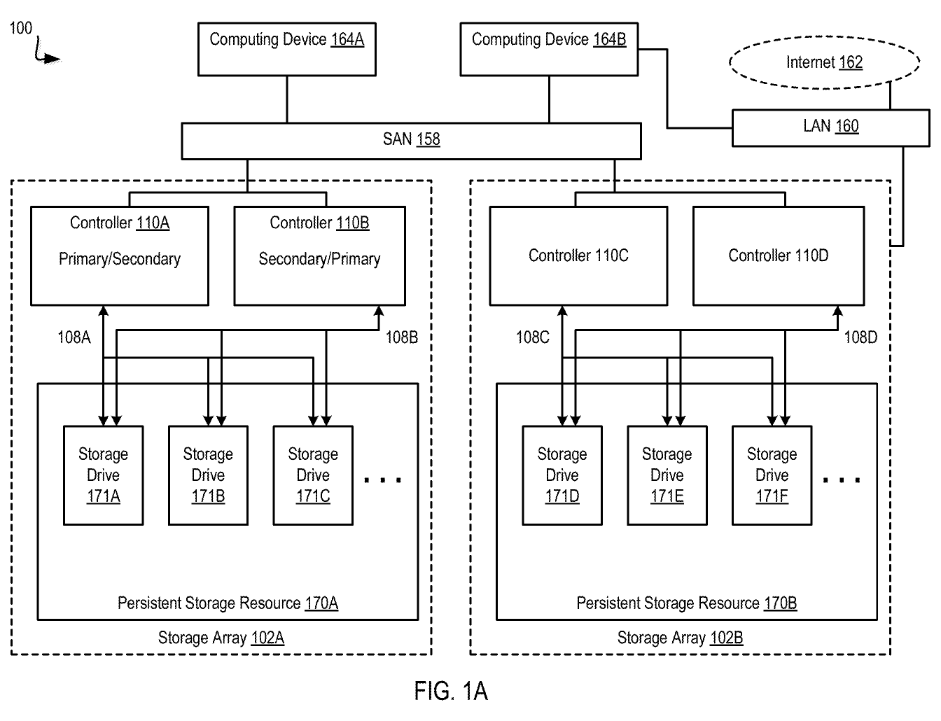

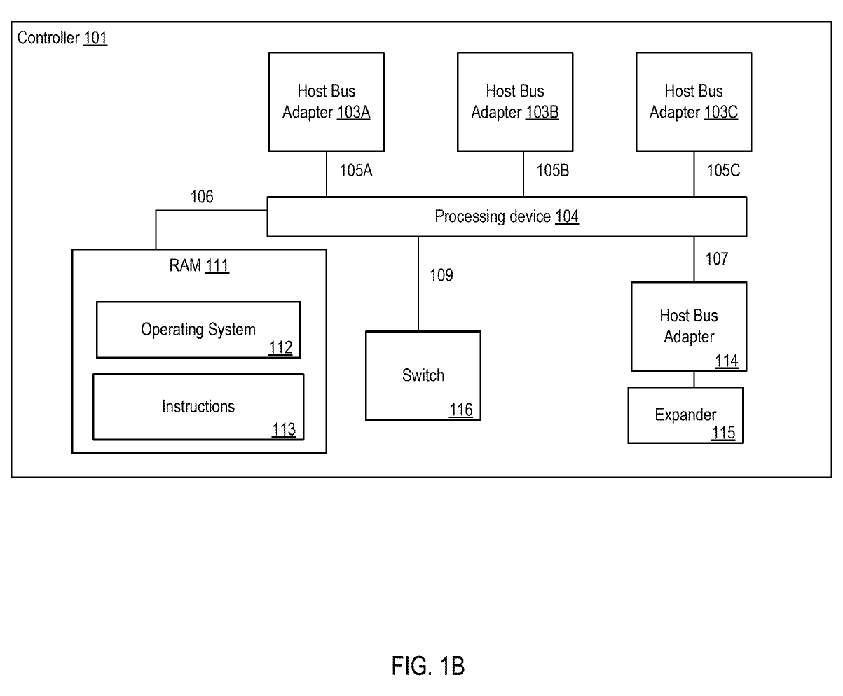

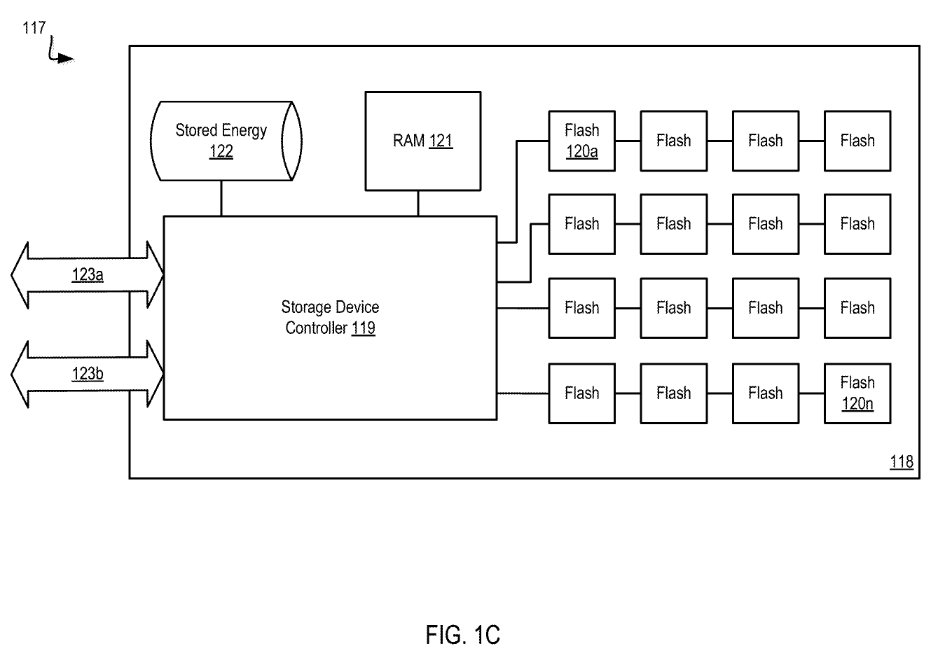

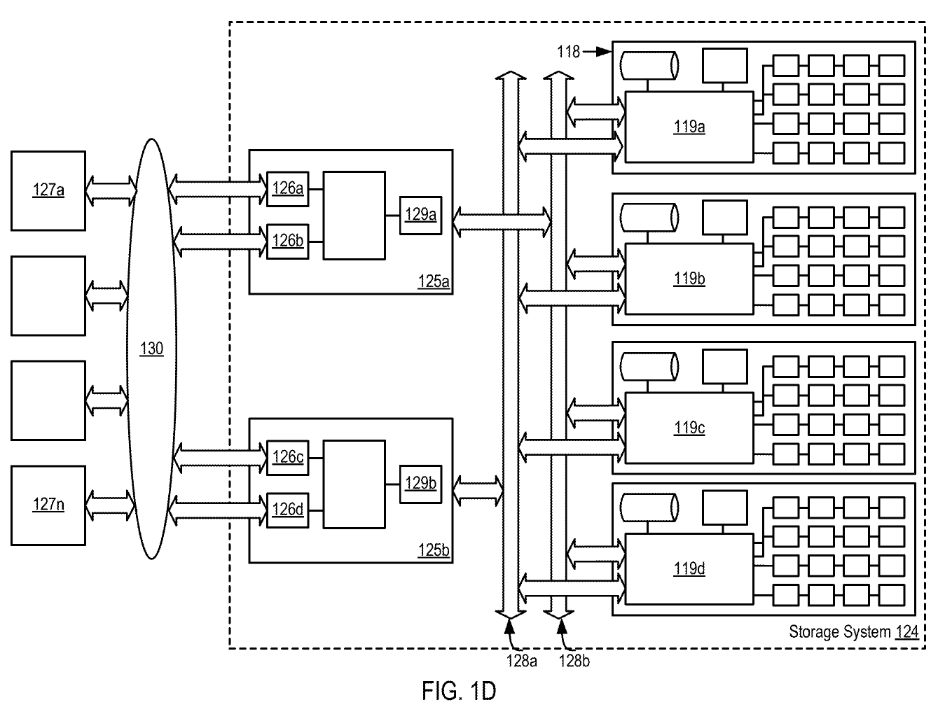

FIG. 1A illustrates an example system for data storage, in accordance with some implementations. System 100 (also referred to as “storage system” herein) includes numerous elements for purposes of illustration rather than limitation. It may be noted that system 100 may include the same, more, or fewer elements configured in the same or different manner in other implementations.

System 100 includes a number of computing devices 164A-B. Computing devices (also referred to as "client devices" herein) may be embodied, for example, a server in a data center, a workstation, a personal computer, a notebook, or the like. Computing devices 164A-B may be coupled for data communications to one or more storage arrays 102A-B through a storage area network ('SAN') 158 or a local area network ('LAN') 160.

The SAN 158 may be implemented with a variety of data communications fabrics, devices, and protocols. For example, the fabrics for SAN 158 may include Fibre Channel, Ethernet, Infiniband, Serial Attached Small Computer System Interface ('SAS'), or the like. Data communications protocols for use with SAN 158 may include Advanced Technology Attachment ('ATA'), Fibre Channel Protocol, Small Computer System Interface ('SCSI'), Internet Small Computer System Interface ('iSCSI'), HyperSCSI, Non-Volatile Memory Express ('NVMe') over Fabrics, or the like. It may be noted that SAN 158 is provided for illustration, rather than limitation. Other data communication couplings may be implemented between computing devices 164A-B and storage arrays 102A-B.

The LAN 160 may also be implemented with a variety of fabrics, devices, and protocols. For example, the fabrics for LAN 160 may include Ethernet (802.3), wireless (802.11), or the like. Data communication protocols for use in LAN 160 may include Transmission Control Protocol ('TCP'), User Datagram Protocol ('UDP'), Internet Protocol ('IP'), HyperText Transfer Protocol ('HTTP'), Wireless Access Protocol ('WAP'), Handheld Device Transport Protocol ('HDTP'), Session Initiation Protocol ('SIP'), Real Time Protocol ('RTP'), or the like. The LAN 160 may also connect to the Internet 162.

Storage arrays 102A-B may provide persistent data storage for the computing devices 164A-B. Storage array 102A may be contained in a chassis (not shown), and storage array 102B may be contained in another chassis (not shown), in some implementations. Storage array 102A and 102B may include one or more storage array controllers 110A-D (also referred to as "controller" herein). A storage array controller 110A-D may be embodied as a module of automated computing machinery comprising computer hardware, computer software, or a combination of computer hardware and software. In some implementations, the storage array controllers 110A-D may be configured to carry out various storage tasks. Storage tasks may include writing data received from the computing devices 164A-B to storage array 102A-B, erasing data from storage array 102A-B, retrieving data from storage array 102A-B and providing data to computing devices 164A-B, monitoring and reporting of storage device utilization and performance, performing redundancy operations, such as Redundant Array of Independent Drives ('RAID') or RAID-like data redundancy operations, compressing data, encrypting data, and so forth.

Storage array controller 110A-D may be implemented in a variety of ways, including as a Field Programmable Gate Array ('FPGA'), a Programmable Logic Chip ('PLC'), an Application Specific Integrated Circuit ('ASIC'), System-on-Chip ('SOC'), or any computing device that includes discrete components such as a processing device, central processing unit, computer memory, or various adapters. Storage array controller 110A-D may include, for example, a data communications adapter configured to support communications via the SAN 158 or LAN 160. In some implementations, storage array controller 110A-D may be independently coupled to the LAN 160. In some implementations, storage array controller 110A-D may include an I/O controller or the like that couples the storage array controller 110A-D for data communications, through a midplane (not shown), to a persistent storage resource 170A-B (also referred to as a "storage resource" herein). The persistent storage resource 170A-B may include any number of storage drives 171A-F (also referred to as "storage devices" herein) and any number of non-volatile Random Access Memory ('NVRAM') devices (not shown).

In some embodiments, one or more of the storage drives 171A-F may be managed flash storage devices. A managed flash storage device (which may also be referred to as directly managed flash storage device, directly managed storage device, managed storage device, etc.) may provide functions, operations, commands, APIs or some other appropriate mechanism for an external device, such as a processing device of a storage array controller (e.g., storage array controller 110A-D) to control, manage, and/or interact with the flash memory of the managed flash storage device. This may leave a storage device controller with fewer operations to perform (e.g., handling queues, bust transfers, internal error correction, encryption, voltage level adjusts for lines/pages of flash, etc.). Because the storage devices may be directly managed, this allows the storage system to optimize, manage, and/or improve various aspects, characteristics, etc., of the flash memory to improve performance, reliability, and/or lifespan of the flash memory, as discussed in more detail below.

In some implementations, the NVRAM devices of a persistent storage resource 170A-B may be configured to receive, from the storage array controller 110A-D, data to be stored in the storage drives 171A-F. In some examples, the data may originate from computing devices 164A-B. In some examples, writing data to the NVRAM device may be carried out more quickly than directly writing data to the storage drive 171A-F. In some implementations, the storage array controller 110A-D may be configured to utilize the NVRAM devices as a quickly accessible buffer for data destined to be written to the storage drives 171A-F. Latency for write requests using NVRAM devices as a buffer may be improved relative to a system in which a storage array controller 110A-D writes data directly to the storage drives 171A-F. In some implementations, the NVRAM devices may be implemented with computer memory in the form of high bandwidth, low latency RAM. The NVRAM device is referred to as "non-volatile" because the NVRAM device may receive or include a unique power source that maintains the state of the RAM after main power loss to the NVRAM device. Such a power source may be a battery, one or more capacitors, or the like. In response to a power loss, the NVRAM device may be configured to write the contents of the RAM to a persistent storage, such as the storage drives 171A-F.

In some implementations, storage drive 171A-F may refer to any device configured to record data persistently, where "persistently" or "persistent" refers as to a device's ability to maintain recorded data after loss of power. In some implementations, storage drive 171A-F may correspond to non-disk storage media. For example, the storage drive 171A-F may be one or more solid-state drives ('SSDs'), flash memory based storage, any type of solid-state non-volatile memory, or any other type of non-mechanical storage device. In other implementations, storage drive 171A-F may include mechanical or spinning hard disk, such as hard-disk drives ('HDD').

In some implementations, the storage array controllers 110A-D may be configured for offloading device management responsibilities from storage drive 171A-F in storage array 102A-B. For example, storage array controllers 110A-D may manage control information that may describe the state of one or more memory blocks in the storage drives 171A-F. The control information may indicate, for example, that a particular memory block has failed and should no longer be written to, that a particular memory block contains boot code for a storage array controller 110A-D, the number of program-erase ('P/E') cycles that have been performed on a particular memory block, the age of data stored in a particular memory block, the type of data that is stored in a particular memory block, and so forth. In some implementations, the control information may be stored with an associated memory block as metadata. In other implementations, the control information for the storage drives 171A-F may be stored in one or more particular memory blocks of the storage drives 171A-F that are selected by the storage array controller 110A-D. The selected memory blocks may be tagged with an identifier indicating that the selected memory block contains control information. The identifier may be utilized by the storage array controllers 110A-D in conjunction with storage drives 171A-F to quickly identify the memory blocks that contain control information. For example, the storage controllers 110A-D may issue a command to locate memory blocks that contain control information. It may be noted that control information may be so large that parts of the control information may be stored in multiple locations, that the control information may be stored in multiple locations for purposes of redundancy, for example, or that the control information may otherwise be distributed across multiple memory blocks in the storage drives 171A-F.

In some implementations, storage array controllers 110A-D may offload device management responsibilities from storage drives 171A-F of storage array 102A-B by retrieving, from the storage drives 171A-F, control information describing the state of one or more memory blocks in the storage drives 171A-F. Retrieving the control information from the storage drives 171A-F may be carried out, for example, by the storage array controller 110A-D querying the storage drives 171A-F for the location of control information for a particular storage drive 171A-F. The storage drives 171A-F may be configured to execute instructions that enable the storage drives 171A-F to identify the location of the control information. The instructions may be executed by a controller (not shown) associated with or otherwise located on the storage drive 171A-F and may cause the storage drive 171A-F to scan a portion of each memory block to identify the memory blocks that store control information for the storage drives 171A-F. The storage drives 171A-F may respond by sending a response message to the storage array controller 110A-D that includes the location of control information for the storage drive 171A-F. Responsive to receiving the response message, storage array controllers 110A-D may issue a request to read data stored at the address associated with the location of control information for the storage drives 171A-F.

In other implementations, the storage array controllers 110A-D may further offload device management responsibilities from storage drives 171A-F by performing, in response to receiving the control information, a storage drive management operation. A storage drive management operation may include, for example, an operation that is typically performed by the storage drive 171A-F (e.g., the controller (not shown) associated with a particular storage drive 171A-F). A storage drive management operation may include, for example, ensuring that data is not written to failed memory blocks within the storage drive 171A-F, ensuring that data is written to memory blocks within the storage drive 171A-F in such a way that adequate wear leveling is achieved, and so forth.

In some implementations, storage array 102A-B may implement two or more storage array controllers 110A-D. For example, storage array 102A may include storage array controllers 110A and storage array controllers 110B. At a given instant, a single storage array controller 110A-D (e.g., storage array controller 110A) of a storage system 100 may be designated with primary status (also referred to as "primary controller" herein), and other storage array controllers 110A-D (e.g., storage array controller 110B) may be designated with secondary status (also referred to as "secondary controller" herein). The primary controller may have particular rights, such as permission to alter data in persistent storage resource 170A-B (e.g., writing data to persistent storage resource 170A-B). At least some of the rights of the primary controller may supersede the rights of the secondary controller. For instance, the secondary controller may not have permission to alter data in persistent storage resource 170A-B when the primary controller has the right. The status of storage array controllers 110A-D may change. For example, storage array controller 110A may be designated with secondary status, and storage array controller 110B may be designated with primary status.

In some implementations, a primary controller, such as storage array controller 110A, may serve as the primary controller for one or more storage arrays 102A-B, and a second controller, such as storage array controller 110B, may serve as the secondary controller for the one or more storage arrays 102A-B. For example, storage array controller 110A may be the primary controller for storage array 102A and storage array 102B, and storage array controller 110B may be the secondary controller for storage array 102A and 102B. In some implementations, storage array controllers 110C and 110D (also referred to as "storage processing modules") may neither have primary or secondary status. Storage array controllers 110C and 110D, implemented as storage processing modules, may act as a communication interface between the primary and secondary controllers (e.g., storage array controllers 110A and 110B, respectively) and storage array 102B. For example, storage array controller 110A of storage array 102A may send a write request, via SAN 158, to storage array 102B. The write request may be received by both storage array controllers 110C and 110D of storage array 102B. Storage array controllers 110C and 110D facilitate the communication, e.g., send the write request to the appropriate storage drive 171A-F. It may be noted that in some implementations storage processing modules may be used to increase the number of storage drives controlled by the primary and secondary controllers.

In some implementations, storage array controllers 110A-D are communicatively coupled, via a midplane (not shown), to one or more storage drives 171A-F and to one or more NVRAM devices (not shown) that are included as part of a storage array 102A-B. The storage array controllers 110A-D may be coupled to the midplane via one or more data communication links and the midplane may be coupled to the storage drives 171A-F and the NVRAM devices via one or more data communications links. The data communications links described herein are collectively illustrated by data communications links 108A-D and may include a Peripheral Component Interconnect Express ('PCIe') bus, for example.

FIG. 1B illustrates an example system for data storage, in accordance with some implementations. Storage array controller 101 illustrated in FIG. 1B may be similar to the storage array controllers 110A-D described with respect to FIG. 1A. In one example, storage array controller 101 may be similar to storage array controller 110A or storage array controller 110B. Storage array controller 101 includes numerous elements for purposes of illustration rather than limitation. It may be noted that storage array controller 101 may include the same, more, or fewer elements configured in the same or different manner in other implementations. It may be noted that elements of FIG. 1A may be included below to help illustrate features of storage array controller 101.

Storage array controller 101 may include one or more processing devices 104 and random access memory ('RAM') 111. Processing device 104 (or controller 101) represents one or more general-purpose processing devices such as a microprocessor, central processing unit, or the like. More particularly, the processing device 104 (or controller 101) may be a complex instruction set computing ('CISC') microprocessor, reduced instruction set computing ('RISC') microprocessor, very long instruction word ('VLIW') microprocessor, or a processor implementing other instruction sets or processors implementing a combination of instruction sets. The processing device 104 (or controller 101) may also be one or more special-purpose processing devices such as an ASIC, an FPGA, a digital signal processor ('DSP'), network processor, or the like.

The processing device 104 may be connected to the RAM 111 via a data communications link 106, which may be embodied as a high speed memory bus such as a Double-Data Rate 4 ('DDR4') bus. Stored in RAM 111 is an operating system 112. In some implementations, instructions 113 are stored in RAM 111. Instructions 113 may include computer program instructions for performing operations in a direct-mapped flash storage system. In one embodiment, a direct-mapped flash storage system is one that addresses data blocks within flash drives directly and without an address translation performed by the storage controllers of the flash drives.

In some implementations, storage array controller 101 includes one or more host bus adapters 103A-C that are coupled to the processing device 104 via a data communications link 105A-C. In some implementations, host bus adapters 103A-C may be computer hardware that connects a host system (e.g., the storage array controller) to other network and storage arrays. In some examples, host bus adapters 103A-C may be a Fibre Channel adapter that enables the storage array controller 101 to connect to a SAN, an Ethernet adapter that enables the storage array controller 101 to connect to a LAN, or the like. Host bus adapters 103A-C may be coupled to the processing device 104 via a data communications link 105A-C such as, for example, a PCIe bus.

In some implementations, storage array controller 101 may include a host bus adapter 114 that is coupled to an expander 115. The expander 115 may be used to attach a host system to a larger number of storage drives. The expander 115 may, for example, be a SAS expander utilized to enable the host bus adapter 114 to attach to storage drives in an implementation where the host bus adapter 114 is embodied as a SAS controller.

In some implementations, storage array controller 101 may include a switch 116 coupled to the processing device 104 via a data communications link 109. The switch 116 may be a computer hardware device that can create multiple endpoints out of a single endpoint, thereby enabling multiple devices to share a single endpoint. The switch 116 may, for example, be a PCIe switch that is coupled to a PCIe bus (e.g., data communications link 109) and presents multiple PCIe connection points to the midplane.

In some implementations, storage array controller 101 includes a data communications link 107 for coupling the storage array controller 101 to other storage array controllers. In some examples, data communications link 107 may be a QuickPath Interconnect (QPI) interconnect.

A traditional storage system that uses traditional flash drives may implement a process across the flash drives that are part of the traditional storage system. For example, a higher level process of the storage system may initiate and control a process across the flash drives. However, a flash drive of the traditional storage system may include its own storage controller that also performs the process. Thus, for the traditional storage system, a higher level process (e.g., initiated by the storage system) and a lower level process (e.g., initiated by a storage controller of the storage system) may both be performed.

To resolve various deficiencies of a traditional storage system, operations may be performed by higher level processes and not by the lower level processes. For example, the flash storage system may include flash drives that do not include storage controllers that provide the process. Thus, the operating system of the flash storage system itself may initiate and control the process. This may be accomplished by a direct-mapped flash storage system that addresses data blocks within the flash drives directly and without an address translation performed by the storage controllers of the flash drives.

In some implementations, storage drive 171A-F may be one or more zoned storage devices. In some implementations, the one or more zoned storage devices may be a shingled HDD. In some implementations, the one or more storage devices may be a flash-based SSD. In a zoned storage device, a zoned namespace on the zoned storage device can be addressed by groups of blocks that are grouped and aligned by a natural size, forming a number of addressable zones. In some implementations utilizing an SSD, the natural size may be based on the erase block size of the SSD. In some implementations, the zones of the zoned storage device may be defined during initialization of the zoned storage device. In some implementations, the zones may be defined dynamically as data is written to the zoned storage device.

In some implementations, zones may be heterogeneous, with some zones each being a page group and other zones being multiple page groups. In some implementations, some zones may correspond to an erase block and other zones may correspond to multiple erase blocks. In an implementation, zones may be any combination of differing numbers of pages in page groups and/or erase blocks, for heterogeneous mixes of programming modes, manufacturers, product types and/or product generations of storage devices, as applied to heterogeneous assemblies, upgrades, distributed storages, etc. In some implementations, zones may be defined as having usage characteristics, such as a property of supporting data with particular kinds of longevity (very short lived or very long lived, for example). These properties could be used by a zoned storage device to determine how the zone will be managed over the zone’s expected lifetime.

It should be appreciated that a zone is a virtual construct. Any particular zone may not have a fixed location at a storage device. Until allocated, a zone may not have any location at a storage device. A zone may correspond to a number representing a chunk of virtually allocatable space that is the size of an erase block or other block size in various implementations. When the system allocates or opens a zone, zones get allocated to flash or other solid-state storage memory and, as the system writes to the zone, pages are written to that mapped flash or other solid-state storage memory of the zoned storage device. When the system closes the zone, the associated erase block(s) or other sized block(s) are completed. At some point in the future, the system may delete a zone which will free up the zone's allocated space. During its lifetime, a zone may be moved around to different locations of the zoned storage device, e.g., as the zoned storage device does internal maintenance.

In some implementations, the zones of the zoned storage device may be in different states. A zone may be in an empty state in which data has not been stored at the zone. An empty zone may be opened explicitly, or implicitly by writing data to the zone. This is the initial state for zones on a fresh zoned storage device, but may also be the result of a zone reset. In some implementations, an empty zone may have a designated location within the flash memory of the zoned storage device. In an implementation, the location of the empty zone may be chosen when the zone is first opened or first written to (or later if writes are buffered into memory). A zone may be in an open state either implicitly or explicitly, where a zone that is in an open state may be written to store data with write or append commands. In an implementation, a zone that is in an open state may also be written to using a copy command that copies data from a different zone. In some implementations, a zoned storage device may have a limit on the number of open zones at a particular time.

A zone in a closed state is a zone that has been partially written to, but has entered a closed state after issuing an explicit close operation. A zone in a closed state may be left available for future writes, but may reduce some of the run-time overhead consumed by keeping the zone in an open state. In some implementations, a zoned storage device may have a limit on the number of closed zones at a particular time. A zone in a full state is a zone that is storing data and can no longer be written to. A zone may be in a full state either after writes have written data to the entirety of the zone or as a result of a zone finish operation. Prior to a finish operation, a zone may or may not have been completely written. After a finish operation, however, the zone may not be opened a written to further without first performing a zone reset operation.

The mapping from a zone to an erase block (or to a shingled track in an HDD) may be arbitrary, dynamic, and hidden from view. The process of opening a zone may be an operation that allows a new zone to be dynamically mapped to underlying storage of the zoned storage device, and then allows data to be written through appending writes into the zone until the zone reaches capacity. The zone can be finished at any point, after which further data may not be written into the zone. When the data stored at the zone is no longer needed, the zone can be reset which effectively deletes the zone's content from the zoned storage device, making the physical storage held by that zone available for the subsequent storage of data. Once a zone has been written and finished, the zoned storage device ensures that the data stored at the zone is not lost until the zone is reset. In the time between writing the data to the zone and the resetting of the zone, the zone may be moved around between shingle tracks or erase blocks as part of maintenance operations within the zoned storage device, such as by copying data to keep the data refreshed or to handle memory cell aging in an SSD.

In some implementations utilizing an HDD, the resetting of the zone may allow the shingle tracks to be allocated to a new, opened zone that may be opened at some point in the future. In some implementations utilizing an SSD, the resetting of the zone may cause the associated physical erase block(s) of the zone to be erased and subsequently reused for the storage of data. In some implementations, the zoned storage device may have a limit on the number of open zones at a point in time to reduce the amount of overhead dedicated to keeping zones open.

The operating system of the flash storage system may identify and maintain a list of allocation units across multiple flash drives of the flash storage system. The allocation units may be entire erase blocks or multiple erase blocks. The operating system may maintain a map or address range that directly maps addresses to erase blocks of the flash drives of the flash storage system.

Direct mapping to the erase blocks of the flash drives may be used to rewrite data and erase data. For example, the operations may be performed on one or more allocation units that include a first data and a second data where the first data is to be retained and the second data is no longer being used by the flash storage system. The operating system may initiate the process to write the first data to new locations within other allocation units and erasing the second data and marking the allocation units as being available for use for subsequent data. Thus, the process may only be performed by the higher level operating system of the flash storage system without an additional lower level process being performed by controllers of the flash drives.

Advantages of the process being performed only by the operating system of the flash storage system include increased reliability of the flash drives of the flash storage system as unnecessary or redundant write operations are not being performed during the process. One possible point of novelty here is the concept of initiating and controlling the process at the operating system of the flash storage system. In addition, the process can be controlled by the operating system across multiple flash drives. This is in contrast to the process being performed by a storage controller of a flash drive.

A storage system can consist of two storage array controllers that share a set of drives for failover purposes, or it could consist of a single storage array controller that provides a storage service that utilizes multiple drives, or it could consist of a distributed network of storage array controllers each with some number of drives or some amount of Flash storage where the storage array controllers in the network collaborate to provide a complete storage service and collaborate on various aspects of a storage service including storage allocation and garbage collection.

FIG. 1C illustrates a third example system 117 for data storage in accordance with some implementations. System 117 (also referred to as "storage system" herein) includes numerous elements for purposes of illustration rather than limitation. It may be noted that system 117 may include the same, more, or fewer elements configured in the same or different manner in other implementations.

In one embodiment, system 117 includes a dual Peripheral Component Interconnect ('PCI') flash storage device 118 with separately addressable fast write storage. System 117 may include a storage device controller 119. In one embodiment, storage device controller 119A-D may be a CPU, ASIC, FPGA, or any other circuitry that may implement control structures necessary according to the present disclosure. In one embodiment, system 117 includes flash memory devices (e.g., including flash memory devices 120a-n), operatively coupled to various channels of the storage device controller 119. Flash memory devices 120a-n may be presented to the controller 119A-D as an addressable collection of Flash pages, erase blocks, and/or control elements sufficient to allow the storage device controller 119A-D to program and retrieve various aspects of the Flash. In one embodiment, storage device controller 119A-D may perform operations on flash memory devices 120a-n including storing and retrieving data content of pages, arranging and erasing any blocks, tracking statistics related to the use and reuse of Flash memory pages, erase blocks, and cells, tracking and predicting error codes and faults within the Flash memory, controlling voltage levels associated with programming and retrieving contents of Flash cells, etc.

In one embodiment, system 117 may include RAM 121 to store separately addressable fast-write data. In one embodiment, RAM 121 may be one or more separate discrete devices. In another embodiment, RAM 121 may be integrated into storage device controller 119A-D or multiple storage device controllers. The RAM 121 may be utilized for other purposes as well, such as temporary program memory for a processing device (e.g., a CPU) in the storage device controller 119.

In one embodiment, system 117 may include a stored energy device 122, such as a rechargeable battery or a capacitor. Stored energy device 122 may store energy sufficient to power the storage device controller 119, some amount of the RAM (e.g., RAM 121), and some amount of Flash memory (e.g., Flash memory 120a-120n) for sufficient time to write the contents of RAM to Flash memory. In one embodiment, storage device controller 119A-D may write the contents of RAM to Flash Memory if the storage device controller detects loss of external power.

In one embodiment, system 117 includes two data communications links 123a, 123b. In one embodiment, data communications links 123a, 123b may be PCI interfaces. In another embodiment, data communications links 123a, 123b may be based on other communications standards (e.g., HyperTransport, InfiniBand, etc.). Data communications links 123a, 123b may be based on non-volatile memory express ('NVMe') or NVMe over fabrics ('NVMf') specifications that allow external connection to the storage device controller 119A-D from other components in the storage system 117. It should be noted that data communications links may be interchangeably referred to herein as PCI buses for convenience.

System 117 may also include an external power source (not shown), which may be provided over one or both data communications links 123a, 123b, or which may be provided separately. An alternative embodiment includes a separate Flash memory (not shown) dedicated for use in storing the content of RAM 121. The storage device controller 119A-D may present a logical device over a PCI bus which may include an addressable fast-write logical device, or a distinct part of the logical address space of the storage device 118, which may be presented as PCI memory or as persistent storage. In one embodiment, operations to store into the device are directed into the RAM 121. On power failure, the storage device controller 119A-D may write stored content associated with the addressable fast-write logical storage to Flash memory (e.g., Flash memory 120a-n) for long-term persistent storage.

In one embodiment, the logical device may include some presentation of some or all of the content of the Flash memory devices 120a-n, where that presentation allows a storage system including a storage device 118 (e.g., storage system 117) to directly address Flash memory pages and directly reprogram erase blocks from storage system components that are external to the storage device through the PCI bus. The presentation may also allow one or more of the external components to control and retrieve other aspects of the Flash memory including some or all of: tracking statistics related to use and reuse of Flash memory pages, erase blocks, and cells across all the Flash memory devices; tracking and predicting error codes and faults within and across the Flash memory devices; controlling voltage levels associated with programming and retrieving contents of Flash cells; etc.

In one embodiment, the stored energy device 122 may be sufficient to ensure completion of in-progress operations to the Flash memory devices 120a-120n. The stored energy device 122 may power storage device controller 119A-D and associated Flash memory devices (e.g., 120a-n) for those operations, as well as for the storing of fast-write RAM to Flash memory. Stored energy device 122 may be used to store accumulated statistics and other parameters kept and tracked by the Flash memory devices 120a-n and/or the storage device controller 119. Separate capacitors or stored energy devices (such as smaller capacitors near or embedded within the Flash memory devices themselves) may be used for some or all of the operations described herein.

Various schemes may be used to track and optimize the life span of the stored energy component, such as adjusting voltage levels over time, partially discharging the stored energy device 122 to measure corresponding discharge characteristics, etc. If the available energy decreases over time, the effective available capacity of the addressable fast-write storage may be decreased to ensure that it can be written safely based on the currently available stored energy.

FIG. 1D illustrates a third example storage system 124 for data storage in accordance with some implementations. In one embodiment, storage system 124 includes storage controllers 125a, 125b. In one embodiment, storage controllers 125a, 125b are operatively coupled to Dual PCI storage devices. Storage controllers 125a, 125b may be operatively coupled (e.g., via a storage network 130) to some number of host computers 127a-n.

In one embodiment, two storage controllers (e.g., 125a, and 125b) provide storage services, such as a SCS block storage array, a file server, an object server, a database or data analytics service, etc. The storage controllers 1125a, 125b may provide services through some number of network interfaces (e.g., 126a-d) to host computers 127a-n outside of the storage system 124. Storage controllers 125a, 125b may provide integrated services or an application entirely within the storage system 124, forming a converged storage and compute system. The storage controllers 125a, 125b may utilize the fast write memory within or across storage devices 119a-d to journal in progress operations to ensure the operations are not lost on a power failure, storage controller removal, storage controller or storage system shutdown, or some fault of one or more software or hardware components within the storage system 124.

In one embodiment, storage controllers 125a, 125b operate as PCI masters to one or the other PCI buses 128a, 128b. In another embodiment, 128a and 128b may be based on other communications standards (e.g., HyperTransport, InfiniBand, etc.). Other storage system embodiments may operate storage controllers 125a, 125b as multi-masters for both PCI buses 128a, 128b. Alternately, a PCI/NVMe/NVMf switching infrastructure or fabric may connect multiple storage controllers. Some storage system embodiments may allow storage devices to communicate with each other directly rather than communicating only with storage controllers. In one embodiment, a storage device controller 119a may be operable under direction from a storage controller 125a to synthesize and transfer data to be stored into Flash memory devices from data that has been stored in RAM (e.g., RAM 121 of FIG. 1C). For example, a recalculated version of RAM content may be transferred after a storage controller has determined that an operation has fully committed across the storage system, or when fast-write memory on the device has reached a certain used capacity, or after a certain amount of time, to ensure improve safety of the data or to release addressable fast-write capacity for reuse. This mechanism may be used, for example, to avoid a second transfer over a bus (e.g., 128a, 128b) from the storage controllers 125a, 125b. In one embodiment, a recalculation may include compressing data, attaching indexing or other metadata, combining multiple data segments together, performing erasure code calculations, etc.

In one embodiment, under direction from a storage controller 125a, 125b, a storage device controller 119a, 119b may be operable to calculate and transfer data to other storage devices from data stored in RAM (e.g., RAM 121 of FIG. 1C) without involvement of the storage controllers 125a, 125b. This operation may be used to mirror data stored in one storage controller 125a to another storage controller 125b, or it could be used to offload compression, data aggregation, and/or erasure coding calculations and transfers to storage devices to reduce load on storage controllers or the storage controller interface 129a, 129b to the PCI bus 128a, 128b.

A storage device controller 119A-D may include mechanisms for implementing high availability primitives for use by other parts of a storage system external to the Dual PCI storage device 118. For example, reservation or exclusion primitives may be provided so that, in a storage system with two storage controllers providing a highly available storage service, one storage controller may prevent the other storage controller from accessing or continuing to access the storage device. This could be used, for example, in cases where one controller detects that the other controller is not functioning properly or where the interconnect between the two storage controllers may itself not be functioning properly.

In one embodiment, a storage system for use with Dual PCI direct mapped storage devices with separately addressable fast write storage includes systems that manage erase blocks or groups of erase blocks as allocation units for storing data on behalf of the storage service, or for storing metadata (e.g., indexes, logs, etc.) associated with the storage service, or for proper management of the storage system itself. Flash pages, which may be a few kilobytes in size, may be written as data arrives or as the storage system is to persist data for long intervals of time (e.g., above a defined threshold of time). To commit data more quickly, or to reduce the number of writes to the Flash memory devices, the storage controllers may first write data into the separately addressable fast write storage on one or more storage devices.

In one embodiment, the storage controllers 125a, 125b may initiate the use of erase blocks within and across storage devices (e.g., 118) in accordance with an age and expected remaining lifespan of the storage devices, or based on other statistics. The storage controllers 125a, 125b may initiate garbage collection and data migration between storage devices in accordance with pages that are no longer needed as well as to manage Flash page and erase block lifespans and to manage overall system performance.

In one embodiment, the storage system 124 may utilize mirroring and/or erasure coding schemes as part of storing data into addressable fast write storage and/or as part of writing data into allocation units associated with erase blocks. Erasure codes may be used across storage devices, as well as within erase blocks or allocation units, or within and across Flash memory devices on a single storage device, to provide redundancy against single or multiple storage device failures or to protect against internal corruptions of Flash memory pages resulting from Flash memory operations or from degradation of Flash memory cells. Mirroring and erasure coding at various levels may be used to recover from multiple types of failures that occur separately or in combination.

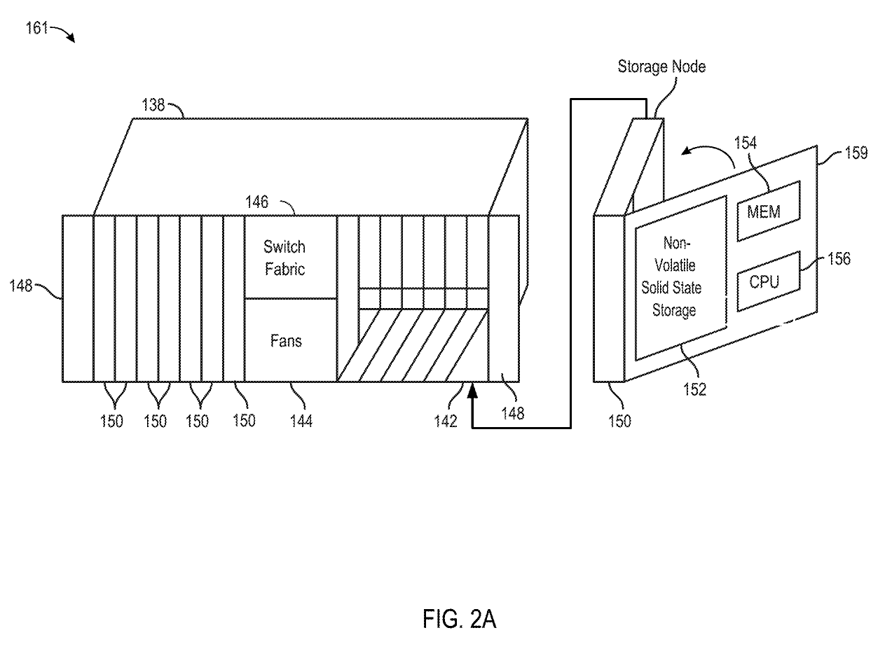

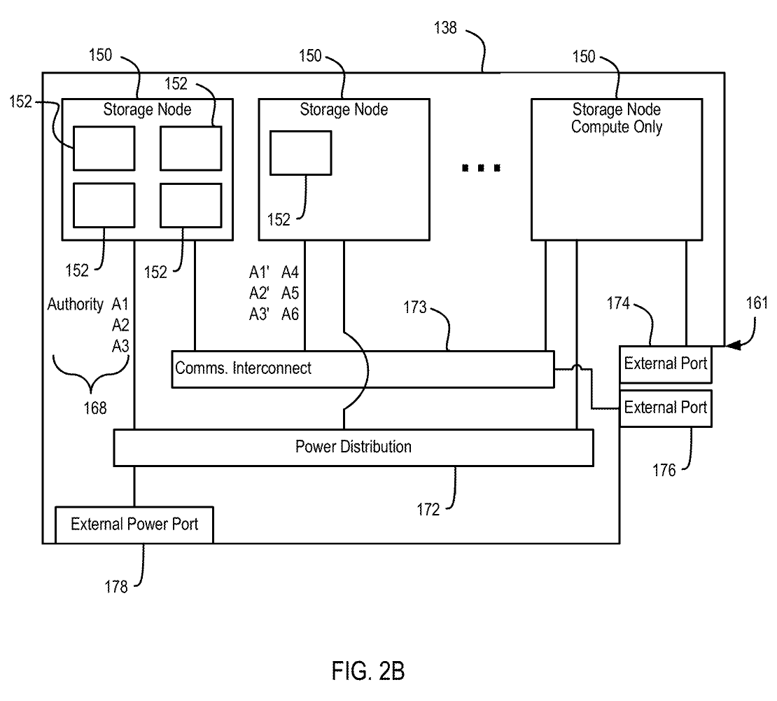

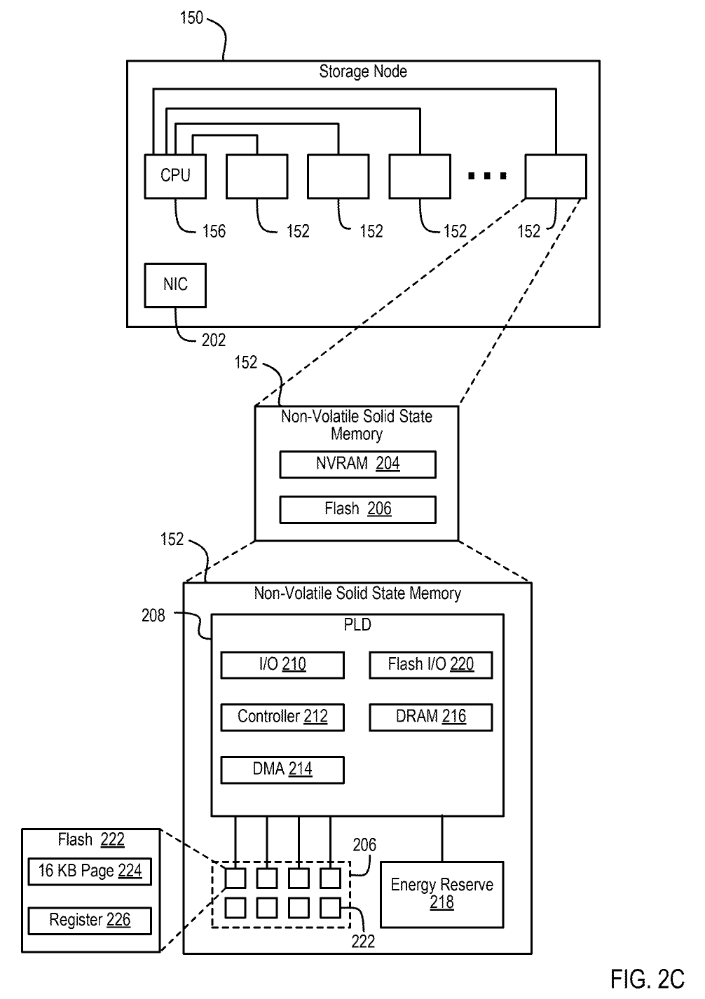

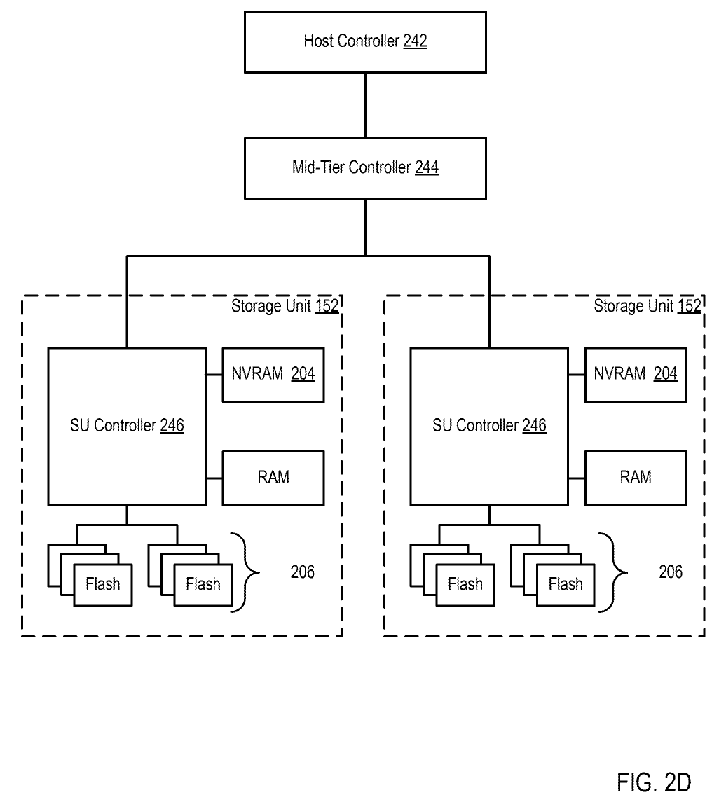

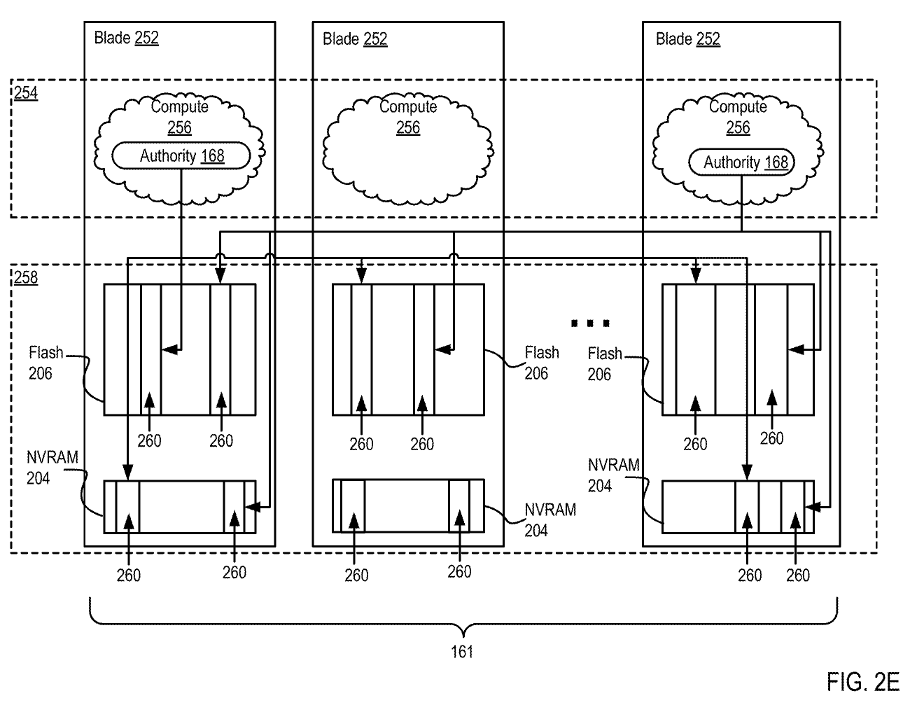

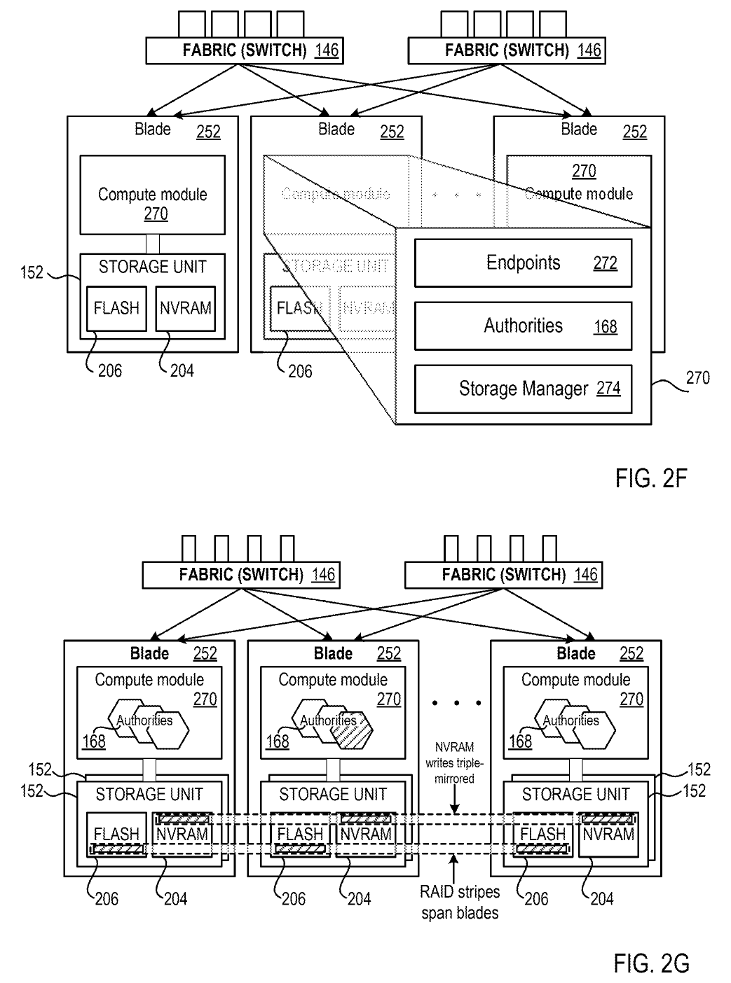

The embodiments depicted with reference to FIGS. 2A-G illustrate a storage cluster that stores user data, such as user data originating from one or more user or client systems or other sources external to the storage cluster. The storage cluster distributes user data across storage nodes housed within a chassis, or across multiple chassis, using erasure coding and redundant copies of metadata. Erasure coding refers to a method of data protection or reconstruction in which data is stored across a set of different locations, such as disks, storage nodes or geographic locations. Flash memory is one type of solid-state memory that may be integrated with the embodiments, although the embodiments may be extended to other types of solid-state memory or other storage medium, including non- solid state memory. Control of storage locations and workloads are distributed across the storage locations in a clustered peer-to-peer system. Tasks such as mediating communications between the various storage nodes, detecting when a storage node has become unavailable, and balancing I/Os (inputs and outputs) across the various storage nodes, are all handled on a distributed basis. Data is laid out or distributed across multiple storage nodes in data fragments or stripes that support data recovery in some embodiments. Ownership of data can be reassigned within a cluster, independent of input and output patterns. This architecture described in more detail below allows a storage node in the cluster to fail, with the system remaining operational, since the data can be reconstructed from other storage nodes and thus remain available for input and output operations. In various embodiments, a storage node may be referred to as a cluster node, a blade, or a server.

The storage cluster may be contained within a chassis, i.e., an enclosure housing one or more storage nodes. A mechanism to provide power to each storage node, such as a power distribution bus, and a communication mechanism, such as a communication bus that enables communication between the storage nodes are included within the chassis. The storage cluster can run as an independent system in one location according to some embodiments. In one embodiment, a chassis contains at least two instances of both the power distribution and the communication bus which may be enabled or disabled independently. The internal communication bus may be an Ethernet bus, however, other technologies such as PCIe, InfiniBand, and others, are equally suitable. The chassis provides a port for an external communication bus for enabling communication between multiple chassis, directly or through a switch, and with client systems. The external communication may use a technology such as Ethernet, InfiniBand, Fibre Channel, etc. In some embodiments, the external communication bus uses different communication bus technologies for inter-chassis and client communication. If a switch is deployed within or between chassis, the switch may act as a translation between multiple protocols or technologies. When multiple chassis are connected to define a storage cluster, the storage cluster may be accessed by a client using either proprietary interfaces or standard interfaces such as network file system ('NFS'), common internet file system ('CIFS'), small computer system interface ('SCSI') or hypertext transfer protocol ('HTTP'). Translation from the client protocol may occur at the switch, chassis external communication bus or within each storage node. In some embodiments, multiple chassis may be coupled or connected to each other through an aggregator switch. A portion and/or all of the coupled or connected chassis may be designated as a storage cluster. As discussed above, each chassis can have multiple blades, each blade has a media access control ('MAC') address, but the storage cluster is presented to an external network as having a single cluster IP address and a single MAC address in some embodiments.

Each storage node may be one or more storage servers and each storage server is connected to one or more non-volatile solid state memory units, which may be referred to as storage units or storage devices. One embodiment includes a single storage server in each storage node and between one to eight non-volatile solid state memory units, however this one example is not meant to be limiting. The storage server may include a processor, DRAM and interfaces for the internal communication bus and power distribution for each of the power buses. Inside the storage node, the interfaces and storage unit share a communication bus, e.g., PCI Express, in some embodiments. The non-volatile solid state memory units may directly access the internal communication bus interface through a storage node communication bus, or request the storage node to access the bus interface. The non-volatile solid state memory unit contains an embedded CPU, solid state storage controller, and a quantity of solid state mass storage, e.g., between 2-32 terabytes ('TB') in some embodiments. An embedded volatile storage medium, such as DRAM, and an energy reserve apparatus are included in the non-volatile solid state memory unit. In some embodiments, the energy reserve apparatus is a capacitor, super-capacitor, or battery that enables transferring a subset of DRAM contents to a stable storage medium in the case of power loss. In some embodiments, the non-volatile solid state memory unit is constructed with a storage class memory, such as phase change or magnetoresistive random access memory ('MRAM') that substitutes for DRAM and enables a reduced power hold-up apparatus.

One of many features of the storage nodes and non-volatile solid state storage is the ability to proactively rebuild data in a storage cluster. The storage nodes and non-volatile solid state storage can determine when a storage node or non-volatile solid state storage in the storage cluster is unreachable, independent of whether there is an attempt to read data involving that storage node or non-volatile solid state storage. The storage nodes and non-volatile solid state storage then cooperate to recover and rebuild the data in at least partially new locations. This constitutes a proactive rebuild, in that the system rebuilds data without waiting until the data is needed for a read access initiated from a client system employing the storage cluster. These and further details of the storage memory and operation thereof are discussed below.

FIG. 2A is a perspective view of a storage cluster 161, with multiple storage nodes 150 and internal solid-state memory coupled to each storage node to provide network attached storage or storage area network, in accordance with some embodiments. A network attached storage, storage area network, or a storage cluster, or other storage memory, could include one or more storage clusters 161, each having one or more storage nodes 150, in a flexible and reconfigurable arrangement of both the physical components and the amount of storage memory provided thereby. The storage cluster 161 is designed to fit in a rack, and one or more racks can be set up and populated as desired for the storage memory. The storage cluster 161 has a chassis 138 having multiple slots 142. It should be appreciated that chassis 138 may be referred to as a housing, enclosure, or rack unit. In one embodiment, the chassis 138 has fourteen slots 142, although other numbers of slots are readily devised. For example, some embodiments have four slots, eight slots, sixteen slots, thirty-two slots, or other suitable number of slots. Each slot 142 can accommodate one storage node 150 in some embodiments. Chassis 138 includes flaps 148 that can be utilized to mount the chassis 138 on a rack. Fans 144 provide air circulation for cooling of the storage nodes 150 and components thereof, although other cooling components could be used, or an embodiment could be devised without cooling components. A switch fabric 146 couples storage nodes 150 within chassis 138 together and to a network for communication to the memory. In an embodiment depicted in herein, the slots 142 to the left of the switch fabric 146 and fans 144 are shown occupied by storage nodes 150, while the slots 142 to the right of the switch fabric 146 and fans 144 are empty and available for insertion of storage node 150 for illustrative purposes. This configuration is one example, and one or more storage nodes 150 could occupy the slots 142 in various further arrangements. The storage node arrangements need not be sequential or adjacent in some embodiments. Storage nodes 150 are hot pluggable, meaning that a storage node 150 can be inserted into a slot 142 in the chassis 138, or removed from a slot 142, without stopping or powering down the system. Upon insertion or removal of storage node 150 from slot 142, the system automatically reconfigures in order to recognize and adapt to the change. Reconfiguration, in some embodiments, includes restoring redundancy and/or rebalancing data or load.

Each storage node 150 can have multiple components. In the embodiment shown here, the storage node 150 includes a printed circuit board 159 populated by a CPU 156, i.e., processor, a memory 154 coupled to the CPU 156, and a non-volatile solid state storage 152 coupled to the CPU 156, although other mountings and/or components could be used in further embodiments. The memory 154 has instructions which are executed by the CPU 156 and/or data operated on by the CPU 156. As further explained below, the non-volatile solid state storage 152 includes flash or, in further embodiments, other types of solid-state memory. In some embodiments, the non-volatile solid state storage 152 may include one or more managed flash storage devices, as previously described.

Referring to FIG. 2A, storage cluster 161 is scalable, meaning that storage capacity with non-uniform storage sizes is readily added, as described above. One or more storage nodes 150 can be plugged into or removed from each chassis and the storage cluster self-configures in some embodiments. Plug-in storage nodes 150, whether installed in a chassis as delivered or later added, can have different sizes. For example, in one embodiment a storage node 150 can have any multiple of 4 TB, e.g., 8 TB, 12 TB, 16 TB, 32 TB, etc. In further embodiments, a storage node 150 could have any multiple of other storage amounts or capacities. Storage capacity of each storage node 150 is broadcast, and influences decisions of how to stripe the data. For maximum storage efficiency, an embodiment can self-configure as wide as possible in the stripe, subject to a predetermined requirement of continued operation with loss of up to one, or up to two, non-volatile solid state storage 152 units or storage nodes 150 within the chassis.

FIG. 2B is a block diagram showing a communications interconnect 173 and power distribution bus 172 coupling multiple storage nodes 150. Referring back to FIG. 2A, the communications interconnect 173 can be included in or implemented with the switch fabric 146 in some embodiments. Where multiple storage clusters 161 occupy a rack, the communications interconnect 173 can be included in or implemented with a top of rack switch, in some embodiments. As illustrated in FIG. 2B, storage cluster 161 is enclosed within a single chassis 138. External port 176 is coupled to storage nodes 150 through communications interconnect 173, while external port 174 is coupled directly to a storage node. External power port 178 is coupled to power distribution bus 172. Storage nodes 150 may include varying amounts and differing capacities of non-volatile solid state storage 152 as described with reference to FIG. 2A. In addition, one or more storage nodes 150 may be a compute only storage node as illustrated in FIG. 2B. Authorities 168 are implemented on the non-volatile solid state storage 152, for example as lists or other data structures stored in memory. In some embodiments the authorities are stored within the non-volatile solid state storage 152 and supported by software executing on a controller or other processor of the non-volatile solid state storage 152. In a further embodiment, authorities 168 are implemented on the storage nodes 150, for example as lists or other data structures stored in the memory 154 and supported by software executing on the CPU 156 of the storage node 150. Authorities 168 control how and where data is stored in the non-volatile solid state storage 152 in some embodiments. This control assists in determining which type of erasure coding scheme is applied to the data, and which storage nodes 150 have which portions of the data. Each authority 168 may be assigned to a non-volatile solid state storage 152. Each authority may control a range of inode numbers, segment numbers, or other data identifiers which are assigned to data by a file system, by the storage nodes 150, or by the non-volatile solid state storage 152, in various embodiments.

Every piece of data, and every piece of metadata, has redundancy in the system in some embodiments. In addition, every piece of data and every piece of metadata has an owner, which may be referred to as an authority. If that authority is unreachable, for example through failure of a storage node, there is a plan of succession for how to find that data or that metadata. In various embodiments, there are redundant copies of authorities 168. Authorities 168 have a relationship to storage nodes 150 and non-volatile solid state storage 152 in some embodiments. Each authority 168, covering a range of data segment numbers or other identifiers of the data, may be assigned to a specific non-volatile solid state storage 152. In some embodiments the authorities 168 for all of such ranges are distributed over the non-volatile solid state storage 152 of a storage cluster. Each storage node 150 has a network port that provides access to the non-volatile solid state storage(s) 152 of that storage node 150. Data can be stored in a segment, which is associated with a segment number and that segment number is an indirection for a configuration of a RAID (redundant array of independent disks) stripe in some embodiments. The assignment and use of the authorities 168 thus establishes an indirection to data. Indirection may be referred to as the ability to reference data indirectly, in this case via an authority 168, in accordance with some embodiments. A segment identifies a set of non-volatile solid state storage 152 and a local identifier into the set of non-volatile solid state storage 152 that may contain data. In some embodiments, the local identifier is an offset into the device and may be reused sequentially by multiple segments. In other embodiments the local identifier is unique for a specific segment and never reused. The offsets in the non-volatile solid state storage 152 are applied to locating data for writing to or reading from the non-volatile solid state storage 152 (in the form of a RAID stripe). Data is striped across multiple units of non-volatile solid state storage 152, which may include or be different from the non-volatile solid state storage 152 having the authority 168 for a particular data segment.

If there is a change in where a particular segment of data is located, e.g., during a data move or a data reconstruction, the authority 168 for that data segment should be consulted, at that non-volatile solid state storage 152 or storage node 150 having that authority 168. In order to locate a particular piece of data, embodiments calculate a hash value for a data segment or apply an inode number or a data segment number. The output of this operation points to a non-volatile solid state storage 152 having the authority 168 for that particular piece of data. In some embodiments there are two stages to this operation. The first stage maps an entity identifier (ID), e.g., a segment number, inode number, or directory number to an authority identifier. This mapping may include a calculation such as a hash or a bit mask. The second stage is mapping the authority identifier to a particular non-volatile solid state storage 152, which may be done through an explicit mapping. The operation is repeatable, so that when the calculation is performed, the result of the calculation repeatably and reliably points to a particular non-volatile solid state storage 152 having that authority 168. The operation may include the set of reachable storage nodes as input. If the set of reachable non-volatile solid state storage units changes the optimal set changes. In some embodiments, the persisted value is the current assignment (which is always true) and the calculated value is the target assignment the cluster will attempt to reconfigure towards. This calculation may be used to determine the optimal non-volatile solid state storage 152 for an authority in the presence of a set of non-volatile solid state storage 152 that are reachable and constitute the same cluster. The calculation also determines an ordered set of peer non-volatile solid state storage 152 that will also record the authority to non-volatile solid state storage mapping so that the authority may be determined even if the assigned non-volatile solid state storage is unreachable. A duplicate or substitute authority 168 may be consulted if a specific authority 168 is unavailable in some embodiments.

With reference to FIG. 2A and 2B, two of the many tasks of the CPU 156 on a storage node 150 are to break up write data, and reassemble read data. When the system has determined that data is to be written, the authority 168 for that data is located as above. When the segment ID for data is already determined the request to write is forwarded to the non-volatile solid state storage 152 currently determined to be the host of the authority 168 determined from the segment. The host CPU 156 of the storage node 150, on which the non-volatile solid state storage 152 and corresponding authority 168 reside, then breaks up or shards the data and transmits the data out to various non-volatile solid state storage 152. The transmitted data is written as a data stripe in accordance with an erasure coding scheme. In some embodiments, data is requested to be pulled, and in other embodiments, data is pushed. In reverse, when data is read, the authority 168 for the segment ID containing the data is located as described above. The host CPU 156 of the storage node 150 on which the non-volatile solid state storage 152 and corresponding authority 168 reside requests the data from the non-volatile solid state storage and corresponding storage nodes pointed to by the authority. In some embodiments the data is read from flash storage as a data stripe. The host CPU 156 of storage node 150 then reassembles the read data, correcting any errors (if present) according to the appropriate erasure coding scheme, and forwards the reassembled data to the network. In further embodiments, some or all of these tasks can be handled in the non-volatile solid state storage 152. In some embodiments, the segment host requests the data be sent to storage node 150 by requesting pages from storage and then sending the data to the storage node making the original request.

In embodiments, authorities 168 operate to determine how operations will proceed against particular logical elements. Each of the logical elements may be operated on through a particular authority across a plurality of storage controllers of a storage system. The authorities 168 may communicate with the plurality of storage controllers so that the plurality of storage controllers collectively perform operations against those particular logical elements.

In embodiments, logical elements could be, for example, files, directories, object buckets, individual objects, delineated parts of files or objects, other forms of key-value pair databases, or tables. In embodiments, performing an operation can involve, for example, ensuring consistency, structural integrity, and/or recoverability with other operations against the same logical element, reading metadata and data associated with that logical element, determining what data should be written durably into the storage system to persist any changes for the operation, or where metadata and data can be determined to be stored across modular storage devices attached to a plurality of the storage controllers in the storage system.

In some embodiments the operations are token based transactions to efficiently communicate within a distributed system. Each transaction may be accompanied by or associated with a token, which gives permission to execute the transaction. The authorities 168 are able to maintain a pre-transaction state of the system until completion of the operation in some embodiments. The token based communication may be accomplished without a global lock across the system, and also enables restart of an operation in case of a disruption or other failure.

In some systems, for example in UNIX-style file systems, data is handled with an index node or inode, which specifies a data structure that represents an object in a file system. The object could be a file or a directory, for example. Metadata may accompany the object, as attributes such as permission data and a creation timestamp, among other attributes. A segment number could be assigned to all or a portion of such an object in a file system. In other systems, data segments are handled with a segment number assigned elsewhere. For purposes of discussion, the unit of distribution is an entity, and an entity can be a file, a directory or a segment. That is, entities are units of data or metadata stored by a storage system. Entities are grouped into sets called authorities. Each authority has an authority owner, which is a storage node that has the exclusive right to update the entities in the authority. In other words, a storage node contains the authority, and that the authority, in turn, contains entities.

A segment is a logical container of data in accordance with some embodiments. A segment is an address space between medium address space and physical flash locations, i.e., the data segment number, are in this address space. Segments may also contain meta-data, which enable data redundancy to be restored (rewritten to different flash locations or devices) without the involvement of higher level software. In one embodiment, an internal format of a segment contains client data and medium mappings to determine the position of that data. Each data segment is protected, e.g., from memory and other failures, by breaking the segment into a number of data and parity shards, where applicable. The data and parity shards are distributed, i.e., striped, across non-volatile solid state storage 152 coupled to the host CPUs 156 (See FIGS. 2E and 2G) in accordance with an erasure coding scheme. Usage of the term segments refers to the container and its place in the address space of segments in some embodiments. Usage of the term stripe refers to the same set of shards as a segment and includes how the shards are distributed along with redundancy or parity information in accordance with some embodiments.

A series of address-space transformations takes place across an entire storage system. At the top are the directory entries (file names) which link to an inode. Inodes point into medium address space, where data is logically stored. Medium addresses may be mapped through a series of indirect mediums to spread the load of large files, or implement data services like deduplication or snapshots. Segment addresses are then translated into physical flash locations. Physical flash locations have an address range bounded by the amount of flash in the system in accordance with some embodiments. Medium addresses and segment addresses are logical containers, and in some embodiments use a 128 bit or larger identifier so as to be practically infinite, with a likelihood of reuse calculated as longer than the expected life of the system. Addresses from logical containers are allocated in a hierarchical fashion in some embodiments. Initially, each non-volatile solid state storage 152 unit may be assigned a range of address space. Within this assigned range, the non-volatile solid state storage 152 is able to allocate addresses without synchronization with other non-volatile solid state storage 152.

Data and metadata is stored by a set of underlying storage layouts that are optimized for varying workload patterns and storage devices. These layouts incorporate multiple redundancy schemes, compression formats and index algorithms. Some of these layouts store information about authorities and authority masters, while others store file metadata and file data. The redundancy schemes include error correction codes that tolerate corrupted bits within a single storage device (such as a NAND flash chip), erasure codes that tolerate the failure of multiple storage nodes, and replication schemes that tolerate data center or regional failures. In some embodiments, low density parity check ('LDPC') code is used within a single storage unit. Reed-Solomon encoding is used within a storage cluster, and mirroring is used within a storage grid in some embodiments. Metadata may be stored using an ordered log structured index (such as a Log Structured Merge Tree), and large data may not be stored in a log structured layout.

In order to maintain consistency across multiple copies of an entity, the storage nodes agree implicitly on two things through calculations:
(1) the authority that contains the entity, and
(2) the storage node that contains the authority. The assignment of entities to authorities can be done by pseudo randomly assigning entities to authorities, by splitting entities into ranges based upon an externally produced key, or by placing a single entity into each authority. Examples of pseudorandom schemes are linear hashing and the Replication Under Scalable Hashing ('RUSH') family of hashes, including Controlled Replication Under Scalable Hashing ('CRUSH'). In some embodiments, pseudo-random assignment is utilized only for assigning authorities to nodes because the set of nodes can change. The set of authorities cannot change so any subjective function may be applied in these embodiments. Some placement schemes automatically place authorities on storage nodes, while other placement schemes rely on an explicit mapping of authorities to storage nodes. In some embodiments, a pseudorandom scheme is utilized to map from each authority to a set of candidate authority owners. A pseudorandom data distribution function related to CRUSH may assign authorities to storage nodes and create a list of where the authorities are assigned. Each storage node has a copy of the pseudorandom data distribution function, and can arrive at the same calculation for distributing, and later finding or locating an authority. Each of the pseudorandom schemes requires the reachable set of storage nodes as input in some embodiments in order to conclude the same target nodes. Once an entity has been placed in an authority, the entity may be stored on physical devices so that no expected failure will lead to unexpected data loss. In some embodiments, rebalancing algorithms attempt to store the copies of all entities within an authority in the same layout and on the same set of machines.

Examples of expected failures include device failures, stolen machines, datacenter fires, and regional disasters, such as nuclear or geological events. Different failures lead to different levels of acceptable data loss. In some embodiments, a stolen storage node impacts neither the security nor the reliability of the system, while depending on system configuration, a regional event could lead to no loss of data, a few seconds or minutes of lost updates, or even complete data loss.

In the embodiments, the placement of data for storage redundancy is independent of the placement of authorities for data consistency. In some embodiments, storage nodes that contain authorities do not contain any persistent storage. Instead, the storage nodes are connected to non-volatile solid state storage units that do not contain authorities. The communications interconnect between storage nodes and non-volatile solid state storage units consists of multiple communication technologies and has non-uniform performance and fault tolerance characteristics. In some embodiments, as mentioned above, non-volatile solid state storage units are connected to storage nodes via PCI express, storage nodes are connected together within a single chassis using Ethernet backplane, and chassis are connected together to form a storage cluster. Storage clusters are connected to clients using Ethernet or fiber channel in some embodiments. If multiple storage clusters are configured into a storage grid, the multiple storage clusters are connected using the Internet or other long-distance networking links, such as a "metro scale" link or private link that does not traverse the internet.

Authority owners have the exclusive right to modify entities, to migrate entities from one non-volatile solid state storage unit to another non-volatile solid state storage unit, and to add and remove copies of entities. This allows for maintaining the redundancy of the underlying data. When an authority owner fails, is going to be decommissioned, or is overloaded, the authority is transferred to a new storage node. Transient failures make it non-trivial to ensure that all non-faulty machines agree upon the new authority location. The ambiguity that arises due to transient failures can be achieved automatically by a consensus protocol such as Paxos, hot-warm failover schemes, via manual intervention by a remote system administrator, or by a local hardware administrator (such as by physically removing the failed machine from the cluster, or pressing a button on the failed machine). In some embodiments, a consensus protocol is used, and failover is automatic. If too many failures or replication events occur in too short a time period, the system goes into a self-preservation mode and halts replication and data movement activities until an administrator intervenes in accordance with some embodiments.

As authorities are transferred between storage nodes and authority owners update entities in their authorities, the system transfers messages between the storage nodes and non-volatile solid state storage units. With regard to persistent messages, messages that have different purposes are of different types. Depending on the type of the message, the system maintains different ordering and durability guarantees. As the persistent messages are being processed, the messages are temporarily stored in multiple durable and non-durable storage hardware technologies. In some embodiments, messages are stored in RAM, NVRAM and on NAND flash devices, and a variety of protocols are used in order to make efficient use of each storage medium. Latency-sensitive client requests may be persisted in replicated NVRAM, and then later NAND, while background rebalancing operations are persisted directly to NAND.

Persistent messages are persistently stored prior to being transmitted. This allows the system to continue to serve client requests despite failures and component replacement. Although many hardware components contain unique identifiers that are visible to system administrators, manufacturer, hardware supply chain and ongoing monitoring quality control infrastructure, applications running on top of the infrastructure address virtualize addresses. These virtualized addresses do not change over the lifetime of the storage system, regardless of component failures and replacements. This allows each component of the storage system to be replaced over time without reconfiguration or disruptions of client request processing, i.e., the system supports non-disruptive upgrades.

In some embodiments, the virtualized addresses are stored with sufficient redundancy. A continuous monitoring system correlates hardware and software status and the hardware identifiers. This allows detection and prediction of failures due to faulty components and manufacturing details. The monitoring system also enables the proactive transfer of authorities and entities away from impacted devices before failure occurs by removing the component from the critical path in some embodiments.

FIG. 2C is a multiple level block diagram, showing contents of a storage node 150 and contents of a non-volatile solid state storage 152 of the storage node 150. Data is communicated to and from the storage node 150 by a network interface controller ('NIC') 202 in some embodiments. Each storage node 150 has a CPU 156, and one or more non-volatile solid state storage 152, as discussed above. Moving down one level in FIG. 2C, each non-volatile solid state storage 152 has a relatively fast non-volatile solid state memory, such as nonvolatile random access memory ('NVRAM') 204, and flash memory 206. In some embodiments, NVRAM 204 may be a component that does not require program/erase cycles (DRAM, MRAM, PCM), and can be a memory that can support being written vastly more often than the memory is read from. Moving down another level in FIG. 2C, the NVRAM 204 is implemented in one embodiment as high speed volatile memory, such as dynamic random access memory (DRAM) 216, backed up by energy reserve 218. Energy reserve 218 provides sufficient electrical power to keep the DRAM 216 powered long enough for contents to be transferred to the flash memory 206 in the event of power failure. In some embodiments, energy reserve 218 is a capacitor, super-capacitor, battery, or other device, that supplies a suitable supply of energy sufficient to enable the transfer of the contents of DRAM 216 to a stable storage medium in the case of power loss. The flash memory 206 is implemented as multiple flash dies 222, which may be referred to as packages of flash dies 222 or an array of flash dies 222. It should be appreciated that the flash dies 222 could be packaged in any number of ways, with a single die per package, multiple dies per package (i.e., multichip packages), in hybrid packages, as bare dies on a printed circuit board or other substrate, as encapsulated dies, etc. In the embodiment shown, the non-volatile solid state storage 152 has a controller 212 or other processor, and an input output (I/O) port 210 coupled to the controller 212. I/O port 210 is coupled to the CPU 156 and/or the network interface controller 202 of the flash storage node 150. Flash input output (I/O) port 220 is coupled to the flash dies 222, and a direct memory access unit (DMA) 214 is coupled to the controller 212, the DRAM 216 and the flash dies 222. In the embodiment shown, the I/O port 210, controller 212, DMA unit 214 and flash I/O port 220 are implemented on a programmable logic device ('PLD') 208, e.g., an FPGA. In this embodiment, each flash die 222 has pages, organized as sixteen kB (kilobyte) pages 224, and a register 226 through which data can be written to or read from the flash die 222. In further embodiments, other types of solid-state memory are used in place of, or in addition to flash memory illustrated within flash die 222.

Storage clusters 161, in various embodiments as disclosed herein, can be contrasted with storage arrays in general. The storage nodes 150 are part of a collection that creates the storage cluster 161. Each storage node 150 owns a slice of data and computing required to provide the data. Multiple storage nodes 150 cooperate to store and retrieve the data. Storage memory or storage devices, as used in storage arrays in general, are less involved with processing and manipulating the data. Storage memory or storage devices in a storage array receive commands to read, write, or erase data. The storage memory or storage devices in a storage array are not aware of a larger system in which they are embedded, or what the data means. Storage memory or storage devices in storage arrays can include various types of storage memory, such as RAM, solid state drives, hard disk drives, etc. The non-volatile solid state storage 152 units described herein have multiple interfaces active simultaneously and serving multiple purposes. In some embodiments, some of the functionality of a storage node 150 is shifted into a storage unit 152, transforming the storage unit 152 into a combination of storage unit 152 and storage node 150. Placing computing (relative to storage data) into the storage unit 152 places this computing closer to the data itself. The various system embodiments have a hierarchy of storage node layers with different capabilities. By contrast, in a storage array, a controller owns and knows everything about all of the data that the controller manages in a shelf or storage devices. In a storage cluster 161, as described herein, multiple controllers in multiple non-volatile solid state storage 152 units and/or storage nodes 150 cooperate in various ways (e.g., for erasure coding, data sharding, metadata communication and redundancy, storage capacity expansion or contraction, data recovery, and so on).

FIG. 2D shows a storage server environment, which uses embodiments of the storage nodes 150 and storage 152 units of FIGS. 2A-C. In this version, each non-volatile solid state storage 152 unit has a processor such as controller 212 (see FIG. 2C), an FPGA, flash memory 206, and NVRAM 204 (which is super-capacitor backed DRAM 216, see FIGS. 2B and 2C) on a PCIe (peripheral component interconnect express) board in a chassis 138 (see FIG. 2A). The non-volatile solid state storage 152 unit may be implemented as a single board containing storage, and may be the largest tolerable failure domain inside the chassis. In some embodiments, up to two non-volatile solid state storage 152 units may fail and the device will continue with no data loss.

The physical storage is divided into named regions based on application usage in some embodiments. The NVRAM 204 is a contiguous block of reserved memory in the non-volatile solid state storage 152 DRAM 216, and is backed by NAND flash. NVRAM 204 is logically divided into multiple memory regions written for two as spool (e.g., spool_region). Space within the NVRAM 204 spools is managed by each authority 168 independently. Each device provides an amount of storage space to each authority 168. That authority 168 further manages lifetimes and allocations within that space. Examples of a spool include distributed transactions or notions. When the primary power to a non-volatile solid state storage 152 unit fails, onboard super-capacitors provide a short duration of power hold up. During this holdup interval, the contents of the NVRAM 204 are flushed to flash memory 206. On the next power-on, the contents of the NVRAM 204 are recovered from the flash memory 206.

As for the storage unit controller, the responsibility of the logical "controller" is distributed across each of the blades containing authorities 168. This distribution of logical control is shown in FIG. 2D as a host controller 242, mid-tier controller 244 and storage unit controller(s) 246. Management of the control plane and the storage plane are treated independently, although parts may be physically co-located on the same blade. Each authority 168 effectively serves as an independent controller. Each authority 168 provides its own data and metadata structures, its own background workers, and maintains its own lifecycle.

FIG. 2E is a blade 252 hardware block diagram, showing a control plane 254, compute and storage planes 256, 258, and authorities 168 interacting with underlying physical resources, using embodiments of the storage nodes 150 and storage units 152 of FIGS. 2A-C in the storage server environment of FIG. 2D. The control plane 254 is partitioned into a number of authorities 168 which can use the compute resources in the compute plane 256 to run on any of the blades 252. The storage plane 258 is partitioned into a set of devices, each of which provides access to flash 206 and NVRAM 204 resources. In one embodiment, the compute plane 256 may perform the operations of a storage array controller, as described herein, on one or more devices of the storage plane 258 (e.g., a storage array).

In the compute and storage planes 256, 258 of FIG. 2E, the authorities 168 interact with the underlying physical resources (i.e., devices). From the point of view of an authority 168, its resources are striped over all of the physical devices. From the point of view of a device, it provides resources to all authorities 168, irrespective of where the authorities happen to run. Each authority 168 has allocated or has been allocated one or more partitions 260 of storage memory in the storage units 152, e.g., partitions 260 in flash memory 206 and NVRAM 204. Each authority 168 uses those allocated partitions 260 that belong to it, for writing or reading user data. Authorities can be associated with differing amounts of physical storage of the system. For example, one authority 168 could have a larger number of partitions 260 or larger sized partitions 260 in one or more storage units 152 than one or more other authorities 168.

FIG. 2F depicts elasticity software layers in blades 252 of a storage cluster, in accordance with some embodiments. In the elasticity structure, elasticity software is symmetric, i.e., each blade's compute module 270 runs the three identical layers of processes depicted in FIG. 2F. Storage managers 274 execute read and write requests from other blades 252 for data and metadata stored in local storage unit 152 NVRAM 204 and flash 206. Authorities 168 fulfill client requests by issuing the necessary reads and writes to the blades 252 on whose storage units 152 the corresponding data or metadata resides. Endpoints 272 parse client connection requests received from switch fabric 146 supervisory software, relay the client connection requests to the authorities 168 responsible for fulfillment, and relay the authorities' 168 responses to clients. The symmetric three-layer structure enables the storage system's high degree of concurrency. Elasticity scales out efficiently and reliably in these embodiments. In addition, elasticity implements a unique scale-out technique that balances work evenly across all resources regardless of client access pattern, and maximizes concurrency by eliminating much of the need for inter-blade coordination that typically occurs with conventional distributed locking.

Still referring to FIG. 2F, authorities 168 running in the compute modules 270 of a blade 252 perform the internal operations required to fulfill client requests. One feature of elasticity is that authorities 168 are stateless, i.e., they cache active data and metadata in their own blades' 252 DRAMs for fast access, but the authorities store every update in their NVRAM 204 partitions on three separate blades 252 until the update has been written to flash 206. All the storage system writes to NVRAM 204 are in triplicate to partitions on three separate blades 252 in some embodiments. With triple-mirrored NVRAM 204 and persistent storage protected by parity and Reed-Solomon RAID checksums, the storage system can survive concurrent failure of two blades 252 with no loss of data, metadata, or access to either.

Because authorities 168 are stateless, they can migrate between blades 252. Each authority 168 has a unique identifier. NVRAM 204 and flash 206 partitions are associated with authorities' 168 identifiers, not with the blades 252 on which they are running in some embodiments. Thus, when an authority 168 migrates, the authority 168 continues to manage the same storage partitions from its new location. When a new blade 252 is installed in an embodiment of the storage cluster, the system automatically rebalances load by: partitioning the new blade's 252 storage for use by the system's authorities 168, migrating selected authorities 168 to the new blade 252, starting endpoints 272 on the new blade 252 and including them in the switch fabric's 146 client connection distribution algorithm.

From their new locations, migrated authorities 168 persist the contents of their NVRAM 204 partitions on flash 206, process read and write requests from other authorities 168, and fulfill the client requests that endpoints 272 direct to them. Similarly, if a blade 252 fails or is removed, the system redistributes its authorities 168 among the system's remaining blades 252. The redistributed authorities 168 continue to perform their original functions from their new locations.

FIG. 2G depicts authorities 168 and storage resources in blades 252 of a storage cluster, in accordance with some embodiments. Each authority 168 is exclusively responsible for a partition of the flash 206 and NVRAM 204 on each blade 252. The authority 168 manages the content and integrity of its partitions independently of other authorities 168. Authorities 168 compress incoming data and preserve it temporarily in their NVRAM 204 partitions, and then consolidate, RAID-protect, and persist the data in segments of the storage in their flash 206 partitions. As the authorities 168 write data to flash 206, storage managers 274 perform the necessary flash translation to optimize write performance and maximize media longevity. In the background, authorities 168 "garbage collect," or reclaim space occupied by data that clients have made obsolete by overwriting the data. It should be appreciated that since authorities' 168 partitions are disjoint, there is no need for distributed locking to execute client and writes or to perform background functions.

The embodiments described herein may utilize various software, communication and/or networking protocols. In addition, the configuration of the hardware and/or software may be adjusted to accommodate various protocols. For example, the embodiments may utilize Active Directory, which is a database based system that provides authentication, directory, policy, and other services in a WINDOWS^{TM} environment. In these embodiments, LDAP (Lightweight Directory Access Protocol) is one example application protocol for querying and modifying items in directory service providers such as Active Directory. In some embodiments, a network lock manager ('NLM') is utilized as a facility that works in cooperation with the Network File System ('NFS') to provide a System V style of advisory file and record locking over a network. The Server Message Block ('SMB') protocol, one version of which is also known as Common Internet File System ('CIFS'), may be integrated with the storage systems discussed herein. SMB operates as an application-layer network protocol typically used for providing shared access to files, printers, and serial ports and miscellaneous communications between nodes on a network. SMB also provides an authenticated inter-process communication mechanism. AMAZON^{TM} S3 (Simple Storage Service) is a web service offered by Amazon Web Services, and the systems described herein may interface with Amazon S3 through web services interfaces (REST (representational state transfer), SOAP (simple object access protocol), and BitTorrent). A RESTful API (application programming interface) breaks down a transaction to create a series of small modules. Each module addresses a particular underlying part of the transaction. The control or permissions provided with these embodiments, especially for object data, may include utilization of an access control list ('ACL'). The ACL is a list of permissions attached to an object and the ACL specifies which users or system processes are granted access to objects, as well as what operations are allowed on given objects. The systems may utilize Internet Protocol version 6 ('IPv6'), as well as IPv4, for the communications protocol that provides an identification and location system for computers on networks and routes traffic across the Internet. The routing of packets between networked systems may include Equal-cost multi-path routing ('ECMP'), which is a routing strategy where next-hop packet forwarding to a single destination can occur over multiple "best paths" which tie for top place in routing metric calculations. Multi-path routing can be used in conjunction with most routing protocols, because it is a per-hop decision limited to a single router. The software may support Multi-tenancy, which is an architecture in which a single instance of a software application serves multiple customers. Each customer may be referred to as a tenant. Tenants may be given the ability to customize some parts of the application, but may not customize the application's code, in some embodiments. The embodiments may maintain audit logs. An audit log is a document that records an event in a computing system. In addition to documenting what resources were accessed, audit log entries typically include destination and source addresses, a timestamp, and user login information for compliance with various regulations. The embodiments may support various key management policies, such as encryption key rotation. In addition, the system may support dynamic root passwords or some variation dynamically changing passwords.

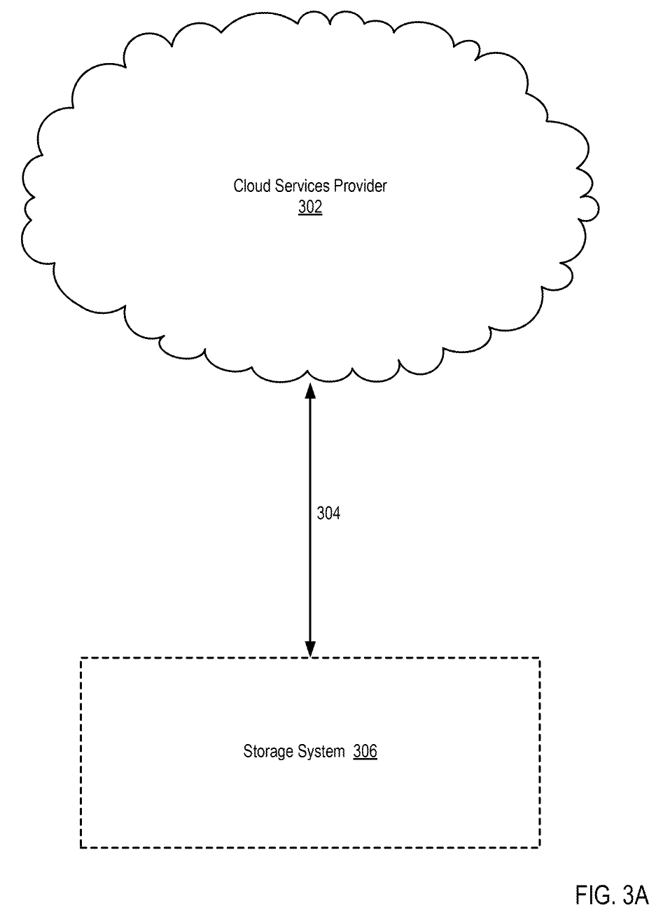

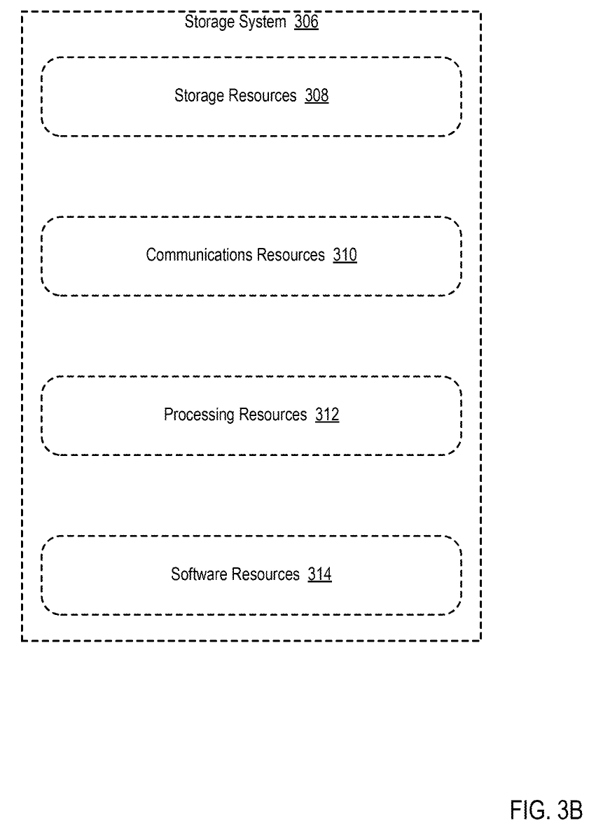

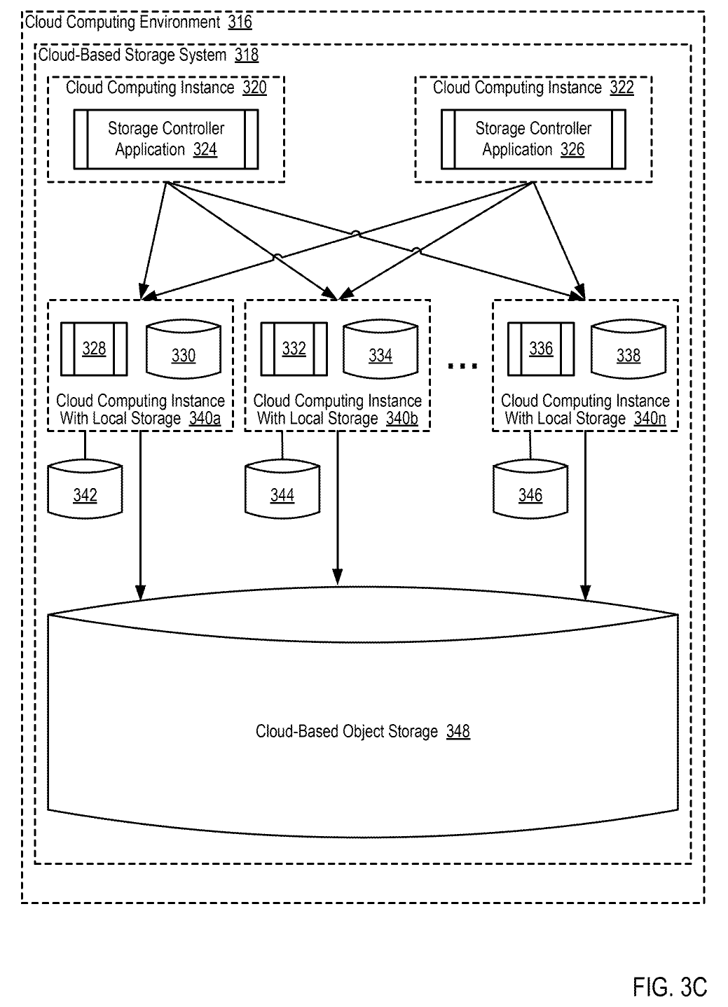

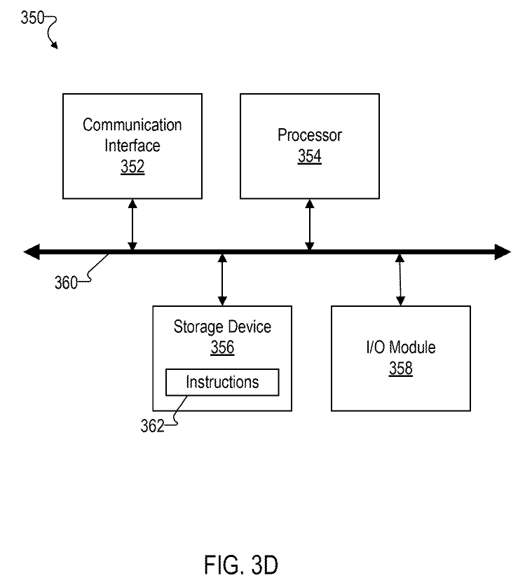

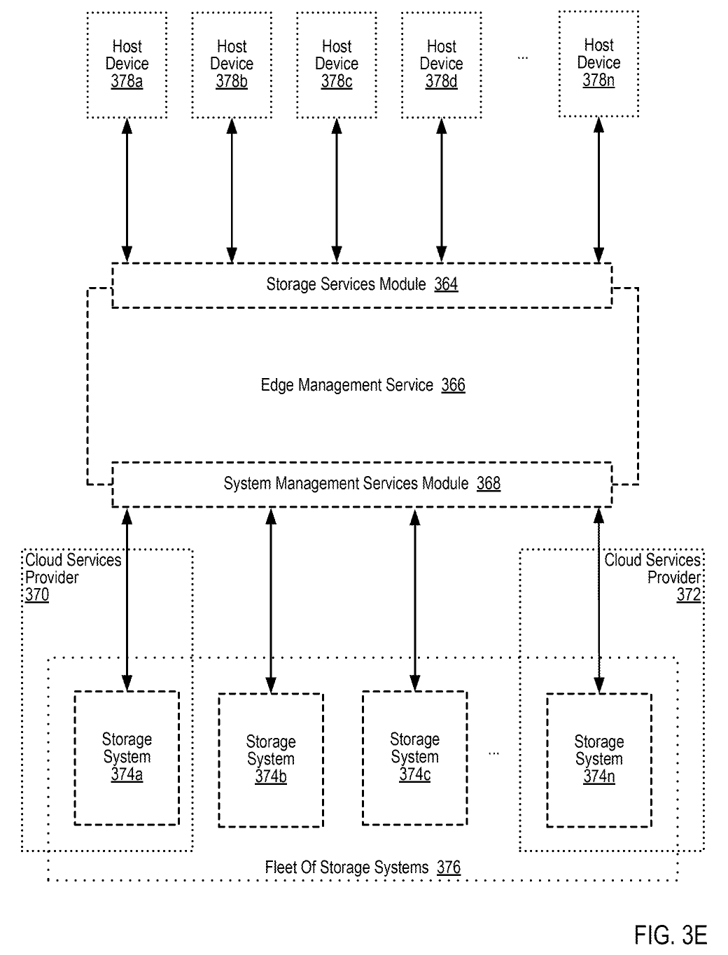

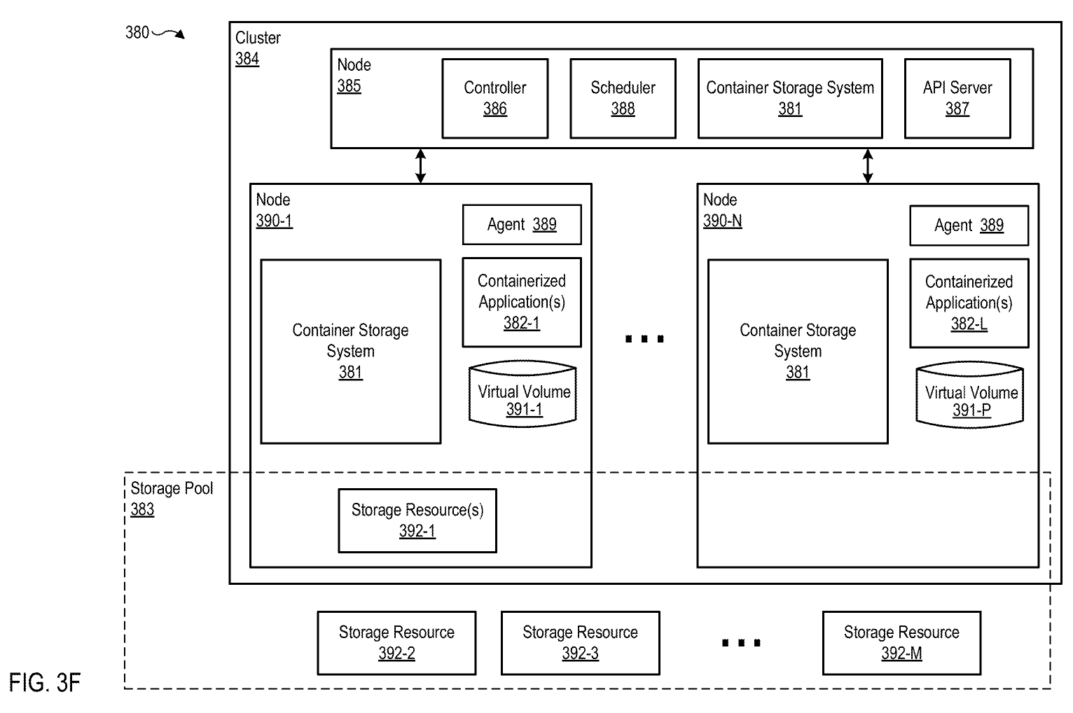

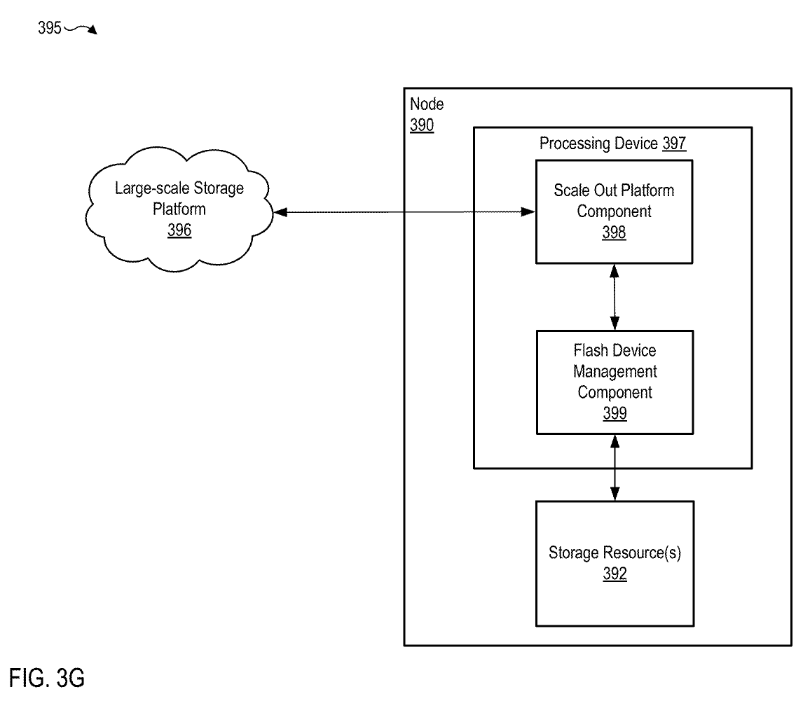

FIG. 3A sets forth a diagram of a storage system 306 that is coupled for data communications with a cloud services provider 302 in accordance with some embodiments of the present disclosure. Although depicted in less detail, the storage system 306 depicted in FIG. 3A may be similar to the storage systems described above with reference to FIGS. 1A-1D and FIGS. 2A-2G. In some embodiments, the storage system 306 depicted in FIG. 3A may be embodied as a storage system that includes imbalanced active/active controllers, as a storage system that includes balanced active/active controllers, as a storage system that includes active/active controllers where less than all of each controller's resources are utilized such that each controller has reserve resources that may be used to support failover, as a storage system that includes fully active/active controllers, as a storage system that includes dataset-segregated controllers, as a storage system that includes dual-layer architectures with front-end controllers and back-end integrated storage controllers, as a storage system that includes scale-out clusters of dual-controller arrays, as well as combinations of such embodiments.

In the example depicted in FIG. 3A, the storage system 306 is coupled to the cloud services provider 302 via a data communications link 304. Such a data communications link 304 may be fully wired, fully wireless, or some aggregation of wired and wireless data communications pathways. In such an example, digital information may be exchanged between the storage system 306 and the cloud services provider 302 via the data communications link 304 using one or more data communications protocols. For example, digital information may be exchanged between the storage system 306 and the cloud services provider 302 via the data communications link 304 using the handheld device transfer protocol ('HDTP'), hypertext transfer protocol ('HTTP'), internet protocol ('IP'), real-time transfer protocol ('RTP'), transmission control protocol ('TCP'), user datagram protocol ('UDP'), wireless application protocol ('WAP'), or other protocol.

The cloud services provider 302 depicted in FIG. 3A may be embodied, for example, as a system and computing environment that provides a vast array of services to users of the cloud services provider 302 through the sharing of computing resources via the data communications link 304. The cloud services provider 302 may provide on-demand access to a shared pool of configurable computing resources such as computer networks, servers, storage, applications and services, and so on.

In the example depicted in FIG. 3A, the cloud services provider 302 may be configured to provide a variety of services to the storage system 306 and users of the storage system 306 through the implementation of various service models. For example, the cloud services provider 302 may be configured to provide services through the implementation of an infrastructure as a service ('IaaS') service model, through the implementation of a platform as a service ('PaaS') service model, through the implementation of a software as a service ('SaaS') service model, through the implementation of an authentication as a service ('AaaS') service model, through the implementation of a storage as a service model where the cloud services provider 302 offers access to its storage infrastructure for use by the storage system 306 and users of the storage system 306, and so on.

In the example depicted in FIG. 3A, the cloud services provider 302 may be embodied, for example, as a private cloud, as a public cloud, or as a combination of a private cloud and public cloud. In an embodiment in which the cloud services provider 302 is embodied as a private cloud, the cloud services provider 302 may be dedicated to providing services to a single organization rather than providing services to multiple organizations. In an embodiment where the cloud services provider 302 is embodied as a public cloud, the cloud services provider 302 may provide services to multiple organizations. In still alternative embodiments, the cloud services provider 302 may be embodied as a mix of a private and public cloud services with a hybrid cloud deployment.

Although not explicitly depicted in FIG. 3A, readers will appreciate that a vast amount of additional hardware components and additional software components may be necessary to facilitate the delivery of cloud services to the storage system 306 and users of the storage system 306. For example, the storage system 306 may be coupled to (or even include) a cloud storage gateway. Such a cloud storage gateway may be embodied, for example, as hardware-based or software-based appliance that is located on premises with the storage system 306. Such a cloud storage gateway may operate as a bridge between local applications that are executing on the storage system 306 and remote, cloud-based storage that is utilized by the storage system 306. Through the use of a cloud storage gateway, organizations may move primary iSCSI or NAS to the cloud services provider 302, thereby enabling the organization to save space on their on-premises storage systems. Such a cloud storage gateway may be configured to emulate a disk array, a block-based device, a file server, or other storage system that can translate the SCSI commands, file server commands, or other appropriate command into REST-space protocols that facilitate communications with the cloud services provider 302.

In order to enable the storage system 306 and users of the storage system 306 to make use of the services provided by the cloud services provider 302, a cloud migration process may take place during which data, applications, or other elements from an organization's local systems (or even from another cloud environment) are moved to the cloud services provider 302. In order to successfully migrate data, applications, or other elements to the cloud services provider's 302 environment, middleware such as a cloud migration tool may be utilized to bridge gaps between the cloud services provider's 302 environment and an organization's environment. In order to further enable the storage system 306 and users of the storage system 306 to make use of the services provided by the cloud services provider 302, a cloud orchestrator may also be used to arrange and coordinate automated tasks in pursuit of creating a consolidated process or workflow. Such a cloud orchestrator may perform tasks such as configuring various components, whether those components are cloud components or on-premises components, as well as managing the interconnections between such components.

In the example depicted in FIG. 3A, and as described briefly above, the cloud services provider 302 may be configured to provide services to the storage system 306 and users of the storage system 306 through the usage of a SaaS service model. For example, the cloud services provider 302 may be configured to provide access to data analytics applications to the storage system 306 and users of the storage system 306. Such data analytics applications may be configured, for example, to receive vast amounts of telemetry data phoned home by the storage system 306. Such telemetry data may describe various operating characteristics of the storage system 306 and may be analyzed for a vast array of purposes including, for example, to determine the health of the storage system 306, to identify workloads that are executing on the storage system 306, to predict when the storage system 306 will run out of various resources, to recommend configuration changes, hardware or software upgrades, workflow migrations, or other actions that may improve the operation of the storage system 306.

The cloud services provider 302 may also be configured to provide access to virtualized computing environments to the storage system 306 and users of the storage system 306. Examples of such virtualized environments can include virtual machines that are created to emulate an actual computer, virtualized desktop environments that separate a logical desktop from a physical machine, virtualized file systems that allow uniform access to different types of concrete file systems, and many others.

Although the example depicted in FIG. 3A illustrates the storage system 306 being coupled for data communications with the cloud services provider 302, in other embodiments the storage system 306 may be part of a hybrid cloud deployment in which private cloud elements (e.g., private cloud services, on-premises infrastructure, and so on) and public cloud elements (e.g., public cloud services, infrastructure, and so on that may be provided by one or more cloud services providers) are combined to form a single solution, with orchestration among the various platforms. Such a hybrid cloud deployment may leverage hybrid cloud management software such as, for example, Azure^{TM} Arc from Microsoft^{TM}, that centralize the management of the hybrid cloud deployment to any infrastructure and enable the deployment of services anywhere. In such an example, the hybrid cloud management software may be configured to create, update, and delete resources (both physical and virtual) that form the hybrid cloud deployment, to allocate compute and storage to specific workloads, to monitor workloads and resources for performance, policy compliance, updates and patches, security status, or to perform a variety of other tasks.

Readers will appreciate that by pairing the storage systems described herein with one or more cloud services providers, various offerings may be enabled. For example, disaster recovery as a service ('DRaaS') may be provided where cloud resources are utilized to protect applications and data from disruption caused by disaster, including in embodiments where the storage systems may serve as the primary data store. In such embodiments, a total system backup may be taken that allows for business continuity in the event of system failure. In such embodiments, cloud data backup techniques (by themselves or as part of a larger DRaaS solution) may also be integrated into an overall solution that includes the storage systems and cloud services providers described herein.

The storage systems described herein, as well as the cloud services providers, may be utilized to provide a wide array of security features. For example, the storage systems may encrypt data at rest (and data may be sent to and from the storage systems encrypted) and may make use of Key Management-as-a-Service ('KMaaS') to manage encryption keys, keys for locking and unlocking storage devices, and so on. Likewise, cloud data security gateways or similar mechanisms may be utilized to ensure that data stored within the storage systems does not improperly end up being stored in the cloud as part of a cloud data backup operation. Furthermore, microsegmentation or identity-based-segmentation may be utilized in a data center that includes the storage systems or within the cloud services provider, to create secure zones in data centers and cloud deployments that enables the isolation of workloads from one another.

For further explanation, FIG. 3B sets forth a diagram of a storage system 306 in accordance with some embodiments of the present disclosure. Although depicted in less detail, the storage system 306 depicted in FIG. 3B may be similar to the storage systems described above with reference to FIGS. 1A-1D and FIGS. 2A-2G as the storage system may include many of the components described above.

The storage system 306 depicted in FIG. 3B may include a vast amount of storage resources 308, which may be embodied in many forms. For example, the storage resources 308 can include nano-RAM or another form of nonvolatile random access memory that utilizes carbon nanotubes deposited on a substrate, 3D crosspoint non-volatile memory, flash memory including single-level cell ('SLC') NAND flash having one bit of data per cell, multi-level cell ('MLC') NAND flash having two bits of data per cell, triple-level cell ('TLC') NAND flash having three bits of data per cell, quad-level cell ('QLC') NAND flash having four bits of data per cell, penta-level cell ('PLC') NAND flash having five bits of data per cell, or other programming modes having different numbers of bits of data per cell of flash memory. Likewise, the storage resources 308 may include non-volatile magnetoresistive random-access memory ('MRAM'), including spin transfer torque ('STT') MRAM. The example storage resources 308 may alternatively include non-volatile phase-change memory ('PCM'), quantum memory that allows for the storage and retrieval of photonic quantum information, resistive random-access memory ('ReRAM'), storage class memory ('SCM'), or other form of storage resources, including any combination of resources described herein. Readers will appreciate that other forms of computer memories and storage devices may be utilized by the storage systems described above, including DRAM, SRAM, EEPROM, universal memory, and many others. The storage resources 308 depicted in FIG. 3A may be embodied in a variety of form factors, including but not limited to, dual in-line memory modules ('DIMMs'), non-volatile dual in-line memory modules ('NVDIMMs'), M.2, U.2, and others. In some embodiments, the storage resources 308 may include one or more managed flash storage devices, as previously described.

The storage resources 308 depicted in FIG. 3B may include various forms of SCM. SCM may effectively treat fast, non-volatile memory (e.g., NAND flash) as an extension of DRAM such that an entire dataset may be treated as an in-memory dataset that resides entirely in DRAM. SCM may include non-volatile media such as, for example, NAND flash. Such NAND flash may be accessed utilizing NVMe that can use the PCIe bus as its transport, providing for relatively low access latencies compared to older protocols. In fact, the network protocols used for SSDs in all-flash arrays can include NVMe using Ethernet (ROCE, NVME TCP), Fibre Channel (NVMe FC), InfiniBand (iWARP), and others that make it possible to treat fast, non-volatile memory as an extension of DRAM. In view of the fact that DRAM is often byte-addressable and fast, non-volatile memory such as NAND flash is block-addressable, a controller software/hardware stack may be needed to convert the block data to the bytes that are stored in the media. Examples of media and software that may be used as SCM can include, for example, 3D XPoint, Intel Memory Drive Technology, Samsung's Z-SSD, and others.

The storage resources 308 depicted in FIG. 3B may also include racetrack memory (also referred to as domain-wall memory). Such racetrack memory may be embodied as a form of non-volatile, solid-state memory that relies on the intrinsic strength and orientation of the magnetic field created by an electron as it spins in addition to its electronic charge, in solid-state devices. Through the use of spin-coherent electric current to move magnetic domains along a nanoscopic permalloy wire, the domains may pass by magnetic read/write heads positioned near the wire as current is passed through the wire, which alter the domains to record patterns of bits. In order to create a racetrack memory device, many such wires and read/write elements may be packaged together.

The example storage system 306 depicted in FIG. 3B may implement a variety of storage architectures. For example, storage systems in accordance with some embodiments of the present disclosure may utilize block storage where data is stored in blocks, and each block essentially acts as an individual hard drive. Storage systems in accordance with some embodiments of the present disclosure may utilize object storage, where data is managed as objects. Each object may include the data itself, a variable amount of metadata, and a globally unique identifier, where object storage can be implemented at multiple levels (e.g., device level, system level, interface level). Storage systems in accordance with some embodiments of the present disclosure utilize file storage in which data is stored in a hierarchical structure. Such data may be saved in files and folders, and presented to both the system storing it and the system retrieving it in the same format.

The example storage system 306 depicted in FIG. 3B may be embodied as a storage system in which additional storage resources can be added through the use of a scale-up model, additional storage resources can be added through the use of a scale-out model, or through some combination thereof. In a scale-up model, additional storage may be added by adding additional storage devices. In a scale-out model, however, additional storage nodes may be added to a cluster of storage nodes, where such storage nodes can include additional processing resources, additional networking resources, and so on.

The example storage system 306 depicted in FIG. 3B may leverage the storage resources described above in a variety of different ways. For example, some portion of the storage resources may be utilized to serve as a write cache, storage resources within the storage system may be utilized as a read cache, or tiering may be achieved within the storage systems by placing data within the storage system in accordance with one or more tiering policies.

The storage system 306 depicted in FIG. 3B also includes communications resources 310 that may be useful in facilitating data communications between components within the storage system 306, as well as data communications between the storage system 306 and computing devices that are outside of the storage system 306, including embodiments where those resources are separated by a relatively vast expanse. The communications resources 310 may be configured to utilize a variety of different protocols and data communication fabrics to facilitate data communications between components within the storage systems as well as computing devices that are outside of the storage system. For example, the communications resources 310 can include fibre channel ('FC') technologies such as FC fabrics and FC protocols that can transport SCSI commands over FC network, FC over ethernet ('FCoE') technologies through which FC frames are encapsulated and transmitted over Ethernet networks, InfiniBand ('IB') technologies in which a switched fabric topology is utilized to facilitate transmissions between channel adapters, NVM Express ('NVMe') technologies and NVMe over fabrics ('NVMeoF') technologies through which non-volatile storage media attached via a PCI express ('PCIe') bus may be accessed, and others. In fact, the storage systems described above may, directly or indirectly, make use of neutrino communication technologies and devices through which information (including binary information) is transmitted using a beam of neutrinos.

The communications resources 310 can also include mechanisms for accessing storage resources 308 within the storage system 306 utilizing serial attached SCSI ('SAS'), serial ATA ('SATA') bus interfaces for connecting storage resources 308 within the storage system 306 to host bus adapters within the storage system 306, internet small computer systems interface ('iSCSI') technologies to provide block-level access to storage resources 308 within the storage system 306, and other communications resources that may be useful in facilitating data communications between components within the storage system 306, as well as data communications between the storage system 306 and computing devices that are outside of the storage system 306.

The storage system 306 depicted in FIG. 3B also includes processing resources 312 that may be useful in executing computer program instructions and performing other computational tasks within the storage system 306. The processing resources 312 may include one or more ASICs that are customized for some particular purpose as well as one or more CPUs. The processing resources 312 may also include one or more DSPs, one or more FPGAs, one or more systems on a chip ('SoCs'), or other form of processing resources 312. The storage system 306 may utilize the processing resources 312 to perform a variety of tasks including, but not limited to, supporting the execution of software resources 314 that will be described in greater detail below.

The storage system 306 depicted in FIG. 3B also includes software resources 314 that, when executed by processing resources 312 within the storage system 306, may perform a vast array of tasks. The software resources 314 may include, for example, one or more modules of computer program instructions that when executed by processing resources 312 within the storage system 306 are useful in carrying out various data protection techniques. Such data protection techniques may be carried out, for example, by system software executing on computer hardware within the storage system, by a cloud services provider, or in other ways. Such data protection techniques can include data archiving, data backup, data replication, data snapshotting, data and database cloning, and other data protection techniques.

The software resources 314 may also include software that is useful in implementing software-defined storage ('SDS'). In such an example, the software resources 314 may include one or more modules of computer program instructions that, when executed, are useful in policy-based provisioning and management of data storage that is independent of the underlying hardware. Such software resources 314 may be useful in implementing storage virtualization to separate the storage hardware from the software that manages the storage hardware.

The software resources 314 may also include software that is useful in facilitating and optimizing I/O operations that are directed to the storage system 306. For example, the software resources 314 may include software modules that perform various data reduction techniques such as, for example, data compression, data deduplication, and others. The software resources 314 may include software modules that intelligently group together I/O operations to facilitate better usage of the underlying storage resource 308, software modules that perform data migration operations to migrate from within a storage system, as well as software modules that perform other functions. Such software resources 314 may be embodied as one or more software containers or in many other ways.

For further explanation, FIG. 3C sets forth an example of a cloud-based storage system 318 in accordance with some embodiments of the present disclosure. In the example depicted in FIG. 3C, the cloud-based storage system 318 is created entirely in a cloud computing environment 316 such as, for example, Amazon Web Services ('AWS')^{TM}, Microsoft Azure^{TM}, Google Cloud Platform^{TM}, IBM Cloud^{TM}, Oracle Cloud^{TM}, and others. The cloud-based storage system 318 may be used to provide services similar to the services that may be provided by the storage systems described above.

The cloud-based storage system 318 depicted in FIG. 3C includes two cloud computing instances 320, 322 that each are used to support the execution of a storage controller application 324, 326. The cloud computing instances 320, 322 may be embodied, for example, as instances of cloud computing resources (e.g., virtual machines) that may be provided by the cloud computing environment 316 to support the execution of software applications such as the storage controller application 324, 326. For example, each of the cloud computing instances 320, 322 may execute on an Azure VM, where each Azure VM may include high speed temporary storage that may be leveraged as a cache (e.g., as a read cache). In one embodiment, the cloud computing instances 320, 322 may be embodied as Amazon Elastic Compute Cloud ('EC2') instances. In such an example, an Amazon Machine Image ('AMI') that includes the storage controller application 324, 326 may be booted to create and configure a virtual machine that may execute the storage controller application 324, 326.

In the example method depicted in FIG. 3C, the storage controller application 324, 326 may be embodied as a module of computer program instructions that, when executed, carries out various storage tasks. For example, the storage controller application 324, 326 may be embodied as a module of computer program instructions that, when executed, carries out the same tasks as the controllers 110A, 110B in FIG. 1A described above such as writing data to the cloud-based storage system 318, erasing data from the cloud-based storage system 318, retrieving data from the cloud-based storage system 318, monitoring and reporting of storage device utilization and performance, performing redundancy operations, such as RAID or RAID-like data redundancy operations, compressing data, encrypting data, deduplicating data, and so forth. Readers will appreciate that because there are two cloud computing instances 320, 322 that each include the storage controller application 324, 326, in some embodiments one cloud computing instance 320 may operate as the primary controller as described above while the other cloud computing instance 322 may operate as the secondary controller as described above. Readers will appreciate that the storage controller application 324, 326 depicted in FIG. 3C may include identical source code that is executed within different cloud computing instances 320, 322 such as distinct EC2 instances.

Readers will appreciate that other embodiments that do not include a primary and secondary controller are within the scope of the present disclosure. For example, each cloud computing instance 320, 322 may operate as a primary controller for some portion of the address space supported by the cloud-based storage system 318, each cloud computing instance 320, 322 may operate as a primary controller where the servicing of I/O operations directed to the cloud-based storage system 318 are divided in some other way, and so on. In fact, in other embodiments where costs savings may be prioritized over performance demands, only a single cloud computing instance may exist that contains the storage controller application.

The cloud-based storage system 318 depicted in FIG. 3C includes cloud computing instances 340a, 340b, 340n with local storage 330, 334, 338. The cloud computing instances 340a, 340b, 340n may be embodied, for example, as instances of cloud computing resources that may be provided by the cloud computing environment 316 to support the execution of software applications. The cloud computing instances 340a, 340b, 340n of FIG. 3C may differ from the cloud computing instances 320, 322 described above as the cloud computing instances 340a, 340b, 340n of FIG. 3C have local storage 330, 334, 338 resources whereas the cloud computing instances 320, 322 that support the execution of the storage controller application 324, 326 need not have local storage resources. The cloud computing instances 340a, 340b, 340n with local storage 330, 334, 338 may be embodied, for example, as EC2 M5 instances that include one or more SSDs, as EC2 R5 instances that include one or more SSDs, as EC2 I3 instances that include one or more SSDs, and so on. In some embodiments, the local storage 330, 334, 338 must be embodied as solid-state storage (e.g., SSDs) rather than storage that makes use of hard disk drives.

In the example depicted in FIG. 3C, each of the cloud computing instances 340a, 340b, 340n with local storage 330, 334, 338 can include a software daemon 328, 332, 336 that, when executed by a cloud computing instance 340a, 340b, 340n can present itself to the storage controller applications 324, 326 as if the cloud computing instance 340a, 340b, 340n were a physical storage device (e.g., one or more SSDs). In such an example, the software daemon 328, 332, 336 may include computer program instructions similar to those that would normally be contained on a storage device such that the storage controller applications 324, 326 can send and receive the same commands that a storage controller would send to storage devices. In such a way, the storage controller applications 324, 326 may include code that is identical to (or substantially identical to) the code that would be executed by the controllers in the storage systems described above. In these and similar embodiments, communications between the storage controller applications 324, 326 and the cloud computing instances 340a, 340b, 340n with local storage 330, 334, 338 may utilize iSCSI, NVMe over TCP, messaging, a custom protocol, or in some other mechanism.

In the example depicted in FIG. 3C, each of the cloud computing instances 340a, 340b, 340n with local storage 330, 334, 338 may also be coupled to block storage 342, 344, 346 that is offered by the cloud computing environment 316 such as, for example, as Amazon Elastic Block Store ('EBS') volumes. In such an example, the block storage 342, 344, 346 that is offered by the cloud computing environment 316 may be utilized in a manner that is similar to how the NVRAM devices described above are utilized, as the software daemon 328, 332, 336 (or some other module) that is executing within a particular cloud computing instance 340a, 340b, 340n may, upon receiving a request to write data, initiate a write of the data to its attached EBS volume as well as a write of the data to its local storage 330, 334, 338 resources. In some alternative embodiments, data may only be written to the local storage 330, 334, 338 resources within a particular cloud computing instance 340a, 340b, 340n. In an alternative embodiment, rather than using the block storage 342, 344, 346 that is offered by the cloud computing environment 316 as NVRAM, actual RAM on each of the cloud computing instances 340a, 340b, 340n with local storage 330, 334, 338 may be used as NVRAM, thereby decreasing network utilization costs that would be associated with using an EBS volume as the NVRAM. In yet another embodiment, high performance block storage resources such as one or more Azure Ultra Disks may be utilized as the NVRAM.

When a request to write data is received by a particular cloud computing instance 340a, 340b, 340n with local storage 330, 334, 338, the software daemon 328, 332, 336 may be configured to not only write the data to its own local storage 330, 334, 338 resources and any appropriate block storage 342, 344, 346 resources, but the software daemon 328, 332, 336 may also be configured to write the data to cloud-based object storage 348 that is attached to the particular cloud computing instance 340a, 340b, 340n. The cloud-based object storage 348 that is attached to the particular cloud computing instance 340a, 340b, 340n may be embodied, for example, as Amazon Simple Storage Service ('S3'). In other embodiments, the cloud computing instances 320, 322 that each include the storage controller application 324, 326 may initiate the storage of the data in the local storage 330, 334, 338 of the cloud computing instances 340a, 340b, 340n and the cloud-based object storage 348. In other embodiments, rather than using both the cloud computing instances 340a, 340b, 340n with local storage 330, 334, 338 (also referred to herein as ‘virtual drives’) and the cloud-based object storage 348 to store data, a persistent storage layer may be implemented in other ways. For example, one or more Azure Ultra disks may be used to persistently store data (e.g., after the data has been written to the NVRAM layer). In an embodiment where one or more Azure Ultra disks may be used to persistently store data, the usage of a cloud-based object storage 348 may be eliminated such that data is only stored persistently in the Azure Ultra disks without also writing the data to an object storage layer.

While the local storage 330, 334, 338 resources and the block storage 342, 344, 346 resources that are utilized by the cloud computing instances 340a, 340b, 340n may support block-level access, the cloud-based object storage 348 that is attached to the particular cloud computing instance 340a, 340b, 340n supports only object-based access. The software daemon 328, 332, 336 may therefore be configured to take blocks of data, package those blocks into objects, and write the objects to the cloud-based object storage 348 that is attached to the particular cloud computing instance 340a, 340b, 340n.

In some embodiments, all data that is stored by the cloud-based storage system 318 may be stored in both: 1) the cloud-based object storage 348, and 2) at least one of the local storage 330, 334, 338 resources or block storage 342, 344, 346 resources that are utilized by the cloud computing instances 340a, 340b, 340n. In such embodiments, the local storage 330, 334, 338 resources and block storage 342, 344, 346 resources that are utilized by the cloud computing instances 340a, 340b, 340n may effectively operate as cache that generally includes all data that is also stored in S3, such that all reads of data may be serviced by the cloud computing instances 340a, 340b, 340n without requiring the cloud computing instances 340a, 340b, 340n to access the cloud-based object storage 348. Readers will appreciate that in other embodiments, however, all data that is stored by the cloud-based storage system 318 may be stored in the cloud-based object storage 348, but less than all data that is stored by the cloud-based storage system 318 may be stored in at least one of the local storage 330, 334, 338 resources or block storage 342, 344, 346 resources that are utilized by the cloud computing instances 340a, 340b, 340n. In such an example, various policies may be utilized to determine which subset of the data that is stored by the cloud-based storage system 318 should reside in both: 1) the cloud-based object storage 348, and 2) at least one of the local storage 330, 334, 338 resources or block storage 342, 344, 346 resources that are utilized by the cloud computing instances 340a, 340b, 340n.

One or more modules of computer program instructions that are executing within the cloud-based storage system 318 (e.g., a monitoring module that is executing on its own EC2 instance) may be designed to handle the failure of one or more of the cloud computing instances 340a, 340b, 340n with local storage 330, 334, 338. In such an example, the monitoring module may handle the failure of one or more of the cloud computing instances 340a, 340b, 340n with local storage 330, 334, 338 by creating one or more new cloud computing instances with local storage, retrieving data that was stored on the failed cloud computing instances 340a, 340b, 340n from the cloud-based object storage 348, and storing the data retrieved from the cloud-based object storage 348 in local storage on the newly created cloud computing instances. Readers will appreciate that many variants of this process may be implemented.

Readers will appreciate that various performance aspects of the cloud-based storage system 318 may be monitored (e.g., by a monitoring module that is executing in an EC2 instance) such that the cloud-based storage system 318 can be scaled-up or scaled-out as needed. For example, if the cloud computing instances 320, 322 that are used to support the execution of a storage controller application 324, 326 are undersized and not sufficiently servicing the I/O requests that are issued by users of the cloud-based storage system 318, a monitoring module may create a new, more powerful cloud computing instance (e.g., a cloud computing instance of a type that includes more processing power, more memory, etc…) that includes the storage controller application such that the new, more powerful cloud computing instance can begin operating as the primary controller. Likewise, if the monitoring module determines that the cloud computing instances 320, 322 that are used to support the execution of a storage controller application 324, 326 are oversized and that cost savings could be gained by switching to a smaller, less powerful cloud computing instance, the monitoring module may create a new, less powerful (and less expensive) cloud computing instance that includes the storage controller application such that the new, less powerful cloud computing instance can begin operating as the primary controller.

The storage systems described above may carry out intelligent data backup techniques through which data stored in the storage system may be copied and stored in a distinct location to avoid data loss in the event of equipment failure or some other form of catastrophe. For example, the storage systems described above may be configured to examine each backup to avoid restoring the storage system to an undesirable state. Consider an example in which malware infects the storage system. In such an example, the storage system may include software resources 314 that can scan each backup to identify backups that were captured before the malware infected the storage system and those backups that were captured after the malware infected the storage system. In such an example, the storage system may restore itself from a backup that does not include the malware - or at least not restore the portions of a backup that contained the malware. In such an example, the storage system may include software resources 314 that can scan each backup to identify the presences of malware (or a virus, or some other undesirable), for example, by identifying write operations that were serviced by the storage system and originated from a network subnet that is suspected to have delivered the malware, by identifying write operations that were serviced by the storage system and originated from a user that is suspected to have delivered the malware, by identifying write operations that were serviced by the storage system and examining the content of the write operation against fingerprints of the malware, and in many other ways.

Readers will further appreciate that the backups (often in the form of one or more snapshots) may also be utilized to perform rapid recovery of the storage system. Consider an example in which the storage system is infected with ransomware that locks users out of the storage system. In such an example, software resources 314 within the storage system may be configured to detect the presence of ransomware and may be further configured to restore the storage system to a point-in-time, using the retained backups, prior to the point-in-time at which the ransomware infected the storage system. In such an example, the presence of ransomware may be explicitly detected through the use of software tools utilized by the system, through the use of a key (e.g., a USB drive) that is inserted into the storage system, or in a similar way. Likewise, the presence of ransomware may be inferred in response to system activity meeting a predetermined fingerprint such as, for example, no reads or writes coming into the system for a predetermined period of time.

Readers will appreciate that the various components described above may be grouped into one or more optimized computing packages as converged infrastructures. Such converged infrastructures may include pools of computers, storage and networking resources that can be shared by multiple applications and managed in a collective manner using policy-driven processes. Such converged infrastructures may be implemented with a converged infrastructure reference architecture, with standalone appliances, with a software driven hyper-converged approach (e.g., hyper-converged infrastructures), or in other ways.

Readers will appreciate that the storage systems described in this disclosure may be useful for supporting various types of software applications. In fact, the storage systems may be ‘application aware’ in the sense that the storage systems may obtain, maintain, or otherwise have access to information describing connected applications (e.g., applications that utilize the storage systems) to optimize the operation of the storage system based on intelligence about the applications and their utilization patterns. For example, the storage system may optimize data layouts, optimize caching behaviors, optimize ‘QoS’ levels, or perform some other optimization that is designed to improve the storage performance that is experienced by the application.

As an example of one type of application that may be supported by the storage systems described herein, the storage system 306 may be useful in supporting artificial intelligence ('AI') applications, database applications, XOps projects (e.g., DevOps projects, DataOps projects, MLOps projects, ModelOps projects, PlatformOps projects), electronic design automation tools, event-driven software applications, high performance computing applications, simulation applications, high-speed data capture and analysis applications, machine learning applications, media production applications, media serving applications, picture archiving and communication systems ('PACS') applications, software development applications, virtual reality applications, augmented reality applications, and many other types of applications by providing storage resources to such applications.

In view of the fact that the storage systems include compute resources, storage resources, and a wide variety of other resources, the storage systems may be well suited to support applications that are resource intensive such as, for example, AI applications. AI applications may be deployed in a variety of fields, including: predictive maintenance in manufacturing and related fields, healthcare applications such as patient data & risk analytics, retail and marketing deployments (e.g., search advertising, social media advertising), supply chains solutions, fintech solutions such as business analytics & reporting tools, operational deployments such as real-time analytics tools, application performance management tools, IT infrastructure management tools, and many others.

Such AI applications may enable devices to perceive their environment and take actions that maximize their chance of success at some goal. Examples of such AI applications can include IBM Watson^{TM}, Microsoft Oxford^{TM}, Google DeepMind^{TM}, Baidu Minwa^{TM}, and others.

The storage systems described above may also be well suited to support other types of applications that are resource intensive such as, for example, machine learning applications. Machine learning applications may perform various types of data analysis to automate analytical model building. Using algorithms that iteratively learn from data, machine learning applications can enable computers to learn without being explicitly programmed. One particular area of machine learning is referred to as reinforcement learning, which involves taking suitable actions to maximize reward in a particular situation.

In addition to the resources already described, the storage systems described above may also include graphics processing units ('GPUs'), occasionally referred to as visual processing unit ('VPUs'). Such GPUs may be embodied as specialized electronic circuits that rapidly manipulate and alter memory to accelerate the creation of images in a frame buffer intended for output to a display device. Such GPUs may be included within any of the computing devices that are part of the storage systems described above, including as one of many individually scalable components of a storage system, where other examples of individually scalable components of such storage system can include storage components, memory components, compute components (e.g., CPUs, FPGAs, ASICs), networking components, software components, and others. In addition to GPUs, the storage systems described above may also include neural network processors ('NNPs') for use in various aspects of neural network processing. Such NNPs may be used in place of (or in addition to) GPUs and may also be independently scalable.

As described above, the storage systems described herein may be configured to support artificial intelligence applications, machine learning applications, big data analytics applications, and many other types of applications. The rapid growth in these sort of applications is being driven by three technologies: deep learning (DL), GPU processors, and Big Data. Deep learning is a computing model that makes use of massively parallel neural networks inspired by the human brain. Instead of experts handcrafting software, a deep learning model writes its own software by learning from lots of examples. Such GPUs may include thousands of cores that are well-suited to run algorithms that loosely represent the parallel nature of the human brain.

Advances in deep neural networks, including the development of multi-layer neural networks, have ignited a new wave of algorithms and tools for data scientists to tap into their data with artificial intelligence (AI). With improved algorithms, larger data sets, and various frameworks (including open-source software libraries for machine learning across a range of tasks), data scientists are tackling new use cases like autonomous driving vehicles, natural language processing and understanding, computer vision, machine reasoning, strong AI, and many others. Applications of AI techniques have materialized in a wide array of products include, for example, Amazon Echo's speech recognition technology that allows users to talk to their machines, Google Translate™ which allows for machine-based language translation, Spotify's Discover Weekly that provides recommendations on new songs and artists that a user may like based on the user's usage and traffic analysis, Quill's text generation offering that takes structured data and turns it into narrative stories, Chatbots that provide real-time, contextually specific answers to questions in a dialog format, and many others.

Data is the heart of modern AI and deep learning algorithms. Before training can begin, one problem that must be addressed revolves around collecting the labeled data that is crucial for training an accurate AI model. A full scale AI deployment may be required to continuously collect, clean, transform, label, and store large amounts of data. Adding additional high quality data points directly translates to more accurate models and better insights. Data samples may undergo a series of processing steps including, but not limited to: 1) ingesting the data from an external source into the training system and storing the data in raw form, 2) cleaning and transforming the data in a format convenient for training, including linking data samples to the appropriate label, 3) exploring parameters and models, quickly testing with a smaller dataset, and iterating to converge on the most promising models to push into the production cluster, 4) executing training phases to select random batches of input data, including both new and older samples, and feeding those into production GPU servers for computation to update model parameters, and 5) evaluating including using a holdback portion of the data not used in training in order to evaluate model accuracy on the holdout data. This lifecycle may apply for any type of parallelized machine learning, not just neural networks or deep learning. For example, standard machine learning frameworks may rely on CPUs instead of GPUs but the data ingest and training workflows may be the same. Readers will appreciate that a single shared storage data hub creates a coordination point throughout the lifecycle without the need for extra data copies among the ingest, preprocessing, and training stages. Rarely is the ingested data used for only one purpose, and shared storage gives the flexibility to train multiple different models or apply traditional analytics to the data.

Readers will appreciate that each stage in the AI data pipeline may have varying requirements from the data hub (e.g., the storage system or collection of storage systems). Scale-out storage systems must deliver uncompromising performance for all manner of access types and patterns - from small, metadata-heavy to large files, from random to sequential access patterns, and from low to high concurrency. The storage systems described above may serve as an ideal AI data hub as the systems may service unstructured workloads. In the first stage, data is ideally ingested and stored on to the same data hub that following stages will use, in order to avoid excess data copying. The next two steps can be done on a standard compute server that optionally includes a GPU, and then in the fourth and last stage, full training production jobs are run on powerful GPU-accelerated servers. Often, there is a production pipeline alongside an experimental pipeline operating on the same dataset. Further, the GPU-accelerated servers can be used independently for different models or joined together to train on one larger model, even spanning multiple systems for distributed training. If the shared storage tier is slow, then data must be copied to local storage for each phase, resulting in wasted time staging data onto different servers. The ideal data hub for the AI training pipeline delivers performance similar to data stored locally on the server node while also having the simplicity and performance to enable all pipeline stages to operate concurrently.

In order for the storage systems described above to serve as a data hub or as part of an AI deployment, in some embodiments the storage systems may be configured to provide DMA between storage devices that are included in the storage systems and one or more GPUs that are used in an AI or big data analytics pipeline. The one or more GPUs may be coupled to the storage system, for example, via NVMe-over-Fabrics ('NVMe-oF') such that bottlenecks such as the host CPU can be bypassed and the storage system (or one of the components contained therein) can directly access GPU memory. In such an example, the storage systems may leverage API hooks to the GPUs to transfer data directly to the GPUs. For example, the GPUs may be embodied as Nvidia^{TM} GPUs and the storage systems may support GPUDirect Storage ('GDS') software, or have similar proprietary software, that enables the storage system to transfer data to the GPUs via RDMA or similar mechanism.

Although the preceding paragraphs discuss deep learning applications, readers will appreciate that the storage systems described herein may also be part of a distributed deep learning ('DDL') platform to support the execution of DDL algorithms. The storage systems described above may also be paired with other technologies such as TensorFlow, an open-source software library for dataflow programming across a range of tasks that may be used for machine learning applications such as neural networks, to facilitate the development of such machine learning models, applications, and so on.

Readers will appreciate that, as part of an effort to support AI workloads, the storage systems described above may be configured to operate as a vector database that stores data as vectors (i.e., as mathematical representations of data), where the vector database is designed to efficiently store and query high-dimensional vector data. For example, the storage systems may operate as a vector database that stores vector embeddings that can be useful in machine learning and AI applications, including generative AI applications such as Large Language Models (‘LLMs’). In such embodiments, metadata that is managed by the storage system controllers or by some other entity may be used to manage and identify entries in the vector database. In such embodiments, the vector representations may not be directly stored in a database, but instead the metadata may describe how to generate the vector representations from the underlying data. Alternatively, the storage systems may be used to provide the storage for a vector database, such that the storage systems are effectively preconfigured to provide the functionality of a vector database. In such an example, the vector database may be accessed via APIs provided by the storage system controllers, via one or more APIs that are provided in some other way, via one or more CLIs, or in some other way.

The storage systems described above may also be used in a neuromorphic computing environment. Neuromorphic computing is a form of computing that mimics brain cells. To support neuromorphic computing, an architecture of interconnected "neurons" replace traditional computing models with low-powered signals that go directly between neurons for more efficient computation. Neuromorphic computing may make use of very-large-scale integration (VLSI) systems containing electronic analog circuits to mimic neuro-biological architectures present in the nervous system, as well as analog, digital, mixed-mode analog/digital VLSI, and software systems that implement models of neural systems for perception, motor control, or multisensory integration.

Readers will appreciate that the storage systems described above may be configured to support the storage or use of (among other types of data) blockchains and derivative items such as, for example, open source blockchains and related tools that are part of the IBM^{TM} Hyperledger project, permissioned blockchains in which a certain number of trusted parties are allowed to access the block chain, blockchain products that enable developers to build their own distributed ledger projects, and others. Blockchains and the storage systems described herein may be leveraged to support on-chain storage of data as well as off-chain storage of data.

The storage systems described above may, either alone or in combination with other computing devices, be used to support in-memory computing applications. In-memory computing involves the storage of information in RAM that is distributed across a cluster of computers. Readers will appreciate that the storage systems described above, especially those that are configurable with customizable amounts of processing resources, storage resources, and memory resources (e.g., those systems in which blades contain configurable amounts of each type of resource), may be configured in a way so as to provide an infrastructure that can support in-memory computing. Likewise, the storage systems described above may include component parts (e.g., NVDIMMs, 3D crosspoint storage that provide fast random access memory that is persistent) that can actually provide for an improved in-memory computing environment as compared to in-memory computing environments that rely on RAM distributed across dedicated servers.

In some embodiments, the storage systems described above may be configured to operate as a hybrid in-memory computing environment that includes a universal interface to all storage media (e.g., RAM, flash storage, 3D crosspoint storage). In such embodiments, users may have no knowledge regarding the details of where their data is stored but they can still use the same full, unified API to address data. In such embodiments, the storage system may (in the background) move data to the fastest layer available - including intelligently placing the data in dependence upon various characteristics of the data or in dependence upon some other heuristic. In such an example, the storage systems may even make use of existing products such as Apache Ignite and GridGain to move data between the various storage layers, or the storage systems may make use of custom software to move data between the various storage layers. The storage systems described herein may implement various optimizations to improve the performance of in-memory computing such as, for example, having computations occur as close to the data as possible.

Readers will further appreciate that in some embodiments, the storage systems described above may be paired with other resources to support the applications described above. For example, one infrastructure could include primary compute in the form of servers and workstations which specialize in using General-purpose computing on graphics processing units ('GPGPU') to accelerate deep learning applications that are interconnected into a computation engine to train parameters for deep neural networks. Each system may have Ethernet external connectivity, InfiniBand external connectivity, some other form of external connectivity, or some combination thereof. In such an example, the GPUs can be grouped for a single large training or used independently to train multiple models. The infrastructure could also include a storage system such as those described above to provide, for example, a scale-out all-flash file or object store through which data can be accessed via high-performance protocols such as NFS, S3, and so on. The infrastructure can also include, for example, redundant top-of-rack Ethernet switches connected to storage and compute via ports in MLAG port channels for redundancy. The infrastructure could also include additional compute in the form of whitebox servers, optionally with GPUs, for data ingestion, pre-processing, and model debugging. Readers will appreciate that additional infrastructures are also possible.

Readers will appreciate that the storage systems described above, either alone or in coordination with other computing machinery may be configured to support other AI related tools. For example, the storage systems may make use of tools like ONXX or other open neural network exchange formats that make it easier to transfer models written in different AI frameworks. Likewise, the storage systems may be configured to support tools like Amazon's Gluon that allow developers to prototype, build, and train deep learning models. In fact, the storage systems described above may be part of a larger platform, such as IBM^{TM} Cloud Private for Data, that includes integrated data science, data engineering and application building services.

Readers will further appreciate that the storage systems described above may also be deployed as an edge solution. Such an edge solution may be in place to optimize cloud computing systems by performing data processing at the edge of the network, near the source of the data. Edge computing can push applications, data and computing power (i.e., services) away from centralized points to the logical extremes of a network. Through the use of edge solutions such as the storage systems described above, computational tasks may be performed using the compute resources provided by such storage systems, data may be storage using the storage resources of the storage system, and cloud-based services may be accessed through the use of various resources of the storage system (including networking resources). By performing computational tasks on the edge solution, storing data on the edge solution, and generally making use of the edge solution, the consumption of expensive cloud-based resources may be avoided and, in fact, performance improvements may be experienced relative to a heavier reliance on cloud-based resources.

While many tasks may benefit from the utilization of an edge solution, some particular uses may be especially suited for deployment in such an environment. For example, devices like drones, autonomous cars, robots, and others may require extremely rapid processing - so fast, in fact, that sending data up to a cloud environment and back to receive data processing support may simply be too slow. As an additional example, some IoT devices such as connected video cameras may not be well-suited for the utilization of cloud-based resources as it may be impractical (not only from a privacy perspective, security perspective, or a financial perspective) to send the data to the cloud simply because of the pure volume of data that is involved. As such, many tasks that really on data processing, storage, or communications may be better suited by platforms that include edge solutions such as the storage systems described above.

The storage systems described above may alone, or in combination with other computing resources, serves as a network edge platform that combines compute resources, storage resources, networking resources, cloud technologies and network virtualization technologies, and so on. As part of the network, the edge may take on characteristics similar to other network facilities, from the customer premise and backhaul aggregation facilities to Points of Presence (PoPs) and regional data centers. Readers will appreciate that network workloads, such as Virtual Network Functions (VNFs) and others, will reside on the network edge platform. Enabled by a combination of containers and virtual machines, the network edge platform may rely on controllers and schedulers that are no longer geographically co-located with the data processing resources. The functions, as microservices, may split into control planes, user and data planes, or even state machines, allowing for independent optimization and scaling techniques to be applied. Such user and data planes may be enabled through increased accelerators, both those residing in server platforms, such as FPGAs and Smart NICs, and through SDN-enabled merchant silicon and programmable ASICs.

The storage systems described above may also be optimized for use in big data analytics, including being leveraged as part of a composable data analytics pipeline where containerized analytics architectures, for example, make analytics capabilities more composable. Big data analytics may be generally described as the process of examining large and varied data sets to uncover hidden patterns, unknown correlations, market trends, customer preferences and other useful information that can help organizations make more-informed business decisions. As part of that process, semi-structured and unstructured data such as, for example, internet clickstream data, web server logs, social media content, text from customer emails and survey responses, mobile-phone call-detail records, IoT sensor data, and other data may be converted to a structured form.

The storage systems described above may also support (including implementing as a system interface) applications that perform tasks in response to human speech. For example, the storage systems may support the execution of intelligent personal assistant applications such as, for example, Amazon's Alexa^{TM}, Apple Siri^{TM}, Google Voice^{TM}, Samsung Bixby^{TM}, Microsoft Cortana^{TM}, and others. While the examples described in the previous sentence make use of voice as input, the storage systems described above may also support chatbots, talkbots, chatterbots, or artificial conversational entities or other applications that are configured to conduct a conversation via auditory or textual methods. Likewise, the storage system may actually execute such an application to enable a user such as a system administrator to interact with the storage system via speech. Such applications are generally capable of voice interaction, music playback, making to-do lists, setting alarms, streaming podcasts, playing audiobooks, and providing weather, traffic, and other real time information, such as news, although in embodiments in accordance with the present disclosure, such applications may be utilized as interfaces to various system management operations.

The storage systems described above may also implement AI platforms for delivering on the vision of self-driving storage. Such AI platforms may be configured to deliver global predictive intelligence by collecting and analyzing large amounts of storage system telemetry data points to enable effortless management, analytics and support. In fact, such storage systems may be capable of predicting both capacity and performance, as well as generating intelligent advice on workload deployment, interaction and optimization. Such AI platforms may be configured to scan all incoming storage system telemetry data against a library of issue fingerprints to predict and resolve incidents in real-time, before they impact customer environments, and captures hundreds of variables related to performance that are used to forecast performance load.

The storage systems described above may support the serialized or simultaneous execution of artificial intelligence applications, machine learning applications, data analytics applications, data transformations, and other tasks that collectively may form an AI ladder. Such an AI ladder may effectively be formed by combining such elements to form a complete data science pipeline, where exist dependencies between elements of the AI ladder. For example, AI may require that some form of machine learning has taken place, machine learning may require that some form of analytics has taken place, analytics may require that some form of data and information architecting has taken place, and so on. As such, each element may be viewed as a rung in an AI ladder that collectively can form a complete and sophisticated AI solution.

The storage systems described above may also, either alone or in combination with other computing environments, be used to deliver an AI everywhere experience where AI permeates wide and expansive aspects of business and life. For example, AI may play an important role in the delivery of deep learning solutions, deep reinforcement learning solutions, artificial general intelligence solutions, autonomous vehicles, cognitive computing solutions, commercial UAVs or drones, conversational user interfaces, enterprise taxonomies, ontology management solutions, machine learning solutions, smart dust, smart robots, smart workplaces, and many others.

The storage systems described above may also be part of a multi-cloud environment in which multiple cloud computing and storage services are deployed in a single heterogeneous architecture. In order to facilitate the operation of such a multi-cloud environment, DevOps tools may be deployed to enable orchestration across clouds. Likewise, continuous development and continuous integration tools may be deployed to standardize processes around continuous integration and delivery, new feature rollout and provisioning cloud workloads. By standardizing these processes, a multi-cloud strategy may be implemented that enables the utilization of the best provider for each workload.

The storage systems described above may be used as a part of a platform to enable the use of crypto-anchors that may be used to authenticate a product's origins and contents to ensure that it matches a blockchain record associated with the product. Similarly, as part of a suite of tools to secure data stored on the storage system, the storage systems described above may implement various encryption technologies and schemes, including lattice cryptography. Lattice cryptography can involve constructions of cryptographic primitives that involve lattices, either in the construction itself or in the security proof. Unlike public-key schemes such as the RSA, Diffie-Hellman or Elliptic-Curve cryptosystems, which are easily attacked by a quantum computer, some lattice-based constructions appear to be resistant to attack by both classical and quantum computers.

A quantum computer is a device that performs quantum computing. Quantum computing is computing using quantum-mechanical phenomena, such as superposition and entanglement. Quantum computers differ from traditional computers that are based on transistors, as such traditional computers require that data be encoded into binary digits (bits), each of which is always in one of two definite states (0 or 1). In contrast to traditional computers, quantum computers use quantum bits, which can be in superpositions of states. A quantum computer maintains a sequence of qubits, where a single qubit can represent a one, a zero, or any quantum superposition of those two qubit states. A pair of qubits can be in any quantum superposition of 4 states, and three qubits in any superposition of 8 states. A quantum computer with n qubits can generally be in an arbitrary superposition of up to 2^n different states simultaneously, whereas a traditional computer can only be in one of these states at any one time. A quantum Turing machine is a theoretical model of such a computer.

The storage systems described above may also be paired with FPGA-accelerated servers as part of a larger AI or ML infrastructure. Such FPGA-accelerated servers may reside near (e.g., in the same data center) the storage systems described above or even incorporated into an appliance that includes one or more storage systems, one or more FPGA-accelerated servers, networking infrastructure that supports communications between the one or more storage systems and the one or more FPGA-accelerated servers, as well as other hardware and software components. Alternatively, FPGA-accelerated servers may reside within a cloud computing environment that may be used to perform compute-related tasks for AI and ML jobs. Any of the embodiments described above may be used to collectively serve as a FPGA-based AI or ML platform. Readers will appreciate that, in some embodiments of the FPGA-based AI or ML platform, the FPGAs that are contained within the FPGA-accelerated servers may be reconfigured for different types of ML models (e.g., LSTMs, CNNs, GRUs). The ability to reconfigure the FPGAs that are contained within the FPGA-accelerated servers may enable the acceleration of a ML or AI application based on the most optimal numerical precision and memory model being used. Readers will appreciate that by treating the collection of FPGA-accelerated servers as a pool of FPGAs, any CPU in the data center may utilize the pool of FPGAs as a shared hardware microservice, rather than limiting a server to dedicated accelerators plugged into it.

The FPGA-accelerated servers and the GPU-accelerated servers described above may implement a model of computing where, rather than keeping a small amount of data in a CPU and running a long stream of instructions over it as occurred in more traditional computing models, the machine learning model and parameters are pinned into the high-bandwidth on-chip memory with lots of data streaming through the high-bandwidth on-chip memory. FPGAs may even be more efficient than GPUs for this computing model, as the FPGAs can be programmed with only the instructions needed to run this kind of computing model.

The storage systems described above may be configured to provide parallel storage, for example, through the use of a parallel file system such as BeeGFS. Such parallel files systems may include a distributed metadata architecture. For example, the parallel file system may include a plurality of metadata servers across which metadata is distributed, as well as components that include services for clients and storage servers.

The systems described above can support the execution of a wide array of software applications. Such software applications can be deployed in a variety of ways, including container-based deployment models. Containerized applications may be managed using a variety of tools. For example, containerized applications may be managed using Docker Swarm, Kubernetes, and others. Containerized applications may be used to facilitate a serverless, cloud native computing deployment and management model for software applications. In support of a serverless, cloud native computing deployment and management model for software applications, containers may be used as part of an event handling mechanisms (e.g., AWS Lambdas) such that various events cause a containerized application to be spun up to operate as an event handler.

The storage systems described above may also be configured to implement NVMe Zoned Namespaces. Through the use of NVMe Zoned Namespaces, the logical address space of a namespace is divided into zones. Each zone provides a logical block address range that must be written sequentially and explicitly reset before rewriting, thereby enabling the creation of namespaces that expose the natural boundaries of the device and offload management of internal mapping tables to the host. In order to implement NVMe Zoned Name Spaces ('ZNS'), ZNS SSDs or some other form of zoned block devices may be utilized that expose a namespace logical address space using zones. With the zones aligned to the internal physical properties of the device, several inefficiencies in the placement of data can be eliminated. In such embodiments, each zone may be mapped, for example, to a separate application such that functions like wear levelling and garbage collection could be performed on a per-zone or per-application basis rather than across the entire device. In order to support ZNS, the storage controllers described herein may be configured with to interact with zoned block devices through the usage of, for example, the Linux^{TM} kernel zoned block device interface or other tools.

The storage systems described above may also be configured to implement zoned storage in other ways such as, for example, through the usage of shingled magnetic recording (SMR) storage devices. In examples where zoned storage is used, device-managed embodiments may be deployed where the storage devices hide this complexity by managing it in the firmware, presenting an interface like any other storage device. Alternatively, zoned storage may be implemented via a host-managed embodiment that depends on the operating system to know how to handle the drive, and only write sequentially to certain regions of the drive. Zoned storage may similarly be implemented using a host-aware embodiment in which a combination of a drive managed and host managed implementation is deployed.

The storage systems described herein may be used to form a data lake. A data lake may operate as the first place that an organization’s data flows to, where such data may be in a raw format. Metadata tagging may be implemented to facilitate searches of data elements in the data lake, especially in embodiments where the data lake contains multiple stores of data, in formats not easily accessible or readable (e.g., unstructured data, semi-structured data, structured data). From the data lake, data may go downstream to a data warehouse where data may be stored in a more processed, packaged, and consumable format. The storage systems described above may also be used to implement such a data warehouse. In addition, a data mart or data hub may allow for data that is even more easily consumed, where the storage systems described above may also be used to provide the underlying storage resources necessary for a data mart or data hub. In embodiments, queries the data lake may require a schema-on-read approach, where data is applied to a plan or schema as it is pulled out of a stored location, rather than as it goes into the stored location.

The storage systems described herein may also be configured to implement a recovery point objective (‘RPO’), which may be establish by a user, established by an administrator, established as a system default, established as part of a storage class or service that the storage system is participating in the delivery of, or in some other way. A “recovery point objective” is a goal for the maximum time difference between the last update to a source dataset and the last recoverable replicated dataset update that would be correctly recoverable, given a reason to do so, from a continuously or frequently updated copy of the source dataset. An update is correctly recoverable if it properly takes into account all updates that were processed on the source dataset prior to the last recoverable replicated dataset update.

In synchronous replication, the RPO would be zero, meaning that under normal operation, all completed updates on the source dataset should be present and correctly recoverable on the copy dataset. In best effort nearly synchronous replication, the RPO can be as low as a few seconds. In snapshot-based replication, the RPO can be roughly calculated as the interval between snapshots plus the time to transfer the modifications between a previous already transferred snapshot and the most recent to-be-replicated snapshot.

If updates accumulate faster than they are replicated, then an RPO can be missed. If more data to be replicated accumulates between two snapshots, for snapshot-based replication, than can be replicated between taking the snapshot and replicating that snapshot’s cumulative updates to the copy, then the RPO can be missed. If, again in snapshot-based replication, data to be replicated accumulates at a faster rate than could be transferred in the time between subsequent snapshots, then replication can start to fall further behind which can extend the miss between the expected recovery point objective and the actual recovery point that is represented by the last correctly replicated update.

The storage systems described above may also be part of a shared nothing storage cluster. In a shared nothing storage cluster, each node of the cluster has local storage and communicates with other nodes in the cluster through networks, where the storage used by the cluster is (in general) provided only by the storage connected to each individual node. A collection of nodes that are synchronously replicating a dataset may be one example of a shared nothing storage cluster, as each storage system has local storage and communicates to other storage systems through a network, where those storage systems do not (in general) use storage from somewhere else that they share access to through some kind of interconnect. In contrast, some of the storage systems described above are themselves built as a shared-storage cluster, since there are drive shelves that are shared by the paired controllers. Other storage systems described above, however, are built as a shared nothing storage cluster, as all storage is local to a particular node (e.g., a blade) and all communication is through networks that link the compute nodes together.

In other embodiments, other forms of a shared nothing storage cluster can include embodiments where any node in the cluster has a local copy of all storage they need, and where data is mirrored through a synchronous style of replication to other nodes in the cluster either to ensure that the data isn't lost or because other nodes are also using that storage. In such an embodiment, if a new cluster node needs some data, that data can be copied to the new node from other nodes that have copies of the data.

In some embodiments, mirror-copy-based shared storage clusters may store multiple copies of all the cluster's stored data, with each subset of data replicated to a particular set of nodes, and different subsets of data replicated to different sets of nodes. In some variations, embodiments may store all of the cluster's stored data in all nodes, whereas in other variations nodes may be divided up such that a first set of nodes will all store the same set of data and a second, different set of nodes will all store a different set of data.

Readers will appreciate that RAFT-based databases (e.g., etcd) may operate like shared-nothing storage clusters where all RAFT nodes store all data. The amount of data stored in a RAFT cluster, however, may be limited so that extra copies don’t consume too much storage. A container server cluster might also be able to replicate all data to all cluster nodes, presuming the containers don’t tend to be too large and their bulk data (the data manipulated by the applications that run in the containers) is stored elsewhere such as in an S3 cluster or an external file server. In such an example, the container storage may be provided by the cluster directly through its shared-nothing storage model, with those containers providing the images that form the execution environment for parts of an application or service.

For further explanation, FIG. 3D illustrates an exemplary computing device 350 that may be specifically configured to perform one or more of the processes described herein. As shown in FIG. 3D, computing device 350 may include a communication interface 352, a processor 354, a storage device 356, and an input/output ("I/O") module 358 communicatively connected one to another via a communication infrastructure 360. While an exemplary computing device 350 is shown in FIG. 3D, the components illustrated in FIG. 3D are not intended to be limiting. Additional or alternative components may be used in other embodiments. Components of computing device 350 shown in FIG. 3D will now be described in additional detail.

Communication interface 352 may be configured to communicate with one or more computing devices. Examples of communication interface 352 include, without limitation, a wired network interface (such as a network interface card), a wireless network interface (such as a wireless network interface card), a modem, an audio/video connection, and any other suitable interface.

Processor 354 generally represents any type or form of processing unit capable of processing data and/or interpreting, executing, and/or directing execution of one or more of the instructions, processes, and/or operations described herein. Processor 354 may perform operations by executing computer-executable instructions 362 (e.g., an application, software, code, and/or other executable data instance) stored in storage device 356.

Storage device 356 may include one or more data storage media, devices, or configurations and may employ any type, form, and combination of data storage media and/or device. For example, storage device 356 may include, but is not limited to, any combination of the non-volatile media and/or volatile media described herein. Electronic data, including data described herein, may be temporarily and/or permanently stored in storage device 356. For example, data representative of computer-executable instructions 362 configured to direct processor 354 to perform any of the operations described herein may be stored within storage device 356. In some examples, data may be arranged in one or more databases residing within storage device 356.

I/O module 358 may include one or more I/O modules configured to receive user input and provide user output. I/O module 358 may include any hardware, firmware, software, or combination thereof supportive of input and output capabilities. For example, I/O module 358 may include hardware and/or software for capturing user input, including, but not limited to, a keyboard or keypad, a touchscreen component (e.g., touchscreen display), a receiver (e.g., an RF or infrared receiver), motion sensors, and/or one or more input buttons.

I/O module 358 may include one or more devices for presenting output to a user, including, but not limited to, a graphics engine, a display (e.g., a display screen), one or more output drivers (e.g., display drivers), one or more audio speakers, and one or more audio drivers. In certain embodiments, I/O module 358 is configured to provide graphical data to a display for presentation to a user. The graphical data may be representative of one or more graphical user interfaces and/or any other graphical content as may serve a particular implementation. In some examples, any of the systems, computing devices, and/or other components described herein may be implemented by computing device 350.

For further explanation, FIG. 3E illustrates an example of a fleet of storage systems 376 for providing storage services (also referred to herein as ‘data services’). The fleet of storage systems 376 depicted in FIG. 3E includes a plurality of storage systems 374a, 374b, 374c, through 374n that may each be similar to the storage systems described herein. The storage systems 374a, 374b, 374c, through 374n in the fleet of storage systems 376 may be embodied as identical storage systems or as different types of storage systems. For example, two of the storage systems 374a, 374n depicted in FIG. 3E are depicted as being cloud-based storage systems, as the resources that collectively form each of the storage systems 374a, 374n are provided by distinct cloud services providers 370, 372. For example, the first cloud services provider 370 may be Amazon AWS^{TM} whereas the second cloud services provider 372 is Microsoft Azure^{TM}, although in other embodiments one or more public clouds, private clouds, or combinations thereof may be used to provide the underlying resources that are used to form a particular storage system in the fleet of storage systems 376.

The example depicted in FIG. 3E includes an edge management service 366 for delivering storage services in accordance with some embodiments of the present disclosure. The storage services (also referred to herein as ‘data services’) that are delivered may include, for example, services to provide a certain amount of storage to a consumer, services to provide storage to a consumer in accordance with a predetermined service level agreement, services to provide storage to a consumer in accordance with predetermined regulatory requirements, and many others.

The edge management service 366 depicted in FIG. 3E may be embodied, for example, as one or more modules of computer program instructions executing on computer hardware such as one or more computer processors. Alternatively, the edge management service 366 may be embodied as one or more modules of computer program instructions executing on a virtualized execution environment such as one or more virtual machines, in one or more containers, or in some other way. In other embodiments, the edge management service 366 may be embodied as a combination of the embodiments described above, including embodiments where the one or more modules of computer program instructions that are included in the edge management service 366 are distributed across multiple physical or virtual execution environments.

The edge management service 366 may operate as a gateway for providing storage services to storage consumers, where the storage services leverage storage offered by one or more storage systems 374a, 374b, 374c, through 374n. For example, the edge management service 366 may be configured to provide storage services to host devices 378a, 378b, 378c, 378d, 378n that are executing one or more applications that consume the storage services. In such an example, the edge management service 366 may operate as a gateway between the host devices 378a, 378b, 378c, 378d, 378n and the storage systems 374a, 374b, 374c, through 374n, rather than requiring that the host devices 378a, 378b, 378c, 378d, 378n directly access the storage systems 374a, 374b, 374c, through 374n.

The edge management service 366 of FIG. 3E exposes a storage services module 364 to the host devices 378a, 378b, 378c, 378d, 378n of FIG. 3E, although in other embodiments the edge management service 366 may expose the storage services module 364 to other consumers of the various storage services. The various storage services may be presented to consumers via one or more user interfaces, via one or more APIs, or through some other mechanism provided by the storage services module 364. As such, the storage services module 364 depicted in FIG. 3E may be embodied as one or more modules of computer program instructions executing on physical hardware, on a virtualized execution environment, or combinations thereof, where executing such modules causes enables a consumer of storage services to be offered, select, and access the various storage services.

The edge management service 366 of FIG. 3E also includes a system management services module 368. The system management services module 368 of FIG. 3E includes one or more modules of computer program instructions that, when executed, perform various operations in coordination with the storage systems 374a, 374b, 374c, through 374n to provide storage services to the host devices 378a, 378b, 378c, 378d, 378n. The system management services module 368 may be configured, for example, to perform tasks such as provisioning storage resources from the storage systems 374a, 374b, 374c, through 374n via one or more APIs exposed by the storage systems 374a, 374b, 374c, through 374n, migrating datasets or workloads amongst the storage systems 374a, 374b, 374c, through 374n via one or more APIs exposed by the storage systems 374a, 374b, 374c, through 374n, setting one or more tunable parameters (i.e., one or more configurable settings) on the storage systems 374a, 374b, 374c, through 374n via one or more APIs exposed by the storage systems 374a, 374b, 374c, through 374n, and so on. For example, many of the services described below relate to embodiments where the storage systems 374a, 374b, 374c, through 374n are configured to operate in some way. In such examples, the system management services module 368 may be responsible for using APIs (or some other mechanism) provided by the storage systems 374a, 374b, 374c, through 374n to configure the storage systems 374a, 374b, 374c, through 374n to operate in the ways described below.

In addition to configuring the storage systems 374a, 374b, 374c, through 374n, the edge management service 366 itself may be configured to perform various tasks required to provide the various storage services. Consider an example in which the storage service includes a service that, when selected and applied, causes personally identifiable information (‘PII’) contained in a dataset to be obfuscated when the dataset is accessed. In such an example, the storage systems 374a, 374b, 374c, through 374n may be configured to obfuscate PII when servicing read requests directed to the dataset. Alternatively, the storage systems 374a, 374b, 374c, through 374n may service reads by returning data that includes the PII, but the edge management service 366 itself may obfuscate the PII as the data is passed through the edge management service 366 on its way from the storage systems 374a, 374b, 374c, through 374n to the host devices 378a, 378b, 378c, 378d, 378n.

The storage systems 374a, 374b, 374c, through 374n depicted in FIG. 3E may be embodied as one or more of the storage systems described above with reference to FIGS. 1A-3D, including variations thereof. In fact, the storage systems 374a, 374b, 374c, through 374n may serve as a pool of storage resources where the individual components in that pool have different performance characteristics, different storage characteristics, and so on. For example, one of the storage systems 374a may be a cloud-based storage system, another storage system 374b may be a storage system that provides block storage, another storage system 374c may be a storage system that provides file storage, another storage system 374d may be a relatively high-performance storage system while another storage system 374n may be a relatively low-performance storage system, and so on. In alternative embodiments, only a single storage system may be present.

The storage systems 374a, 374b, 374c, through 374n depicted in FIG. 3E may also be organized into different failure domains so that the failure of one storage system 374a should be totally unrelated to the failure of another storage system 374b. For example, each of the storage systems may receive power from independent power systems, each of the storage systems may be coupled for data communications over independent data communications networks, and so on. Furthermore, the storage systems in a first failure domain may be accessed via a first gateway whereas storage systems in a second failure domain may be accessed via a second gateway. For example, the first gateway may be a first instance of the edge management service 366 and the second gateway may be a second instance of the edge management service 366, including embodiments where each instance is distinct, or each instance is part of a distributed edge management service 366.

As an illustrative example of available storage services, storage services may be presented to a user that are associated with different levels of data protection. For example, storage services may be presented to the user that, when selected and enforced, guarantee the user that data associated with that user will be protected such that various recovery point objectives (‘RPO’) can be guaranteed. A first available storage service may ensure, for example, that some dataset associated with the user will be protected such that any data that is more than 5 seconds old can be recovered in the event of a failure of the primary data store whereas a second available storage service may ensure that the dataset that is associated with the user will be protected such that any data that is more than 5 minutes old can be recovered in the event of a failure of the primary data store.

An additional example of storage services that may be presented to a user, selected by a user, and ultimately applied to a dataset associated with the user can include one or more data compliance services. Such data compliance services may be embodied, for example, as services that may be provided to consumers (i.e., a user) the data compliance services to ensure that the user’s datasets are managed in a way to adhere to various regulatory requirements. For example, one or more data compliance services may be offered to a user to ensure that the user’s datasets are managed in a way so as to adhere to the General Data Protection Regulation (‘GDPR’), one or more data compliance services may be offered to a user to ensure that the user’s datasets are managed in a way so as to adhere to the Sarbanes–Oxley Act of 2002 (‘SOX’), or one or more data compliance services may be offered to a user to ensure that the user’s datasets are managed in a way so as to adhere to some other regulatory act. In addition, the one or more data compliance services may be offered to a user to ensure that the user’s datasets are managed in a way so as to adhere to some non-governmental guidance (e.g., to adhere to best practices for auditing purposes), the one or more data compliance services may be offered to a user to ensure that the user’s datasets are managed in a way so as to adhere to a particular clients or organizations requirements, and so on.

In order to provide this particular data compliance service, the data compliance service may be presented to a user (e.g., via a GUI) and selected by the user. In response to receiving the selection of the particular data compliance service, one or more storage services policies may be applied to a dataset associated with the user to carry out the particular data compliance service. For example, a storage services policy may be applied requiring that the dataset be encrypted prior to being stored in a storage system, prior to being stored in a cloud environment, or prior to being stored elsewhere. In order to enforce this policy, a requirement may be enforced not only requiring that the dataset be encrypted when stored, but a requirement may be put in place requiring that the dataset be encrypted prior to transmitting the dataset (e.g., sending the dataset to another party). In such an example, a storage services policy may also be put in place requiring that any encryption keys used to encrypt the dataset are not stored on the same system that stores the dataset itself. Readers will appreciate that many other forms of data compliance services may be offered and implemented in accordance with embodiments of the present disclosure.

The storage systems 374a, 374b, 374c, through 374n in the fleet of storage systems 376 may be managed collectively, for example, by one or more fleet management modules. The fleet management modules may be part of or separate from the system management services module 368 depicted in FIG. 3E. The fleet management modules may perform tasks such as monitoring the health of each storage system in the fleet, initiating updates or upgrades on one or more storage systems in the fleet, migrating workloads for loading balancing or other performance purposes, and many other tasks. As such, and for many other reasons, the storage systems 374a, 374b, 374c, through 374n may be coupled to each other via one or more data communications links in order to exchange data between the storage systems 374a, 374b, 374c, through 374n.

In some embodiments, one or more storage systems or one or more elements of storage systems (e.g., features, services, operations, components, etc. of storage systems), such as any of the illustrative storage systems or storage system elements described herein may be implemented in one or more container systems. A container system may include any system that supports execution of one or more containerized applications or services. Such a service may be software deployed as infrastructure for building applications, for operating a run-time environment, and/or as infrastructure for other services. In the discussion that follows, descriptions of containerized applications generally apply to containerized services as well.

A container may combine one or more elements of a containerized software application together with a runtime environment for operating those elements of the software application bundled into a single image. For example, each such container of a containerized application may include executable code of the software application and various dependencies, libraries, and/or other components, together with network configurations and configured access to additional resources, used by the elements of the software application within the particular container in order to enable operation of those elements. A containerized application can be represented as a collection of such containers that together represent all the elements of the application combined with the various run-time environments needed for all those elements to run. As a result, the containerized application may be abstracted away from host operating systems as a combined collection of lightweight and portable packages and configurations, where the containerized application may be uniformly deployed and consistently executed in different computing environments that use different container-compatible operating systems or different infrastructures. In some embodiments, a containerized application shares a kernel with a host computer system and executes as an isolated environment (an isolated collection of files and directories, processes, system and network resources, and configured access to additional resources and capabilities) that is isolated by an operating system of a host system in conjunction with a container management framework. When executed, a containerized application may provide one or more containerized workloads and/or services.

The container system may include and/or utilize a cluster of nodes. For example, the container system may be configured to manage deployment and execution of containerized applications on one or more nodes in a cluster. The containerized applications may utilize resources of the nodes, such as memory, processing and/or storage resources provided and/or accessed by the nodes. The storage resources may include any of the illustrative storage resources described herein and may include on-node resources such as a local tree of files and directories, off-node resources such as external networked file systems, databases or object stores, or both on-node and off-node resources. Access to additional resources and capabilities that could be configured for containers of a containerized application could include specialized computation capabilities such as GPUs and AI/ML engines, or specialized hardware such as sensors and cameras.

In some embodiments, the container system may include a container orchestration system (which may also be referred to as a container orchestrator, a container orchestration platform, etc.) designed to make it reasonably simple and for many use cases automated to deploy, scale, and manage containerized applications. In some embodiments, the container system may include a storage management system configured to provision and manage storage resources (e.g., virtual volumes) for private or shared use by cluster nodes and/or containers of containerized applications.

FIG. 3F illustrates an example container system 380. In this example, the container system 380 includes a container storage system 381 that may be configured to perform one or more storage management operations to organize, provision, and manage storage resources for use by one or more containerized applications 382-1 through 382-L of container system 380. In particular, the container storage system 381 may organize storage resources into one or more storage pools 383 of storage resources for use by containerized applications 374a, 374b through 382-L. The container storage system may itself be implemented as a containerized service.

The container system 380 may include or be implemented by one or more container orchestration systems, including Kubernetes™, Mesos™, Docker Swarm™, among others. The container orchestration system may manage the container system 380 running on a cluster 384 through services implemented by a control node, depicted as 385, and may further manage the container storage system or the relationship between individual containers and their storage, memory and CPU limits, networking, and their access to additional resources or services.

A control plane of the container system 380 may implement services that include: deploying applications via a controller 386, monitoring applications via the controller 386, providing an interface via an API server 387, and scheduling deployments via scheduler 388. In this example, controller 386, scheduler 388, API server 387, and container storage system 381 are implemented on a single node, node 385. In other examples, for resiliency, the control plane may be implemented by multiple, redundant nodes, where if a node that is providing management services for the container system 380 fails, then another, redundant node may provide management services for the cluster 384.

A data plane of the container system 380 may include a set of nodes that provides container runtimes for executing containerized applications. An individual node within the cluster 384 may execute a container runtime, such as Docker™, and execute a container manager, or node agent, such as a kubelet in Kubernetes (not depicted) that communicates with the control plane via a local network-connected agent (sometimes called a proxy), such as an agent 389. The agent 389 may route network traffic to and from containers using, for example, Internet Protocol (IP) port numbers. For example, a containerized application may request a storage class from the control plane, where the request is handled by the container manager, and the container manager communicates the request to the control plane using the agent 389.

Cluster 384 may include a set of nodes that run containers for managed containerized applications. A node may be a virtual or physical machine. A node may be a host system.

The container storage system 381 may orchestrate storage resources to provide storage to the container system 380. For example, the container storage system 381 may provide persistent storage to containerized applications 382-1-382-L using the storage pool 383. The container storage system 381 may itself be deployed as a containerized application by a container orchestration system.

For example, the container storage system 381 application may be deployed within cluster 384 and perform management functions for providing storage to the containerized applications 382. Management functions may include determining one or more storage pools from available storage resources, provisioning virtual volumes on one or more nodes, replicating data, responding to and recovering from host and network faults, or handling storage operations. The storage pool 383 may include storage resources from one or more local or remote sources, where the storage resources may be different types of storage, including, as examples, block storage, file storage, and object storage.

The container storage system 381 may also be deployed on a set of nodes for which persistent storage may be provided by the container orchestration system. In some examples, the container storage system 381 may be deployed on all nodes in a cluster 384 using, for example, a Kubernetes DaemonSet. In this example, nodes 390-1 through 390-N provide a container runtime where container storage system 381 executes. In other examples, some, but not all nodes in a cluster may execute the container storage system 381.

The container storage system 381 may handle storage on a node and communicate with the control plane of container system 380, to provide dynamic volumes, including persistent volumes. A persistent volume may be mounted on a node as a virtual volume, such as virtual volumes 391-1 and 391-P. After a virtual volume 391 is mounted, containerized applications may request and use, or be otherwise configured to use, storage provided by the virtual volume 391. In this example, the container storage system 381 may install a driver on a kernel of a node, where the driver handles storage operations directed to the virtual volume. In this example, the driver may receive a storage operation directed to a virtual volume, and in response, the driver may perform the storage operation on one or more storage resources within the storage pool 383, possibly under direction from or using additional logic within containers that implement the container storage system 381 as a containerized service.

The container storage system 381 may, in response to being deployed as a containerized service, determine available storage resources. For example, storage resources 392-1 through 392-M may include local storage, remote storage (storage on a separate node in a cluster), or both local and remote storage. Storage resources may also include storage from external sources such as various combinations of block storage systems, file storage systems, and object storage systems. The storage resources 392-1 through 392-M may include any type(s) and/or configuration(s) of storage resources (e.g., any of the illustrative storage resources described above), and the container storage system 381 may be configured to determine the available storage resources in any suitable way, including based on a configuration file. For example, a configuration file may specify account and authentication information for cloud-based object storage 348 or for a cloud-based storage system 318. The container storage system 381 may also determine availability of one or more storage devices 356 or one or more storage systems. An aggregate amount of storage from one or more of storage device(s) 356, storage system(s), cloud-based storage system(s) 318, edge management services 366, cloud-based object storage 348, or any other storage resources, or any combination or sub-combination of such storage resources may be used to provide the storage pool 383. The storage pool 383 is used to provision storage for the one or more virtual volumes mounted on one or more of the nodes 390 within cluster 384.

In some implementations, the container storage system 381 may create multiple storage pools. For example, the container storage system 381 may aggregate storage resources of a same type into an individual storage pool. In this example, a storage type may be one of: a storage device 356, a storage array 102, a cloud-based storage system 318, storage via an edge management service 366, or a cloud-based object storage 348. Or it could be storage configured with a certain level or type of redundancy or distribution, such as a particular combination of striping, mirroring, or erasure coding.

The container storage system 381 may execute within the cluster 384 as a containerized container storage system service, where instances of containers that implement elements of the containerized container storage system service may operate on different nodes within the cluster 384. In this example, the containerized container storage system service may operate in conjunction with the container orchestration system of the container system 380 to handle storage operations, mount virtual volumes to provide storage to a node, aggregate available storage into a storage pool 383, provision storage for a virtual volume from a storage pool 383, generate backup data, replicate data between nodes, clusters, environments, among other storage system operations. In some examples, the containerized container storage system service may provide storage services across multiple clusters operating in distinct computing environments. For example, other storage system operations may include storage system operations described herein. Persistent storage provided by the containerized container storage system service may be used to implement stateful and/or resilient containerized applications.

The container storage system 381 may be configured to perform any suitable storage operations of a storage system. For example, the container storage system 381 may be configured to perform one or more of the illustrative storage management operations described herein to manage storage resources used by the container system.

In some embodiments, one or more storage operations, including one or more of the illustrative storage management operations described herein, may be containerized. For example, one or more storage operations may be implemented as one or more containerized applications configured to be executed to perform the storage operation(s). Such containerized storage operations may be executed in any suitable runtime environment to manage any storage system(s), including any of the illustrative storage systems described herein.

FIG. 3G illustrates an example of a storage node of a storage system architecture 395 for a large-scale storage platform, in accordance with embodiments of the disclosure. The storage system architecture 395 includes node 390, as previously described at FIG. 3F, and a large-scale storage platform 396. It should be noted that in some embodiments, storage system architecture 395 may include other storage system components as previously described at FIGS. 1A-3F in addition to or instead of the components shown in storage system architecture 395. For illustrative purposes, some components of storage system architecture 395 are not shown.

Node 390 includes a processing device 397 that executes a scale out platform component 398 and a flash device management component 399, which are described in further detail below. Node 390 may also include storage resources 392, as previously described at FIG. 3F.

Large-scale storage platform 396 may be a cloud-scale or hyperscaler storage platform that is operatively coupled to node 390 via one or more network connections (not shown). The large-scale storage platform 396 may provide computing and/or storage resources across multiple data centers to consumers at an enterprise level. In embodiments, node 390 may store data at storage resources 392 on behalf of the large-scale storage platform 396.

Node 390 may be optimized for use by the large-scale storage platform 396 by moving the handling of large blocks of data from individual storage resources 392 to processing device 397 (e.g., flash device management component 399). This may be used to form a simple storage node service that separates the software that ties node 390 into the large-scale storage platform 396, which has similarities but many specific differences between other large-scale storage platforms, with software that can optimize the use of directly managed and abstraction based managed flash storage devices, such as storage resources 392.

In embodiments, node 390 for large-scale storage platform 396 may be a server with a large number of slots for inserting coupled storage devices (e.g., storage resources 392). In embodiments, node 390 may be configured with processing device 397 that executes a flexible server operating system with a large amount of available RAM and network connections for connecting node 390 with the rest of the large-scale storage platform 396 within and across the data centers and geographies of the large-scale storage platform 396. In some embodiments, node 390 may operate according to the needs of the large-scale storage platform 396. Although node 390 may generally store individual shards of widely distributed and erasure coded stripes of data, as well as serving additional needs related to databases, logging, and being compute that is available to run various services that aid in the operation of the large-scale storage service.

In some embodiments, node 390 may have a large number of connected flash storage devices, including directly and abstraction-based managed storage devices, and a processing device and memory (not shown) running software (e.g., scale out platform component 398 and/or flash device management component 399) on the processing device. In embodiments, the scale out platform component 398 may interact with the large-scale storage platform 396 and other large-scale storage platform management infrastructure. The flash device management component 399 may manage the storage resources 392 present the storage resources in some form to the scale out platform component 398.

In embodiments, a flexible large-block model may be implemented within node 390 utilizing directly or abstraction-based managed flash storage devices may improve the performance of a storage system for large-scale storage platform 396. In a conventional storage system, the storage devices generally have fixed-sized DRAM for storing tables. This makes the storage devices inflexible in terms of balancing block sizes and DRAM because it is easier to manufacture a range of DRAM configurations for the server parts of the storage nodes than to manufacture a range of DRAM configurations for pluggable storage devices to insert into hot pluggable drive bays for servers. Furthermore, DRAM takes up valuable space on a circuit board of the pluggable storage device, while placing the DRAM in an enclosure’s motherboard instead migrates that part of the storage node/storage device combination into a place where the DRAMs relative inaccessibility is less of an issue.

In an example embodiment, flash device management component 399 can interface with and manage the managed flash storage devices (e.g., storage resources 392). The flash device management component 399 may provide services to make optimal use of the storage resources 392, for managing the capacity, performance, durability, longevity, and/or localized hardware faults of the storage resources 392. The flash device management component 399 may be able to utilize processing device 397 and memory of node 390 to provide a large-block storage service. For example, the flash device management component 399 may present a set of block volumes to other software layers of the node 390. In another example, a large-scale storage platform 396 can implement software within and across server and storage nodes, such as node 390, that are within and across data centers of the large-scale storage platform 396. The storage nodes may interact with a distributed storage platform to store and retrieve data blocks on behalf of the large-scale storage platform 396. The node 390 can then utilize the set of block volumes provided by the flash device management component 399 to write data segments into large blocks according to a large-block model.

In embodiments, the flash device management component 399 of the node 390 can provide a set of differently optimized storage, such as providing some volumes supporting an amount of large-block optimized storage and other volumes presenting an amount of small-random-write optimized storage for use with tables or databases needed by the scale out platform component 398. In some embodiments, the flash device management component 399 may provide an amount of SLC storage intended for the storage of data that has a heavier overwrite rate. In embodiments, the flash device management component 399 may provide an amount of archive-grade storage that uses less DRAM on the presumption that reads of data stored in the archive-grade storage are infrequent and do not require low latency.

In some embodiments, node 390 may require storage for logs, which may be sequential-write files written in variable-sized data segments. This can end up being similar in write pattern to large blocks that are filled in piecemeal similarly to a large-block allocation model, as long as the file system writing the logs can be coaxed into allocating log file blocks that are appropriately large and appropriately aligned by logical block address.

In embodiments, one mode that the large-scale storage platform 396 may operate their storage nodes, such as node 390, is to run the services that integrate with the rest of the large-scale storage platform on top of a simple file system, such as a XFS file system, that can be configured to prefer aligned extent allocations for regular files, such as logs, and that can further be configured to support fixed alignment and fixed-sized extents on a separate volume for certain types of files (e.g., files that XFS calls real-time files) and where several of those fixed alignment/fixed-sized extents can be written in parallel for higher performance. The storage node then receives shards or pieces of shards, as well as chunks of log data, and/or random-write blocks for various types of databases and turns that data into writes for example to one or more XFS file systems, potentially with writes for one or more shards being written as parallel writes to aligned blocks of XFS real-time files which are then stored by XFS into a volume optimized for those writes. The scale out platform component 398 may further utilize other XFS properties to write log chunks to preferred alignment extents. The shards are part of much larger and very wide stripes with large numbers of parity shards within and across data centers, as previously described. It is the role of the flash device management component 399 of the node 390 to receive the various writes, store them as optimally as is reasonably possible, and support reading any previously written data.

XFS file systems also support issuing TRIM/UNMAP for deleted blocks. In some embodiments, this may be leveraged by the flash device management component 399 to eliminate the potential need to read prior data for partially written large blocks.

In some embodiments, node 390 may also require an amount of storage for booting an operating system. This may be provided by a separate storage resource, such as an SSD, or on-motherboard flash storage. In some embodiments, this may be provided by the storage resources 392 if the BIOS of the storage node is able to read the boot blocks without use of the flash device management component 399, as this layer may not be available until the operating system has booted and execution of the flash device management component 399 has begun. To support this, a storage device controller on one or more of the flash storage devices of storage resources 392 could be configured to provide a namespace supporting random access to a relatively small boot file system. If only reads need be supported, this may be provided by a simple translation table that is updated into the flash storage device while the node 390 is running with flash device management component 399 intact but that is then used to support reads for booting prior to the flash device management component 399 being brought up later in the bootup sequence.

It should be noted that while storage system architecture 395 is shown as having a single node 390 and a single large-scale storage platform 396, embodiments of the disclosure may include any number of nodes and/or large-scale storage platforms.

The storage systems described herein may support various forms of data replication. For example, two or more of the storage systems may synchronously replicate a dataset between each other. In synchronous replication, distinct copies of a particular dataset may be maintained by multiple storage systems, but all accesses (e.g., a read) of the dataset should yield consistent results regardless of which storage system the access was directed to. For example, a read directed to any of the storage systems that are synchronously replicating the dataset should return identical results. As such, while updates to the version of the dataset need not occur at exactly the same time, precautions must be taken to ensure consistent accesses to the dataset. For example, if an update (e.g., a write) that is directed to the dataset is received by a first storage system, the update may only be acknowledged as being completed if all storage systems that are synchronously replicating the dataset have applied the update to their copies of the dataset. In such an example, synchronous replication may be carried out through the use of I/O forwarding (e.g., a write received at a first storage system is forwarded to a second storage system), communications between the storage systems (e.g., each storage system indicating that it has completed the update), or in other ways.

In other embodiments, a dataset may be replicated through the use of checkpoints. In checkpoint-based replication (also referred to as ‘nearly synchronous replication’), a set of updates to a dataset (e.g., one or more write operations directed to the dataset) may occur between different checkpoints, such that a dataset has been updated to a specific checkpoint only if all updates to the dataset prior to the specific checkpoint have been completed. Consider an example in which a first storage system stores a live copy of a dataset that is being accessed by users of the dataset. In this example, assume that the dataset is being replicated from the first storage system to a second storage system using checkpoint-based replication. For example, the first storage system may send a first checkpoint (at time t=0) to the second storage system, followed by a first set of updates to the dataset, followed by a second checkpoint (at time t=1), followed by a second set of updates to the dataset, followed by a third checkpoint (at time t=2). In such an example, if the second storage system has performed all updates in the first set of updates but has not yet performed all updates in the second set of updates, the copy of the dataset that is stored on the second storage system may be up-to-date until the second checkpoint. Alternatively, if the second storage system has performed all updates in both the first set of updates and the second set of updates, the copy of the dataset that is stored on the second storage system may be up-to-date until the third checkpoint. Readers will appreciate that various types of checkpoints may be used (e.g., metadata only checkpoints), checkpoints may be spread out based on a variety of factors (e.g., time, number of operations, an RPO setting), and so on.

In other embodiments, a dataset may be replicated through snapshot-based replication (also referred to as ‘asynchronous replication’). In snapshot-based replication, snapshots of a dataset may be sent from a replication source such as a first storage system to a replication target such as a second storage system. In such an embodiment, each snapshot may include the entire dataset or a subset of the dataset such as, for example, only the portions of the dataset that have changed since the last snapshot was sent from the replication source to the replication target. Readers will appreciate that snapshots may be sent on-demand, based on a policy that takes a variety of factors into consideration (e.g., time, number of operations, an RPO setting), or in some other way.

The storage systems described above may, either alone or in combination, be configured to serve as a continuous data protection store. A continuous data protection store is a feature of a storage system that records updates to a dataset in such a way that consistent images of prior contents of the dataset can be accessed with a low time granularity (often on the order of seconds, or even less), and stretching back for a reasonable period of time (often hours or days). These allow access to very recent consistent points in time for the dataset, and also allow access to points in time for a dataset that might have just preceded some event that, for example, caused parts of the dataset to be corrupted or otherwise lost, while retaining close to the maximum number of updates that preceded that event. Conceptually, they are like a sequence of snapshots of a dataset taken very frequently and kept for a long period of time, though continuous data protection stores are often implemented quite differently from snapshots. A storage system implementing a data continuous data protection store may further provide a means of accessing these points in time, accessing one or more of these points in time as snapshots or as cloned copies, or reverting the dataset back to one of those recorded points in time.

Over time, to reduce overhead, some points in the time held in a continuous data protection store can be merged with other nearby points in time, essentially deleting some of these points in time from the store. This can reduce the capacity needed to store updates. It may also be possible to convert a limited number of these points in time into longer duration snapshots. For example, such a store might keep a low granularity sequence of points in time stretching back a few hours from the present, with some points in time merged or deleted to reduce overhead for up to an additional day. Stretching back in the past further than that, some of these points in time could be converted to snapshots representing consistent point-in-time images from only every few hours.

The storage systems described above may be managed or accessed via a variety of interfaces. Such interfaces may include, for example, command line interfaces, graphical user interfaces, various management consoles, and so on. Such interfaces may be paired with (or include) AI or generative AI capabilities including, for example, generative AI assistants, generative AI tools to create policies (e.g., security policies, data protection policies, replication policies), generative AI tools to analyze and summarize system performance, or generative AI tools to perform any other type of diagnostic investigation, and many others.

In some embodiments, a generative AI tool such as an LLM may operate as an interface to the storage systems. In fact, multiple LLMs may be available, or special purpose Small Language Models (SLMs) may be deployed for specific purposes. For example, one SLM may be deployed to operate as a generative AI assistant that can be specially trained on documents such as user manuals for the storage system, help pages for the storage system, support tickets for the storage systems, and so on. In this example, the generative AI assistant may be specially trained to answer user questions regarding managing the storage system, configuring the storage system, and the like. In another example, a second SLM may be trained on security-related information (e.g., ransomware documentation and best practices, information provided via the MITRE ATT&CK framework) such that the second SLM can be used to help a storage admin understand best practices and current threats to secure their storage systems. Readers will appreciate that many other SLMs or LLMs may be used for many purposes such as expanding analytics capabilities, improving oversight, understanding best practices, and so on. Depending on the specific purpose, models may be specially trained and/or leverage topic-specific RAG knowledge bases.

The storage systems described above may also be used as a part of a larger framework for enabling AI applications, as the storage systems may be paired with one or more GPUs and may implement different interfaces (e.g., GPUDirect) that are used to optimize storage access and storage operations for AI workloads. Likewise, the storage systems may be configured with software and other tools (e.g., vector databases) to better condition data for usage in AI workloads. In such a way, various versions of the storage systems described above may be specifically configured to better service AI workloads, versus how a storage system might be configured to service general I/O-based workloads. This can be true of hardware-based storage systems as well as the cloud-based storage systems described above. For example, the cloud-based storage systems may even leverage AI-focused cloud resources (e.g., the virtualized storage system controllers may be implemented using (or coupled to) GPU-enabled virtual machines such as Azure NC-series that provide for accelerated data exchanges amongst GPUs and GPUs-storage), or be configured in some other way that is aimed at improving the performance of AI workloads that leverage the cloud-based storage systems.

The storage systems described above may be further configured to include computer program instructions to impact the operation of the storage systems described above. For example, the storage system controllers or other entity (such as one or more physical/virtual computing devices that sit above a layer of storage systems) may execute computer program instructions that effectively provide for various performance tiers within the storage systems, where certain volumes, files, objects, or other entity is provided with performance guarantees that are enforced at the software-level (rather than being placed in high-performance storage, placed close to a processor, and so on). Likewise, such software may be used to offer different types of data storage (e.g., file storage, object storage, block storage) using a pool of underlying, back-end storage resources via a single control plane (i.e., a single global namespace). In other embodiments, other aspects of system performance may also be enforced at the software-level rather than placing data in some way to achieve some desired service or performance outcome.

In some embodiments, the storage systems described above may be used to form a data lake (or data lakehouse). Given that the storage systems can provide parallel file systems, one or more of the storage systems may be used to provide a scalable, machine-learning-based AI processing and analytics data storage platform. Such systems may be configured to support GPU Direct Storage (GDS) or similar technologies to enable the direct transfer of data between storage and GPUs to provide a unified data platform for analytics and AI, and may even support retrieval-augmented generation (RAG).

Readers will appreciate that many of the embodiments described above relate to embodiments where various functions are performed by storage system controllers that are distinct from the underlying storage media (e.g., flash core modules, direct flash modules, vendor-specific flash storage devices or modules, purpose built flash storage devices or modules, SSDs, Storage class memory (SCM), or other non-volatile storage media). In other embodiments, however, the underlying storing media may include processing devices such as FPGAs, ASICs, CPUs, processing cores, or some other processing device that can be used to execute computer program instructions that carry out the functions described above. Such computer program instructions may be stored in flash memory or some other storage that can be accessed by the processing devices. In such a way, any of the functions described above may be carried out by processing logic that is more closely coupled to the underlying storage media, rather than being performed by the storage system controllers that are described above.

Although some embodiments are described largely in the context of a storage system, readers of skill in the art will recognize that embodiments of the present disclosure may also take the form of a computer program product disposed upon computer readable storage media for use with any suitable processing system. Such computer readable storage media may be any storage medium for machine-readable information, including magnetic media, optical media, solid-state media, or other suitable media. Examples of such media include magnetic disks in hard drives or diskettes, compact disks for optical drives, magnetic tape, and others as will occur to those of skill in the art. Persons skilled in the art will immediately recognize that any computer system having suitable programming means will be capable of executing the steps described herein as embodied in a computer program product. Persons skilled in the art will recognize also that, although some of the embodiments described in this specification are oriented to software installed and executing on computer hardware, nevertheless, alternative embodiments implemented as firmware or as hardware are well within the scope of the present disclosure.

In some examples, a non-transitory computer-readable medium storing computer-readable instructions may be provided in accordance with the principles described herein. The instructions, when executed by a processor of a computing device, may direct the processor and/or computing device to perform one or more operations, including one or more of the operations described herein. Such instructions may be stored and/or transmitted using any of a variety of known computer-readable media.

A non-transitory computer-readable medium as referred to herein may include any non-transitory storage medium that participates in providing data (e.g., instructions) that may be read and/or executed by a computing device (e.g., by a processor of a computing device). For example, a non-transitory computer-readable medium may include, but is not limited to, any combination of non-volatile storage media and/or volatile storage media. Exemplary non-volatile storage media include, but are not limited to, read-only memory, flash memory, a solid-state drive, a magnetic storage device (e.g., a hard disk, a floppy disk, magnetic tape, etc.), ferroelectric random-access memory ("RAM"), and an optical disc (e.g., a compact disc, a digital video disc, a Blu-ray disc, etc.). Exemplary volatile storage media include, but are not limited to, RAM (e.g., dynamic RAM).

Advantages and features of the present disclosure can be further described by the following statements:
1. A storage system comprising a plurality of storage devices; and a storage controller, operatively coupled to the plurality of storage devices, configured to: form one or more data segments to be stored in the storage system; and write a first data segment of the one or more data segments to regions of flash memory of a first storage device of the plurality of storage devices using an erasure code that divides the first data segment into data shards, wherein writing the first data segment comprises calculating at least one intra-device recovery data shard corresponding to the data shards of the first data segment to be stored in the first storage device that protects the data shards, wherein the data shards of the first data segment and the at least one intra-device recovery data shard are organized and stored into the flash memory of the first storage device based on fault boundaries in flash architectures for writing to flash cells of the flash memory.
2. The storage system of statement 1, wherein the first data segment comprises an erase block of the flash memory.
3. The storage system of any of statements 1-2, wherein the first data segment is written across multiple erase blocks of the flash memory of the storage device
4. The storage system of any of statements 1-3, wherein the at least one intra-device recovery data shard for the first data segment is included within the first data segment along with the data shards of the first data segment.
5. The storage system of any of statements 1-4, wherein the at least one intra-device recovery data shard protecting the data shards of the first data segment is written into a second data segment of the one or more data segments stored on the first storage device.
6. The storage system of any of statements 1-5, wherein garbage collecting the second data segment comprising the at least one intra-device recovery data shard preserves the at least one intra-device recovery data shard if the first data shard is retained by the storage system.
7. The storage system of any of statements 1-6, wherein data is written into the first data segment incrementally and where the at least one intra-device recovery data shard for the first data segment is incrementally recalculated and stored into non-volatile random access memory (NVRAM) as data is added into the first data segment.
8. The storage system of any of statements 1-7, wherein the fault boundaries are word lines of the flash memory and the data shards and the intra-device recovery data shards are each one or more word lines of the flash memory.
9. The storage system of any of statements 1-8, wherein the storage controller is further configured to: receive a read request for a data shard of the first data segment; identify an uncorrectable error in the data shard; and recover the data shard comprising the uncorrectable error by utilizing a combination of remaining data shards of the first data segment and the at least one intra-device recovery data shard for the first data segment.
10. The storage system of any of statements 1-9, wherein data scrubbing is used to search for the uncorrectable errors as a background operation.
11. The storage system of any of statements 1-10, wherein the data scrubbing is performed by the storage device.
12. The storage system of any of statements 1-11, wherein the first data segment is protected by at least one inter-device recovery segment for a plurality of data segments stored on other storage devices of the plurality of storage devices, wherein the at least one inter-device recovery segment is stored on a separate storage device than the first storage device and the other storage devices storing the plurality of data segments are protected by the inter-device recovery segment.
13. A method of performing any of statements 1-12.
14. A non-transitory computer readable storage medium storing instructions which, when executed, cause a processing device to perform any of statements 1-12.

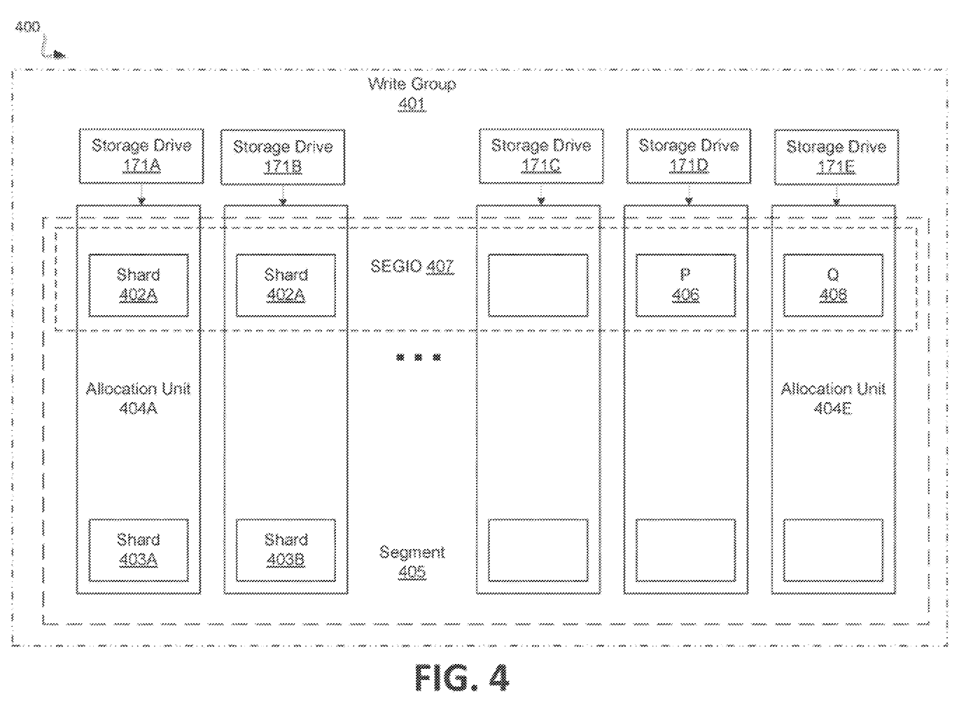

FIG. 4 illustrates an example system 400 for RAID in a direct-mapped storage system, in accordance with some implementations. In one embodiment, system 400 may include storage drives 171A-E. Storage drives 171A-E may be operatively coupled to one or more storage controllers. In one embodiment, storage drives 171A-E include a direct-mapped solid state drive (SSD) storage portion. In other embodiment, storage drives 171A-E also include a fast-write portion to journal data to be written to the direct-mapped SSD portions. In one embodiment, the fast-write portion is an NVRAM portion. The direct-mapped SSD portion and the NVRAM portion may be separately addressable. The NVRAM portion may be smaller than the direct-mapped SSD portion. Storage drives 171A-E may be organized into write groups (e.g., write group 401). Write groups may RAID-protect and write data in segments (e.g., SEGIO 407) that consist of allocation units (e.g., allocation units 404A, 404E) located on a subset of the storage drives 171A-E within a write group.

In one embodiment, SSDs present disk-like LBA spaces of numbered sectors, typically in the range of 512 bytes to 8192 bytes, to storage controllers. The controllers may manage the SSD’s LBA space in relatively large blocks (for example, 1-megabyte to 64-megabytes) of logically contiguous LBAs called allocation units (AUs). Storage controllers may align AUs with each SSD’s internal storage organization to optimize performance and minimize media wear.

In one embodiment storage controllers may allocate physical storage in segments (e.g., SEGIO 407). A segment may consist of several AUs, each on a different SSD in the same write group. An AU in a segment may be located on any AU boundary in its SSD’s LBA space.

Storage controllers may determine the size of a segment when they allocate it based on (a) whether it will contain data or metadata, and (b) the number of SSDs in the selected write group. In one embodiment, a data segment consists of eight to sixteen AUs, and might vary from segment to segment based on redundancy or performance requirements, or available storage devices and storage device layout within the storage system.

In one embodiment, to allocate a segment, a storage controller selects a write group, and the SSDs in the write group that will contribute AUs. Write group and SSD selections may be quasi-random. In another embodiment, for long-term I/O and media wear balance, selections may be slightly biased in favor of newer SSDs, less frequently used SSDs, and/or SSDs that contain more free AUs. In another embodiment, for segments expected to remain untouched for longer periods of time, selection might be biased toward older SSDs or regions of SSDs that are older and have less remaining expected lifespan. To ensure that SSDs are available in order to allow for recovery and rebuilds from failed devices, segments may be limited to one or two fewer AUs than the number of SSDs in the write group at allocation time.

In one embodiment, storage controllers may designate an AU in a segment as a column of, for example, 1-megabyte shards (e.g., shards 402A-E). Corresponding shards in each of a segment’s AUs may collectively be called a SEGIO (e.g., SEGIO 407). SEGIO 407 may be the unit in which storage controllers pack data or metadata before writing it to flash, and over which they calculate RAID-3D checksums. In one embodiment, RAID checksums (erasure codes) may be rotated (e.g., occupy different shard positions in each of a segment’s SEGIOs).

In one embodiment, storage controllers designate a shard as a column of logical pages that align with SSD flash pages, the units in which SSDs write and ECC-protect data internally. In one embodiment, logical pages of 4 kilobytes may be used. In other embodiments, smaller or larger logical pages may be utilized. Storage controllers may calculate independent RAID-3D parity over each set of corresponding logical pages in a SEGIO. Advantageously, when an uncorrectable read error occurs, storage controllers may rebuild the unreadable logical page from erasure codes stored elsewhere in a SEGIO, either elsewhere within the same shard to cover single-page read errors, or from shards on other devices.

In one embodiment, to optimize read time, arrays pack data and metadata into shard buffer logical pages in an order that minimizes large block fragmentation. Packing order may not affect write performance because arrays may write entire shards. Storage controllers may calculate and store a page checksum (e.g., P 406 and Q 408) based on the data written to the storage drives. Checksums may be initialized, with a corresponding page offset in the shard and with the monotonically increasing segment number. In one embodiment, when a storage controller reads a logical page, it recalculates its checksum and compares the result with the stored value to verify both the content and the source of the page.

In one embodiment, storage controllers organize data in content blocks (cblocks) for storage on flash. Storage controllers may split large writes into multiple cblocks based on size and alignment; in one embodiment, a cblock may contain up to 64 kilobytes. In one embodiment, before storing data, storage controllers may reduce (compress) data by: eliminating sectors whose entire contents consist of repeated zeros, repeated byte values, or other simple patterns (for example, repeated single bytes or words, known patterns such as database free blocks, etc.); deduplicating, by eliminating sequences of sectors that are identical to already-stored data; and/or compressing data that is neither a simple pattern nor a duplicate of already-stored data using one of a variety of compression algorithms.

In one embodiment, storage controllers may pack reduced cblocks into logical page buffers in approximate order of arrival, effectively creating a log of the data written by hosts or by the storage system. In another embodiment, storage controllers may pack reduced cblocks into logical page buffers in (or substantially similar to) the order in which the storage controllers generate the data to be stored (e.g., write to a backing store). They may pack cblocks densely—each one begins where the preceding one ends. Advantageously, this may mean that little space is wasted due to “rounding up” to 4, 8, 16, 512 kilobyte, or other boundaries. Dense packing uses media more efficiently than alternative operations that map LBAs directly to physical storage, or that locate data based on its content. Moreover, it may contribute to longer media life by reducing the total accumulated data written to storage media such as flash, which can degrade as it is written.

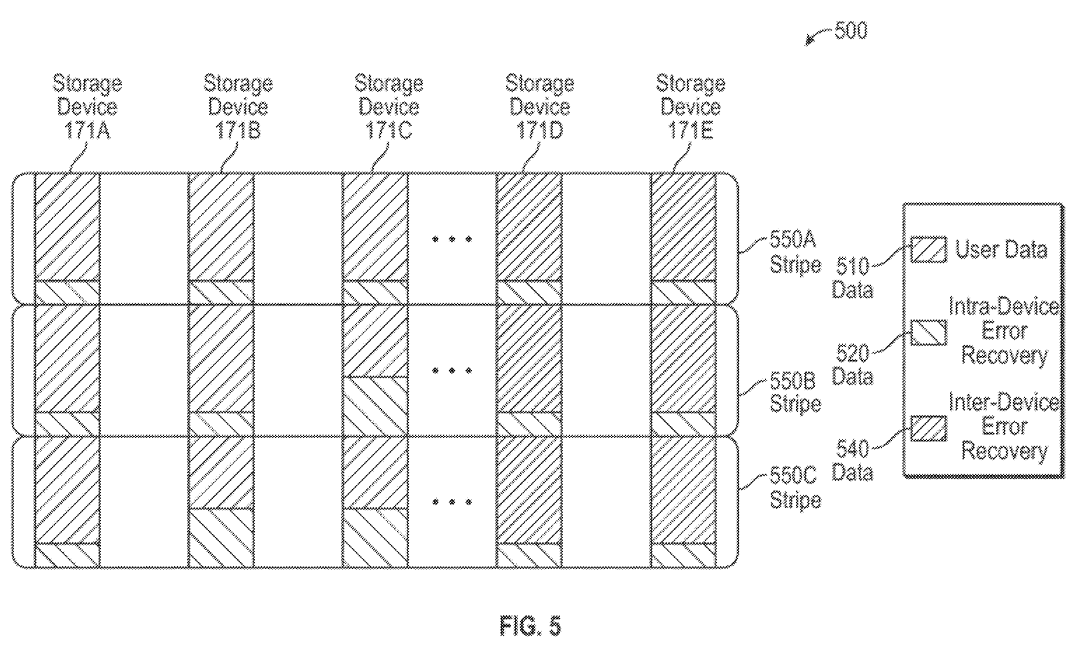

FIG. 5 illustrates an example system 500 for RAID in a direct-mapped storage system, in accordance with some implementations. In one embodiment, an allocation unit within an SSD may include one or more direct-mapped erase blocks within a direct-mapped SSD. Referring to FIG. 5, the user data 510 may refer to both stored data to be modified and accessed by end-users and inter-device error-correction code (ECC) data. The inter-device ECC data may be parity information generated from one or more pages on other storage devices holding user data. For example, the inter-device ECC data may be parity information used in a RAID data layout architecture. The user data 510 may be stored within one or more pages included within one or more of the storage devices 171 a-171 k. In one embodiment, each of the storage devices 171 a-171 e is an SSD.

An erase block within an SSD may comprise several pages. As described earlier, in one embodiment, a page may include 4 KB of data storage space. An erase block may include 64 pages, or 256 KB. In other embodiments, an erase block may be 1 megabyte (MB), and include 256 pages, or 8 megabyte (MB) and include 2048 pages; or pages may be 8 KB or 16 KB with many variations in the size of erase blocks, generally based on the design of the Flash chips and how many bits are stored per Flash memory cell. An allocation unit size may be chosen in a manner to provide both sufficiently large sized units and a relatively low number of units to reduce overhead tracking of the allocation units. Allocation unit size may be determined based on erase block size and/or concerns about future garbage collection strategies. In one embodiment, one or more state tables may maintain a state of an allocation unit (allocated, free, erased, error), a wear level, and a count of a number of errors (correctable and/or uncorrectable) that have occurred within the allocation unit. In various embodiments, the size of an allocation unit may be selected to balance the number of allocation units available for a given device against the overhead of maintaining the allocation units. For example, in one embodiment the size of an allocation unit may be selected to be approximately 1/100th of one percent of the total storage capacity of an SSD. Other amounts of data storage space for pages, erase blocks and other unit arrangements are possible and contemplated.

Latent sector errors (LSEs) may occur when a given sector or other storage unit within a storage device is not validated and repaired for some extended period of time. A read or write operation may not be able to complete for the given sector. In addition, there may be an uncorrectable error-correction code (ECC) error. An LSE is an error that is undetected until the given sector is accessed. Therefore, any data previously stored in the given sector may be lost. A single LSE may lead to data loss when encountered during RAID reconstruction after a storage device failure. For an SSD, an increase in the probability of an occurrence of another LSE may result from at least one of the following statistics: device age, device size, access rates, storage compactness and the occurrence of previous correctable and uncorrectable errors, time since a page was written, and in some cases read or write activity to physically proximate areas of a Flash memory chip. To protect against LSEs and data loss within a given storage device, one of a multiple of intra-device redundancy schemes may be used within the given storage device.

An intra-device redundancy scheme utilizes ECC information, such as parity information, within the given storage device. This intra-device redundancy scheme and its ECC information corresponds to a given device and may be maintained within a given device, but is distinct from ECC that may be internally generated and maintained by the device itself. Generally speaking, the internally generated and maintained ECC of the device is invisible to the system within which the device is included. The intra-device ECC information included within the given storage device may be used to increase data storage reliability within the given storage device. This intra-device ECC information is in addition to other ECC information that may be included within another storage device such as parity information utilized in a RAID data layout architecture.

A highly effective intra-device redundancy scheme may sufficiently enhance the reliability of a given RAID data layout to cause a reduction in a number of devices used to hold parity information. For example, a double parity RAID layout may be replaced with a single parity RAID layout if there is additional intra-device redundancy to protect the data on each device. For a fixed degree of storage efficiency, increasing the redundancy in an intra-device redundancy scheme increases the reliability of the given storage device. However, increasing the redundancy in such a manner may also increase a penalty on the input/output (I/O) performance of the given storage device. One reason for this type of highly effective intra-device redundancy scheme may be to protect against double device failure with reduced concern for latent errors on the remaining devices. Latent errors may be scattered randomly, at low probability, and at high capacities, and may be undetected for some period of time. Device failures may be different and, in some cases, may be detected quickly, possibly resulting in the rebuilding of content that would have been stored on the failed devices. If two devices fail and the remaining devices some number of latent errors, some data may be unrecoverable. Advantageously, embodiments of the present disclosure aid in the recovery in such a case.

In one embodiment, an intra-device redundancy scheme divides a device into groups of locations for storage of user data. For example, a division may be a group of locations within a device that correspond to a stripe within a RAID layout as shown by stripes 550 a-550 c. User data or inter-device RAID redundancy information may be stored in one or more pages within each of the storage devices 171 a-171 e as shown by data 510. Within each storage device, intra-device error recovery data 520 may be stored in one or more pages. As used herein, the intra-device error recovery data 520 may be referred to as intra-device redundancy data 520. As is well known by those skilled in the art, the intra-device redundancy data 520 may be obtained by performing a function on chosen bits of information within the data 510. An XOR-based operation may be used to derive parity information to store in the intra-device redundancy data 520. Other examples of intra-device redundancy schemes include single parity check (SPC), maximum distance separable (MDS) erasure codes, interleaved parity check codes (IPC), hybrid SPC and MDS code (MDS+SPC), and column diagonal parity (CDP). The schemes vary in terms of delivered reliability and overhead depending on the manner the data 520 is computed. In addition to the above described redundancy information, the system may be configured to calculate a checksum value for a region on the device. For example, a checksum may be calculated when information is written to the device. This checksum is stored by the system. When the information is read back from the device, the system may calculate the checksum again and compare it to the value that was stored originally. If the two checksums differ, the information was not read properly, and the system may use other schemes to recover the data. Examples of checksum functions include cyclical redundancy check (CRC), MD5, and SHA-1.

As shown in stripes 550 a-250 c, the width, or number of pages, used to store the data 510 within a given stripe may be the same in each of the storage devices 171 a-171 k. However, as shown in stripes 550 b-250 c, the width, or number of pages, used to store the intra-device redundancy data 520 within a given stripe may not be the same in each of the storage devices 171 a-171 e. In one embodiment, changing characteristics or behaviors of a given storage device may determine, at least in part, the width used to store corresponding intra-device redundancy data 520.

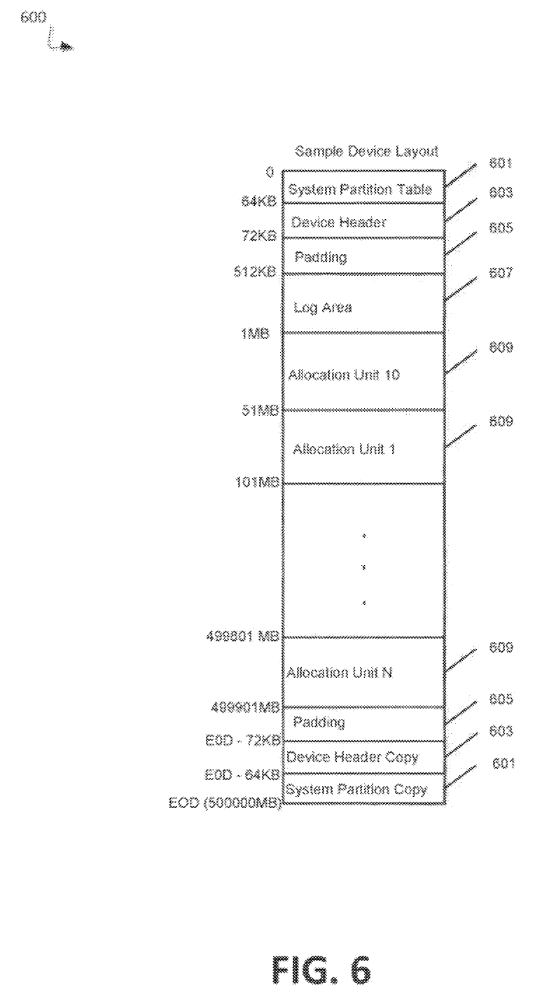

FIG. 6 illustrates an example storage device layout, in accordance with some implementations. In various embodiments, storage devices may be formatted with a partition table 601 at the beginning of the device, and a copy of the partition table at the end of the device. In another embodiment, a device header 603 may be stored in the first and last blocks. For example, in a flash based storage device, a device header may be stored in the first and last erase blocks. As previously discussed, an erase block is a flash construct that is typically in the range of 256 KB-1 MB. Additional unused space in the first erase block may be reserved (padding 605). Diagnostic information 607 may be stored in various erase blocks on the storage device. The rest of the erase blocks in between are divided into Allocation Units (AUs) 609 of a multiple erase blocks. The AU size may be chosen so there are a reasonable number of AUs per device for good allocation granularity. Any number of AUs is possible. In one embodiment, there may be something in the range of millions of AUs on a device to permit allocation in large enough units to avoid overhead, but not too many units for easy tracking. Tracking of the state of an AU (allocated/free/erased/bad) may be maintained an AU State Table. The wear level of an AU may be maintained in a Wear Level Table, and a count of errors may be maintained in an AU Error Table. In various embodiments, the physical layer allocates space in segments which include one segment shard in each device across a set of devices (which could be on different nodes).

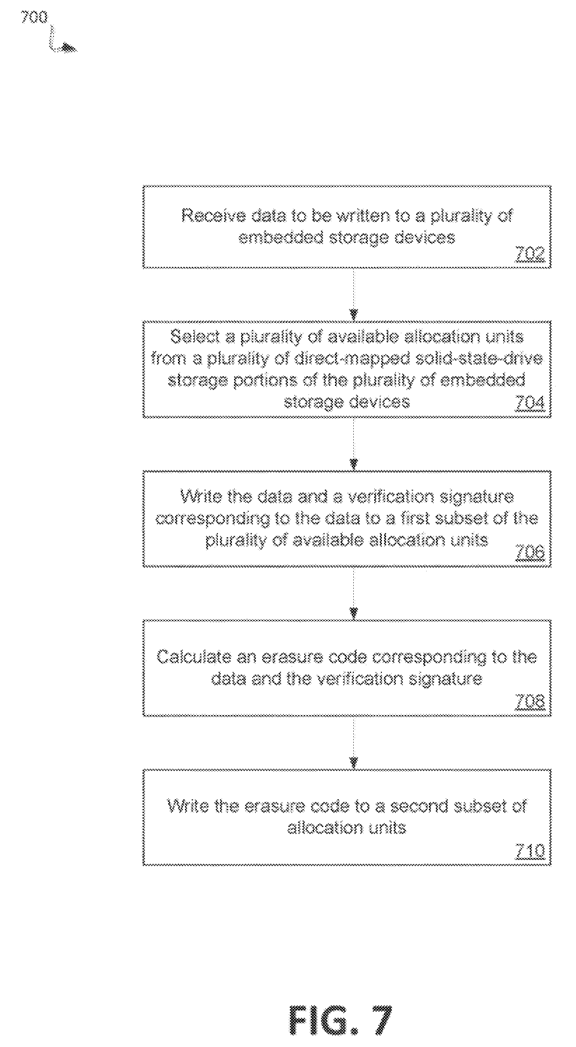

FIG. 7 illustrates a flow diagram for RAID in a direct-mapped storage system, in accordance with some implementations. The method 700 may be performed by processing logic that comprises hardware (e.g., circuitry, dedicated logic, programmable logic, microcode, etc.), software (e.g., instructions run on a processing device to perform hardware simulation), or a combination thereof.

Referring to FIG. 7, at block 702, processing logic receives data to be written to a plurality of embedded storage devices. The data may be written to a number of allocation units spread out across the embedded storage devices. Processing logic, at block 704, selecting a plurality of available allocation units from a plurality of direct-mapped solid-state-drive storage portions of the plurality of embedded storage devices, respectively. At block 706, processing logic may write the data and a verification signature (e.g., a hash, a checksum, etc.) corresponding to the data to a first subset of the plurality of available allocation units. In one embodiment, processing logic calculates a verification signature corresponding to each allocation unit in the first subset of available allocation units. In one embodiment, verification signatures may be used to verify the integrity of the data to which they correspond. At block 708, processing logic may calculate an erasure code corresponding to the data and the verification signature, and at block 710, processing logic may write the erasure code to a second subset of allocation units. In one embodiment, processing logic may calculate a plurality of additional erasure codes corresponding to the data contained in the allocation units (e.g., ‘P’ and a ‘Q’ erasure codes in a RAID system). An erasure code may be referred to herein as having multiple portions. In such a case, each portion may be understood as an individual erasure code. In one embodiment, an erasure code may correspond to a separate one of the plurality of available allocation units. Processing logic may further write the plurality of additional erasure codes to the allocation units (e.g., each additional erasure code to a corresponding allocation unit). In another embodiment, processing logic may write the plurality of erasure codes to allocation units that do not correspond to the erasure code (e.g., to a separate allocation unit on the same drive as the allocation unit to which the erasure code corresponds).

In one embodiment, processing logic may detect that an allocation unit of the first subset of the available allocation units has failed or has been corrupted by comparing the data to the verification signature and, in response to the detecting, recovering a portion of the data from the allocation unit based on the data written to the first subset of the available allocation units and the erasure code. In another embodiment, processing logic may determine that a device controller of an embedded storage device corresponding to the allocation unit did not correct a failure or corruption of the allocation unit and, after determining that the device controller did not correct the failure or corruption, recover that portion of the data.

In one embodiment, the erasure code includes a first portion and a second portion. To write the erasure code, processing logic may write the first portion to a first allocation unit of the subset of the plurality of available allocation units and write the second portion to a second allocation unit of the subset of the plurality of available allocation units in parallel with the first portion.

Processing logic may journal the data in a non-volatile random-access memory (NVRAM) portion. In one embodiment, the direct-mapped SSD portion and the NVRAM portion are separately addressable. In another embodiment, the NVRAM portion is smaller than the direct-mapped SSD portion. As described above, the NVRAM portion may include a random access memory (RAM) device, an energy storing device (e.g., a battery, capacitor, etc.), and a processing device.

Erasure coding or similar techniques may be used to write data across storage devices and protect the data written across the storage devices using an inter-device recovery segment (also referred to as “inter-device recovery data” hereafter). In addition to using erasure coding to write data across multiple storage devices, a storage system may also use erasure coding or other techniques to store recovery data within storage devices (also referred to as “intra-device recovery data” hereafter).

A storage system may utilize intra-device recovery data to deal with latent errors in data stored in a storage device. Latent errors are isolated errors in data segments on a storage device that have become uncorrectably corrupted (such as because the number or pattern of bit errors exceeds that which can be corrected through, for example, sector or flash page-level error correction codes), and have not been detected and resolved by the storage device or the storage system. Latent errors can create issues in assuring reliability of durable data as they can prevent some data of the storage system from being rebuilt in the presence of a full storage device failure. Latent errors can negatively affect data reliability in ways that can be difficult for the storage system to account for short of adding excessive numbers of parity shards to all data stored in the storage system. For example, if a storage system allows for two storage devices to fail through the use of an N+2 erasure code scheme (e.g., a data stripe with two parity shards) when one storage device fails while another has been removed for some reason, a read or a rebuild operation can fail simply because of a latent error on any of the remaining storage devices of a data stripe. This can pressure the storage system to be configured with additional recovery data, such as a third parity shard, just to account for possible latent errors that weren’t corrected prior to a sequence of full drive removals or faults, which can be a substantial hit to the usable storage capacity of the storage system.

Latent errors also complicate schemes to handle non-uniform availability of storage devices as a result of multiple storage devices being accessible only through one of several storage controllers of a storage system. For example, a storage system can include ten or more storage controllers that can uniquely host three or four storage devices. In such a storage system, data availability in the event of a storage controller failure and an additional storage device failure can depend on a careful arrangement of data shards on the individual storage devices of the individual storage controllers. The modeling for such arrangements can be defeated by even a single undetected or unresolved corrupted data segment.

Instead of depending solely on inter-device recovery data to protect against both storage devices failures and latent errors, inter-device recovery data can be complemented with intra-device recovery data. Intra-device recovery data has advantages over depending purely on inter-device recovery data. For example, intra-device recovery data uses less storage capacity overhead, as the number of data shards protected by intra-device recovery data can be higher than inter-device recovery data because intra-device recovery data is only limited by the layout of sufficiently independent portions of data stored on the storage device. Two data segments are sufficiently independent of each other if the physical degradation leading to one of the data segments being uncorrectably corrupted is unlikely to correlate with physical degradation of the other data segment.

In some embodiments, a storage system controller of the storage system may prioritize generating intra-device recovery data to protect older data over intra-device recovery data for newer data because newer data that has been written more recently is generally more reliable than older data. Utilizing intra-device recovery data provides for an improved storage system because the intra-device recovery data allows for optimizations of storing data that utilizes less inter-device recovery data or delays the storing of inter-device recovery data.

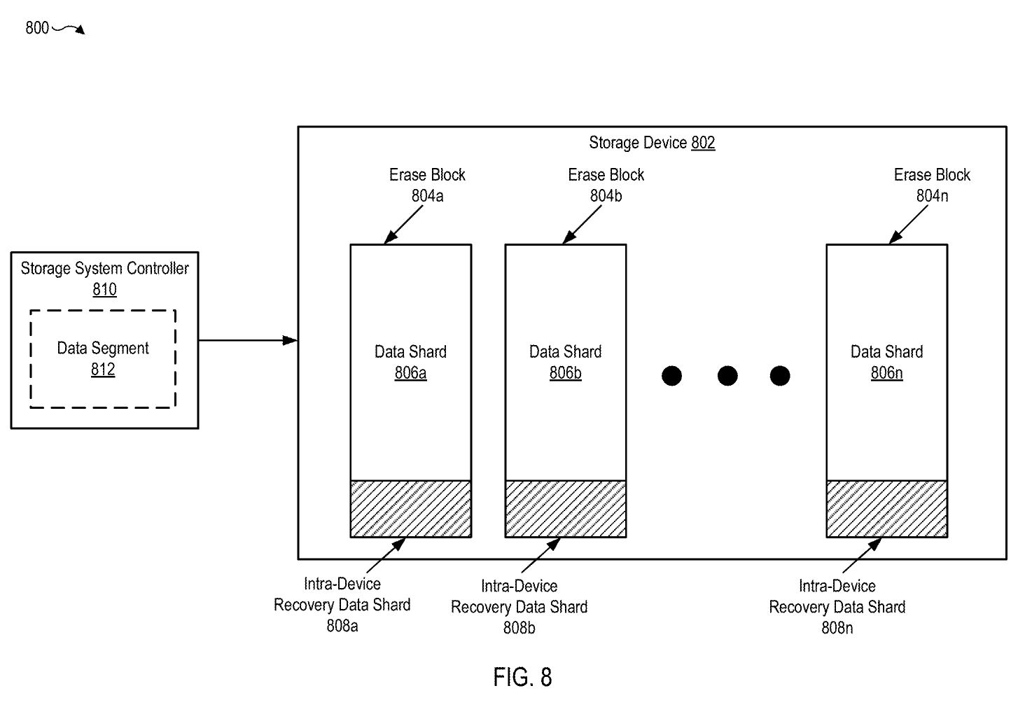

FIG. 8 is an illustration of an example of a storage device of a storage system 800 storing data shards of a data segment and intra-device parity data, in accordance with embodiments of the disclosure. Storage system 800 may correspond to and include one or more components of any of the storage systems previously described at FIGS. 1A-3G. For clarity, some components of storage system 800 are not shown.

Storage system 800 includes a storage device 802 that is operatively coupled to storage system controller 810 via one or more network connections (not shown). Storage device 802 may be a flash memory storage device that includes erase blocks 804a-n of flash memory. Erase blocks 804a-n may correspond to any number of erase blocks of flash memory. Each of erase blocks 804a-n may be a unit of flash memory of storage device 802 that can be erased at one time by storage device 802. In some storage devices utilizing multi-plane flash memory, the term “erase block” may refer to an erasable unit of a single plane, or the term may refer to the matching units that can be erased in a single request to the flash memory across multiple planes. This definition may not be uniform across the flash of a storage device and may not be uniform across time for the same units of flash memory.

Storage system controller 810 may include data segment 812 that is to be stored in storage device 802. In some embodiments, data segment 812 may be part of an erasure coded stripe written across multiple storage devices (not shown) of storage system 800. It should be noted that data segment 812 is shown for illustrative purposes only and is not a physical component of storage system controller 810. Furthermore, although storage system controller 810 is illustrated as having a single data segment (e.g., data segment 812), storage system controller 810 may form any number of data segments for storing in storage devices of storage system 800.

The storage system controller 810 may use an erasure code that divides data segment 812 into one or more data shards (e.g., data shards 806a-n) that may be stored in one or more erase blocks (e.g., erase blocks 804a-n) of storage device 802. The storage system controller 810 may calculate intra-device recovery data shards 808a-n, such as parity data, that protects data shards 806a-n or other data shards stored in storage device 802 from latent errors. In some embodiments, the intra-device redundancy data 808a-n may be calculated using a simple XOR operation. In embodiments, the intra device redundancy data 808a-n may be calculated using Galois-field codes which may enable recovery from more latent errors. In some embodiments, rather than intra-device recovery data shards 808a-n being stored with data shards 806a-n that are protected by intra-device recovery data shards 808a-n, intra-device recovery data shards 808a-n may be stored with data shards of a different data segment of storage device 802.

The data shards 806a-n may be grouped together for calculating intra-device redundancy data 808a-n based on internal organization and fault boundaries of the flash memory of storage device 802. In some embodiments, the groups may be one or more word lines of erase blocks 804a-n, which are the groups of pages of the flash memory that share flash memory cells. In such an embodiment, finalizing an erase block or write segment shard would include writing the intra-device redundancy data to the last word line(s) of the erase block or write segment shard. In some embodiments, erase blocks (or write segment shards) can be completed without writing intra-device redundancy within them, and the intra-device redundancy data for a prior completed erase block or write segment shard can be written into a second erase block or write segment shard. If intra-device redundancy is written into a second erase block or write segment shard, then if that second erase block or write segment shard is eventually garbage collected or is otherwise erased, then the stored parity for the erase block or write segment shard it is protecting can be preserved by garbage collection. In some embodiments, in addition to being protected by intra-device recovery data shards 808a-n, data shards 806a-n may also be protected by at least one inter-device recovery segment for data segments across storage device 802 and other storage devices (not shown) of storage system 800. In such an embodiment, each of the at least one inter-device recovery segments would be stored on a different storage device than storage device 802 or any of the other storage devices storing data shards protected by the inter-device recovery segment(s).

In some embodiments, the intra-device recovery data shards 808a-n may be left non-durable until the intra-device recovery data shards 808a-n are written to erase blocks 804a-n of storage device 802. In embodiments, data may be incrementally written to data segment 812 over an amount of time. In a similar embodiment, the intra-device redundancy data 808a-n may instead be stored durably but temporarily in non-volatile random access memory (NVRAM) of storage system 800 with incremental updates to the intra-device recovery data shards 808a-n as more data is written to data segment 812. For example, if word lines are considered the unit of isolated uncorrectable errors, then if 10 word lines have been written to storage device 802, intra-device recovery data shards calculated for the 10 word lines may be stored in the NVRAM. As more word lines are written to storage device 802, the intra-device recovery data shards 808a-n could be recalculated to also protect the additionally written word lines of data segment 812. In some embodiments, the NVRAM may be integrated into storage device 802. In other embodiments, the NVRAM may be a separate component or included in a different storage device of storage system 800.

As described above, the intra-device recovery data shards 808a-n may be used to recover a data shard of a data segment that includes one or more latent errors. The data shard of the data segment may be recovered using the other data shards of the data segment as well as the intra-device recovery data shards 808a-n of the data segment. In some embodiments, the data shard may be recovered in response to receiving a read request for the data shard that includes the uncorrectable errors. For example, processing logic of the storage device or storage system controller may recover the data shard after reading the data shard and identifying one or more uncorrectable errors in the data shard. The processing logic may then service the read request using the recovered data shard. In embodiments, processing logic of the storage device or storage system controller may perform a data scrubbing operation to identify data shards that include latent errors. The data scrubbing operation may be a background operation performed by the storage system that scans the data shards stored in flash memory to determine if any of the data shards include latent errors and, if so, recover the data shard(s) that have latent errors using the intra-device recovery data shards.

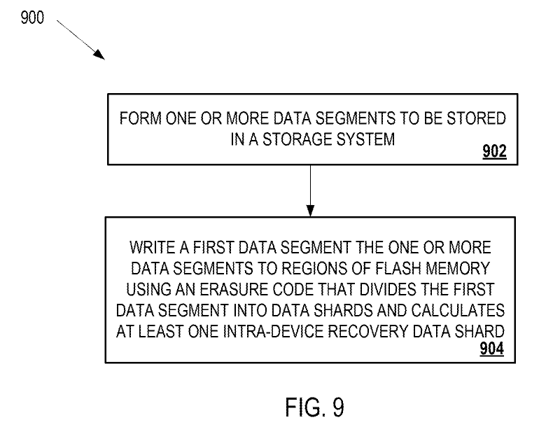

FIG. 9 is an example method 900 to utilize intra-device recovery data to protect against latent errors in accordance with embodiments of the disclosure. In general, the method 900 may be performed by processing logic that may include hardware (e.g., processing device, circuitry, dedicated logic, programmable logic, microcode, hardware of a device, integrated circuit, etc.), software (e.g., instructions run or executed on a processing device), or a combination thereof. In some embodiments, processing logic of a processing device of storage system controller 810 of FIG. 8 may perform the method 900.

Method 900 may begin at block 902, where the processing logic forms one or more data segments to be stored in a storage system.

At block 904, the processing logic writes a first data segment of the one or more data segments to regions of flash memory using an erasure code that divides the first data segment into data shards and calculates at least one intra-device recovery data shard.

As storage systems continue to increase in scale, both in terms of capacity and number of storage devices, sources of data loss and data corruption that were previously considered low probability events can become increasingly significant. In particular, very large-scale storage platforms that operate in a distributed environment across many data nodes may experience failures that include data node failures, device-level failures for devices within the data nodes, localized corruption within storage media, and latent errors that accumulate over time. Conventional redundancy techniques used by these very large-scale storage platforms, such as erasure coding schemes distributed across data nodes of the storage environment, are effective for handling any of these failures, including device-level failures, but overhead may be high if employed too often to resolve every issue even simple device failures or other localized or latent errors.

In many storage systems, redundancy is implemented using encoding techniques in which a set of data units is written together with one or more redundancy units, such as parity data, at the time of writing. While such techniques provide strong protection, they can introduce performance overhead and increased write amplification, particularly in storage systems that frequently modify or relocate data. Additionally, in storage technologies such as flash memory, where data is written to new locations rather than overwritten in place, maintaining redundancy at all times can require additional writes that impact endurance and efficiency. Additionally, the way that flash memory is typically written (e.g., as writes written sequentially into erase blocks that eventually fill up) makes keeping erasure codes for all written data (even data that is in only partially written flash erase blocks) expensive with regards to computing resources (e.g., storage space and computational resources). This often leads to erasure codes being written to NVRAM or being staged to SLC flash memory, all of which adds overhead or expense to storage devices and data nodes. Further, in large-scale environments some means for providing NVRAM, such as relying on super capacitors, may add their own reliability issues, which can lead to NVRAM sizes being constrained below the levels that would be desirable for recording parity and other data for all incompletely written flash memory segments and erase blocks, making it more difficult to balance performance and data reliability.

Further, certain storage architectures impose structural constraints that limit the applicability of conventional redundancy techniques. For example, in storage systems that utilize zones, where a zone represents a region of storage that is written sequentially and later reset as a unit, the size of a zone needed for a zone itself to operate across the erase blocks of a plurality of storage devices with parity for the zone itself may be too large relative to a desirable zone size for the applications writing to zones. As a result, it may not be feasible to generate redundancy within a zone at the time of writing without significantly increasing complexity or resource usage.

Additionally, storage media such as flash memory exhibit non-uniform reliability characteristics. Data that is recently written may be more reliable than data that has been stored for a longer duration. Similarly, certain regions of storage devices, such as frequently accessed regions or regions that have undergone repeated program and erase cycles, or regions adjacent to frequently access regions, may be more susceptible to errors. Conventional redundancy techniques that treat all data uniformly may not take advantage of these characteristics, leading to inefficient use of redundancy resources.

Embodiments described herein address the above, and other deficiencies of conventional systems by providing various fault protection configurations in storage systems that address the above challenges while maintaining efficiency and flexibility. In some embodiments, data described herein as invalidated or logically invalidated may remain physically present within storage media until a subsequent erase, overwrite, garbage collection, relocation, reclamation, or reset operation is performed. For example, an erase block or zone may contain both data scheduled for relocation or reclamation and data that remains valid and recoverable. Accordingly, references herein to invalidated data may refer to data associated with storage locations subject to impending maintenance, relocation, reuse, reclamation, overwrite, or erase operations, rather than implying that the data is immediately physically removed or unusable.

In some embodiments, a first set of techniques addresses the above challenges by decoupling the application of fault protection from the initial writing of data. Rather than generating redundancy at the time data units are written, fault protection may be delayed and applied at a later time. For example, a storage system may receive a plurality of data units and store the data units without immediately generating parity data. Subsequently, the storage system may generate redundancy units based on a subset of the stored data units after certain conditions are satisfied, such as after a threshold amount of data has been accumulated, after a period of time has elapsed, or based on an expected time at which stored data units may no longer be needed, or are erased.

By delaying the generation of redundancy, the storage system can reduce the write amplification, improve performance, and reduce NVRAM or SLC flash memory that would be needed to add parity or other redundancy as data is being written. In some embodiments, fault protection may be applied opportunistically, such that not all data units are protected at all times, but a large proportion of data units are protected at any given time. In addition, when data units stored at particular flash memory locations are no longer needed due to storage management operations such as deletion, garbage collection or data relocation, the storage system may reapply fault protection to remaining data units stored at flash memory locations that are still needed before the erase block is erased upon completion of the storage management operation. With garbage collection, remaining valid data within erase blocks that contain some amount of invalid data will be copied to other erase blocks in order to allow the erase blocks to eventually be erased completely. Accordingly, when storage regions associated with one or more data units become subject to garbage collection, relocation, reclamation, overwrite, or erase operations, the storage system may reapply fault protection to remaining portions of fault protection groups prior to erasing the storage regions (e.g., according to the particular operation applied to the storage regions). These techniques allow the storage system to maintain a desired level of reliability while reducing overhead associated with immediate redundancy generation. In some embodiments, fault protection coverage may be partial or non-uniform over time, such that different subsets of data units are protected at different times, while maintaining an overall target reliability level for the storage system.

In some embodiments, a second set of techniques extends these concepts to zone-based storage architectures by introducing protected zone sets and separate parity zones. In such embodiments, data is written to a plurality of zones defined within one or more storage devices. Because zones may remain open for extended periods of time, generating parity data within a zone at the time of writing may be impractical. Instead, the storage system may identify zones that have been closed to further writing (e.g., indicated as “full”) and group a set of full zones into a protected zone set. This parity can be used to recover from read errors or other latent errors in flash memory that is protected by parity, and can be further used to recover most data in the event of a complete storage device failure, while still relying on the large-scale storage platform to recover whatever non-parity-protected data remains from writes that were received and written but which had not yet been parity protected by the time of the storage device failure.

Parity data may then be generated based on the data stored in the zones of the protected zone set and written into a parity zone that is separate from the zones in the protected zone set, such as on another storage device or another flash die of the same storage device. In this manner, redundancy is decoupled from the writing of individual zones and is instead applied across multiple zones after they have been completed. When one or more zones of a protected zone are reset, the storage system may regroup remaining zones and newly closed zones into new protected zone sets and generate new parity data for the new set. In some embodiments, this regrouping and generation of new parity data occurs before the erase blocks for the reset zones are erased so that the data of the reset zones can still be utilized for recovery in response to faults in the remaining zones until the remaining zones are re-protected through new protected zone sets. These techniques enable fault protection in zone-based storage systems without requiring excessively large zone sizes or immediate redundancy generation, which might otherwise be the case if zones were internally erasure coded across ten to twenty or more erase blocks from ten to twenty or more flash die or flash-based storage devices.

In some embodiments, a third set of techniques further enhances fault protection by introducing multi-dimensional parity relationships across zones and within zones. In such embodiments, data units are written across a plurality of zones in a storage system, and parity data is generated along multiple dimensions corresponding to different groupings of the data units. For example, first parity data may be generated in a first dimension across multiple zones, while second parity data may be generated in a second dimension within individual zones based on groupings of data units within the zones.

Each dimension may correspond to a different failure domain. For example, parity generated across zones may protect against failures affecting entire zones, or individual flash die, or storage devices, or blades, while parity generated within zones may protect against localized errors within a zone, such as errors affecting specific storage units or regions of storage media, such as individual flash pages or word lines or flash memory planes. By organizing data units into multiple groupings and generating parity data for each grouping, the storage system can provide protection against a wider range of failure scenarios, including combinations of device-level failures and localized errors. For example, if there are latent, not yet detected, localized failures within a zone that is part of a protected zone set that is distributed across storage devices and there is a failure of an entire storage device, then protection within a zone can still be used to recover that localized failure within the zone even though the failed other entire storage device cannot be used to recover from that localized failure. In some embodiments, parity is generated within a zone such as by calculating parity across blocks, pages, word lines, planes, or other data groupings to be stored in a small number of additional such groupings within the erase blocks of a zone without also generating parity across zones through protected zone sets.

In some embodiments, parity generated within a zone and parity generated across multiple zones may be implemented independently or in combination. For example, a storage system may generate parity data within individual zones without generating parity data across zones. In other embodiments, parity data may be generated across multiple zones without generating parity data within individual zones. In further embodiments, both techniques may be used together, such that parity generated across zones provides protection for one failure domain while parity generated within zones provides protection for a different failure domain. Accordingly, the use of multiple parity dimensions is one example implementation and should not be interpreted as requiring both intra-zone parity and cross-zone parity in all embodiments.

In some embodiments, the storage systems described herein may operate as storage nodes within a larger distributed storage platform that applies redundancy across multiple storage nodes, such as through erasure coding across shards distributed among different storage nodes. In such embodiments, loss or corruption of data within an individual storage node may be recoverable using higher-level redundancy mechanisms implemented by the larger distributed storage platform. However, reconstruction of data using cross-storage-node redundancy may consume significant network bandwidth, computational resources, and storage system resources. Accordingly, the fault protection techniques described herein, including delayed fault protection, protected zone sets, and multi-dimensional parity relationships, may reduce a frequency with which higher-level reconstruction operations are performed by providing localized protection within a storage node while maintaining storage efficiency, or may reduce the total storage and network bandwidth required to recover lost data, as the amount of lost data can be limited only to relatively recently written data which is typically a very tiny percentage of all stored data.

In addition, in some embodiments, storage systems may utilize shared overflow erase blocks to accommodate variations in zone sizes or to maintain a target zone size. When data associated with a zone exceeds a capacity of the zone, a portion of the data may be stored in one or more overflow erase blocks that are shared among multiple zones. This allows zones to maintain a relatively uniform logical size while providing flexibility in physical storage allocation. The overflow erase blocks may be managed in conjunction with the multi-dimensional parity schemes to ensure that data stored in overflow locations remains protected.

Collectively, these techniques provide a flexible and efficient approach to fault protection in large-scale storage systems. By delaying redundancy generation, decoupling parity from individual write operations, grouping zones into protected sets, and applying multi-dimensional parity across different failure domains, the storage system can achieve high levels of reliability while reducing overhead and accommodating the structural constraints of modern storage architectures.

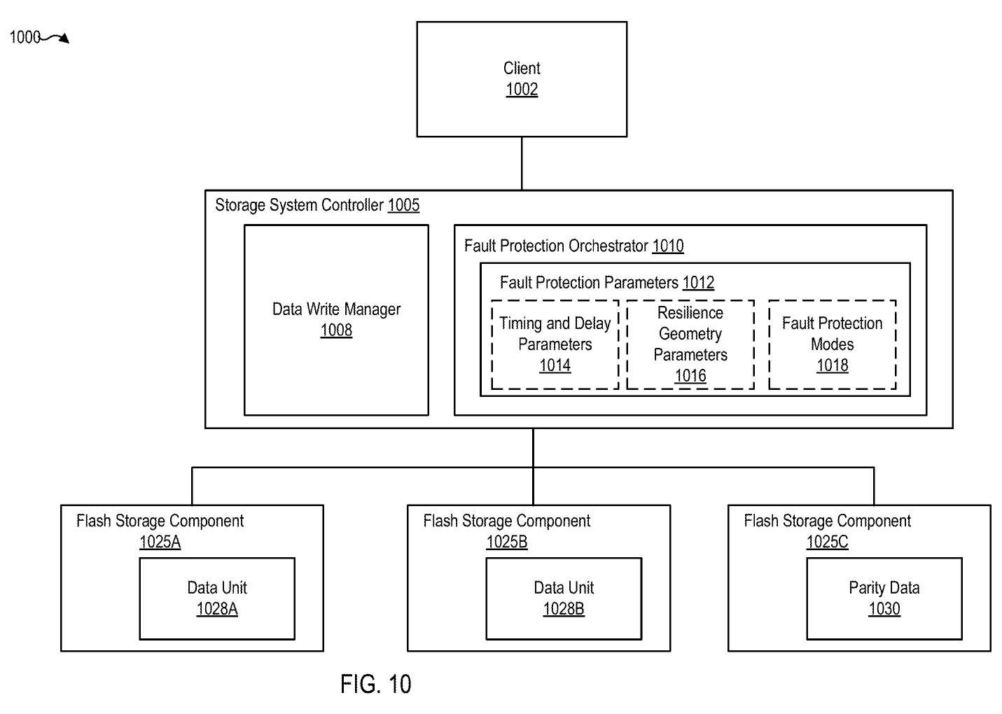

FIG. 10 is a block diagram illustrating a storage system 1000 to perform fault protection operations described herein, including delayed fault protection, protected zone set formation, and multi-dimensional parity generation according to embodiments described herein. The storage system 1000 may include a client 1002 and a storage system controller 1005 coupled to one or more flash storage components 1025A-C. In some embodiments, the storage system controller 1005 may be implemented as a system-level controller within a storage array, while in other embodiments, the storage system controller 1005 may be implemented as a device-level controller within a storage device. For example, a device-level controller may implement the techniques described herein across erase blocks or flash die of the storage device, rather than across storage devices of a storage system.

The storage system controller 1005 may include a data write manager 1008 to receive data from the client 1002 and to manage placement of data units within the flash storage components 1025A-C. As used herein, a data unit may refer to a unit of data that is stored and processed by the storage system, such as a block, page, segment, chunk, or other data structure. In some embodiments, the data write manager 1008 may determine locations for storing data units across a plurality of zones defined within the flash storage components 1025A-C. In some embodiments, the data write manager 1008 may distribute data units across zones in a manner that facilitates subsequent fault protection operations, such as grouping data units across zones or within zones.

The storage system controller 1005 further includes a fault protection orchestrator 1010 configured to manage generation and application of fault protection data, such as parity data 1030. The fault protection orchestrator 1010 may operate based on a set of fault protection parameters 1012, which may include timing and delay parameters 1014, resilience geometry parameters 1016, and fault protection modes 1018. The timing and delay parameters 1014 may define conditions under which fault protection is delayed or deferred, such as based on elapsed time, accumulation of data units, system workload conditions, or may be based on the filling up of data segments or the filling up of flash memory pages, word lines, or erase blocks possibly combined with thresholds in their durability transitions. The resilience geometry parameters 1016 may define how data units are grouped for fault protection, including grouping across zones, grouping within zones, or grouping across other dimensions corresponding to different failure domains. The fault protection modes 1018 may define different strategies for applying fault protection, such as immediate protection, delayed protection, or opportunistic protection. In some embodiments, fault protection parameters 1012 may be dynamically adjusted during operation based on observed workload characteristics, reliability metrics, or storage system conditions. In some implementations, different data sets of a storage device, storage system, or data node may be handled differently. For example, some data may be fully protected at all times, some data may be provided as general purpose volumes with delayed protection for data units, and some percentage of the storage may be provided as zones with a combination of cross-zone protected zone sets and/or parity protection within zones. Thin provisioning may further be deployed to allow a flexible capacity relationship associated with each provided storage type. It should be obvious that many combinations of these types of data sets are possible.

In operation, the data write manager 1008 may receive data units from the client 1002 and store the data units in the flash storage components 1025A-C, for example as data units 1028A and 1028B. In some embodiments, the storage system 1000 may initially store data units without generating parity data, and the fault protection orchestrator 1010 may subsequently generate parity data 1030 at a later time based on one or more of the fault protection parameters 1012. For example, the fault protection orchestrator 1010 may delay generation of parity data until a threshold amount of data units has been stored, or a threshold amount of time has passed, or until zones containing the data units have been indicated as full and thus closed to further writing.

In some embodiments, the fault protection orchestrator 1010 may group data units into fault protection groups based on one or more grouping strategies. For example, data units stored across multiple zones may be grouped to generate parity data that protects against failures affecting entire zones, erase blocks, flash die, flash chip packages, or storage devices. Additionally, data units within a single zone may be grouped to generate parity data that protects against localized errors within the zone, such as errors affecting flash memory pages or flash memory word lines, or individual planes of a zone that incorporates multiple erase blocks across multiple flash memory planes. By generating parity data across multiple groupings of data units, the storage system 1000 may provide multi-dimensional fault protection that addresses different failure domains, allowing, for example, repair from localized failures without having to read additional data or allowing repair from localized failures as part of recovering from more wide-spread failures.

In some embodiments, the fault protection orchestrator 1010 may further manage regrouping of data units when storage locations associated with one or more data units become subject to garbage collection, relocation, overwrite, reclamation, or erase operations due to storage management operations, such as garbage collection or data relocation. For example, when one or more data units within a fault protection group are deleted but not yet erased, the fault protection orchestrator 1010 may form a new fault protection group from remaining portions of the fault protection group and may generate updated parity data for the new group.

In some embodiments, the storage system 1000 may operate in a zone-based configuration in which the flash storage components 1025A-C are organized into zones that are written sequentially and reset as units. The data write manager 1008 may write data units to zones, and the fault protection orchestrator 1010 may identify zones that have been indicated as full and closed to further writing and group such zones into protected zone sets. Parity data may be generated based on data stored in the zones of a protected zone set and may be stored in a separate parity zone or in another storage location. A zone may be a contiguous range of logical block addresses that is managed as a unit and is written sequentially. Each zone may include a write pointer that identifies a next writable location within the zone. Data may be written to a zone by appending data units at the write pointer, and the write pointer may advance as data is written.

In some embodiments, a zone may transition through a set of states during its lifecycle. For example, a zone may initially be in an empty state and may transition to an open state when data is written to the zone. As data is appended, the zone may eventually transition to a closed or full state when a capacity of the zone is reached or when the zone is otherwise indicated as full. A zone that is indicated as full may no longer accept additional writes and may be available for subsequent operations, such as grouping with other zones for fault protection.

In some embodiments, a zone may be reset, such that data associated with the zone is logically invalidated (e.g., the zone is going to be reused for writing different data) and the write pointer is reset to a beginning of the zone. Resetting a zone may enable reuse of the storage that had been associated with the zone. However, in some embodiments described herein, reuse of the storage that had been associated with a reset zone may be delayed until fault protection operations have been performed for data associated with other zones that were previously protected together with the reset zone.

In some embodiments, the storage system may maintain metadata describing states of zones, including whether a zone is open, closed, indicated as full, or reset. The storage system may further track associations between zones and fault protection groupings, such that zones may be grouped, regrouped, and reassigned to different protection sets over time based on zone state transitions.

In some embodiments, the sequential write characteristics of zones and the lifecycle transitions of zones may constrain when and how fault protection operations are performed. For example, because data is appended sequentially within a zone, fault protection may be applied after zones are indicated as full rather than at a time of writing. These constraints are leveraged by the techniques described herein to improve efficiency and flexibility of fault protection operations. As an alternative, it is also possible for a parity zone to be written as other zones in a protected set are filled in, but writes to the parity zone (or zones) might have to wait on progress in writing the other zones in the protected set, for example once all other zones have been written up to a certain block of the zone, the parity zone (or zones) can be calculated up to that block and written to the parity zone. This still doesn’t provide 100% protection for all written data, but it can reduce the amount of data that would have to be rebuilt from other sources.

In some embodiments, the storage system 1000 may further support overflow storage using shared erase blocks. For example, if a configured zone size is larger than will fit evenly in an integral number of erase blocks on a particular storage device, additional data associated with the zone may be stored in one or more overflow erase blocks that are shared among multiple zones stored on the device. The fault protection orchestrator 1010 may account for data stored in overflow erase blocks when generating parity data to ensure that such data remains protected. This can allow for regularization of zone sizes across multiple storage devices with different erase block sizes, or for an application, such as a large-scale storage platform, to standardize on a zone size that may not match erase block sizes of any particular flash memory for data nodes utilized by the large-scale storage platform.

Thus, the storage system 1000 provides a flexible framework for implementing delayed fault protection, protected zone sets, and multi-dimensional parity schemes. Additional details of these operations are described below with reference to subsequent figures.

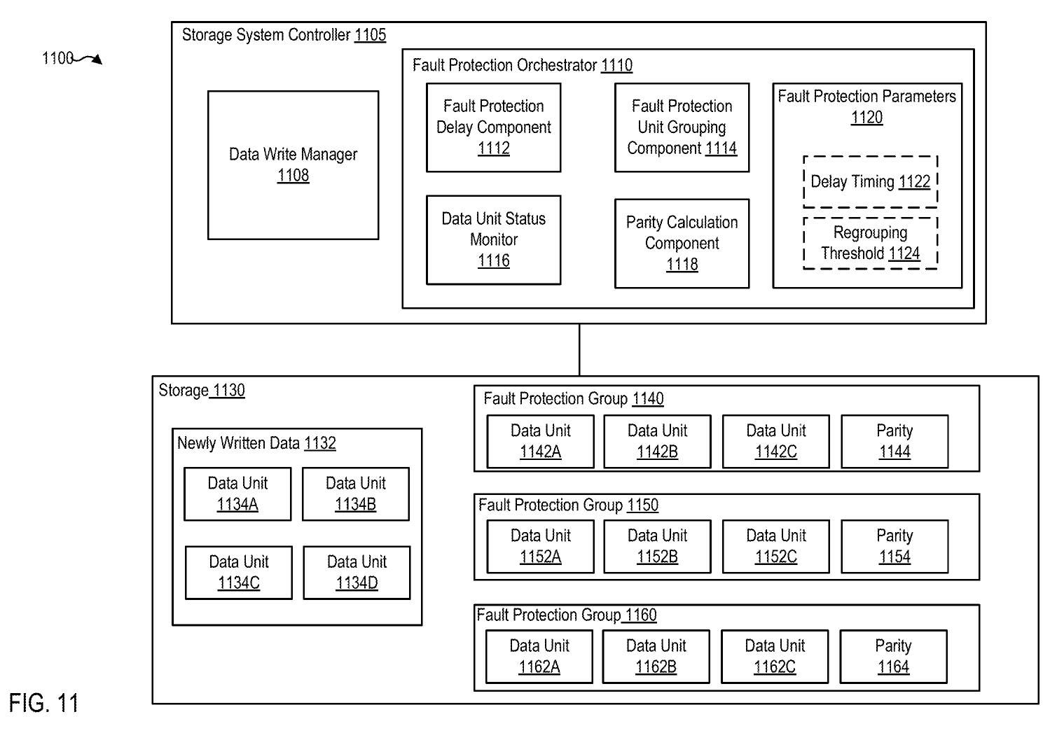

FIG. 11 is a block diagram illustrating a storage system 1100 that provides an overview of delayed fault protection operations in the context of a storage system controller 1105. The storage system controller 1105 may correspond to the storage system controller 1005 described with respect to FIG. 10 and may include a data write manager 1108 and a fault protection orchestrator 1110. The fault protection orchestrator 1110 may include a fault protection delay component 1112, a fault protection unit grouping component 1114, a data unit status monitor 1116, and a parity calculation component 1118.

In some embodiments, the data write manager 1108 may receive newly written data units 1132 and store the data units in a storage 1130. As used herein, a data unit may refer to a unit of data stored by the storage system, such as a sector, block, page, or other unit of storage. The newly written data units 1132 may initially be stored without associated parity data. The fault protection delay component 1112 may determine when fault protection is to be applied to the data units. For example, the fault protection delay component 1112 may delay generation of parity data until a threshold amount of data units has been accumulated, until a period of time has elapsed after writing, or based on other system conditions defined by fault parameters 1120. In some embodiments, the fault protection parameters 1120 may include delay timing 1122 and a regrouping threshold 1124. The delay timing 1122 may specify conditions under which fault protection is delayed, and the regrouping threshold 1124 may specify conditions under which data units are regrouped for fault protection following invalidation events.

The fault protection unit grouping component 1114 may group data units into fault protection groups 1140, 1150, and 1160. Each fault protection group may include a set of data units that are selected for generating parity data. For example, a first fault protection group 1140 may include data units 1142A-C, and parity data 1144 may be generated based on the data units in the first fault protection group 1140. Similarly, a second fault protection group 1150 may include data units 1152A-C with corresponding parity data 1154, and a third fault protection group 1160 may include data units 1162A-C with corresponding parity data 1164. The parity calculation component 1118 may generate the parity data for each fault protection group.

In some embodiments, the data unit status monitor 1116 may monitor whether storage locations (e.g., erase blocks) associated with any data units within a fault protection group are scheduled for erasure or other storage management operation such as to garbage collection, data relocation, or overwrite operations. The regrouping threshold 1124 may define conditions under which data units are regrouped for fault protection. For example, when a number of storage locations associated with data units within a fault protection group become subject to a storage management operation, the remaining data units of the fault protection group may be regrouped into a new fault protection group, and new parity data may be generated before the data units subject to the storage management operation are erased. In this manner, fault protection is applied after data is written and may be updated dynamically as data units become subject to erasure, migration, or overwrite, thereby enabling delayed and opportunistic fault protection.

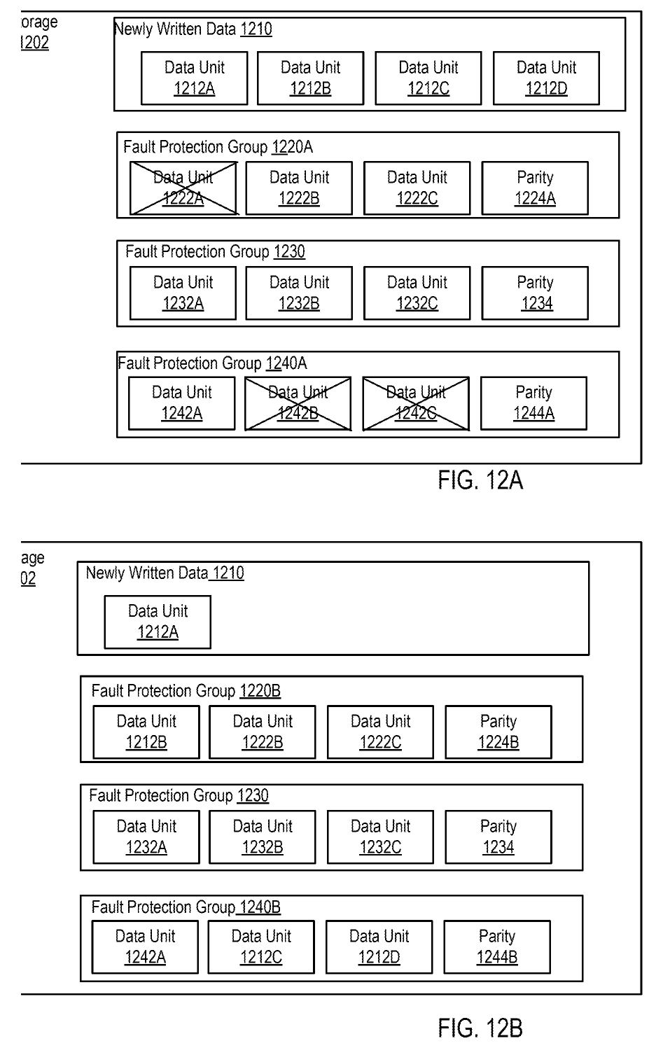

FIG. 12A and 12B are diagrams illustrating detailed examples of delayed fault protection operations within a storage 1202. These figures provide a more granular view of how data units are grouped, protected, and regrouped over time.

Referring to FIG. 12A, the storage 1202 initially stores newly written data units 1210, including data units 1212A, 1212B, 1212C, and 1212D. In some embodiments, the data units 1212A-D are written sequentially or according to a placement policy determined by the data write manager, and are stored without associated parity data at the time of writing. This initial state represents a period during which the data units are temporarily unprotected or protected by other mechanisms outside of the delayed parity scheme (for example, data in partially written erase blocks might also be stored in mirrored or erasure coded NVRAM).

Over time, the storage system forms fault protection groups from available data units. For example, a first fault protection group 1220A includes data units 1222A, 1222B, and 1222C, and parity data 1224A is generated for the group. Similarly, a second fault protection group 1230 includes data units 1232A, 1232B, and 1232C, with parity data 1234, and a third fault protection group 1240A includes data units 1242A, 1242B, and 1242C, with parity data 1244A. In some embodiments, the data units included in these fault protection groups may have been written at different times and may not be contiguous in physical storage. In some embodiments, data units grouped for fault protection do not correspond to write order or physical contiguity, and may be selected independently based on grouping criteria.

In some embodiments, the grouping of data units into fault protection groups may be performed based on one or more criteria, such as age of the data units, physical location of the data units, expected reliability of the storage media, or a desire to distribute data units across independent failure domains. For example, data units stored in different regions of a storage device or across different storage devices may be grouped together to improve fault tolerance. Additionally, the storage system may select data units for grouping in a manner that maximizes independence between data units within a fault protection group. This selection of data units may account for device groupings within a storage system, such as write groups, which can restrict erasure coded groups to avoid excessive combinations of storage device or storage enclosure interdependencies.

The delayed formation of fault protection groups allows the storage system to accumulate a larger pool of data units from which to select group members. This can enable more efficient grouping, reduce the number of parity write operations, and allow grouping decisions to take into account system state and reliability characteristics. In some embodiments, multiple fault protection groups may be formed concurrently, and parity data for different groups may be generated in parallel.

Referring to FIG. 12B, the storage system is shown after one or more data units within the existing fault protection groups have become regrouped into new fault protection groups. For example, certain data units stored in locations that were subject to a storage management operation such as garbage collection, data relocation, or overwrite operations may cause regrouping of data units into different fault protection groups to maintain valid parity data.

In response to a storage maintenance operation being scheduled for a storage region associated with one or more data units of a fault protection group, the storage system may form new fault protection groups that include remaining portions of the fault protection group stored outside the storage region and, in some embodiments, newly written data units. For example, if a first erase block storing a first portion of a fault protection group is scheduled for garbage collection or reclamation, the storage system may generate second fault protection for remaining portions of the fault protection group stored in one or more other erase blocks. For example, a new fault protection group 1220B may include data units 1212B, 1222B, and 1222C, and parity data 1224B is generated for the new group. Similarly, a new fault protection group 1240B may include data units 1242A, 1212C, and 1212D, and parity data 1244B is generated for that group. In this manner, remaining valid data units are regrouped to restore fault protection coverage.

In some embodiments, the regrouping process may occur prior to erasing or reclaiming the storage region associated with the scheduled maintenance operation, allowing existing fault protection relationships to remain valid until second fault protection has been generated for remaining portions of the fault protection group. For example, data stored in an erase block scheduled for garbage collection may continue to participate in reconstruction operations until the erase block is actually erased or reused. This allows fault protection to be maintained for older data while new fault protection groups are formed.

In some embodiments, regrouping may be performed opportunistically and may not occur immediately upon invalidation of a data unit. For example, the storage system may allow a certain number of data units to remain unprotected or less protected for a period of time, based on a target reliability level. The regrouping threshold may define when regrouping is triggered, such as when a number of data units subject to a storage management operation (e.g., garbage collection, erasure, etc.) within a group exceeds a threshold or when a sufficient number of new data units are available to form new groups.

Additionally, in some embodiments, regrouping may incorporate data units from multiple prior fault protection groups as well as newly written data units. This allows the storage system to continuously reorganize fault protection groups over time, maintaining protection while minimizing write amplification. The grouping and regrouping operations may be performed by the fault protection orchestrator using scheduling policies that consider system load, available resources, and desired reliability targets.

Accordingly, FIGS. 12A and 12B illustrate a delayed fault protection approach in which data units are initially written without immediate parity, grouped into fault protection groups after a delay, and dynamically regrouped as data units become subject to impending erasure due to a data storage operation. This approach allows the storage system to balance performance, write efficiency, and reliability by applying fault protection in a flexible and adaptive manner.

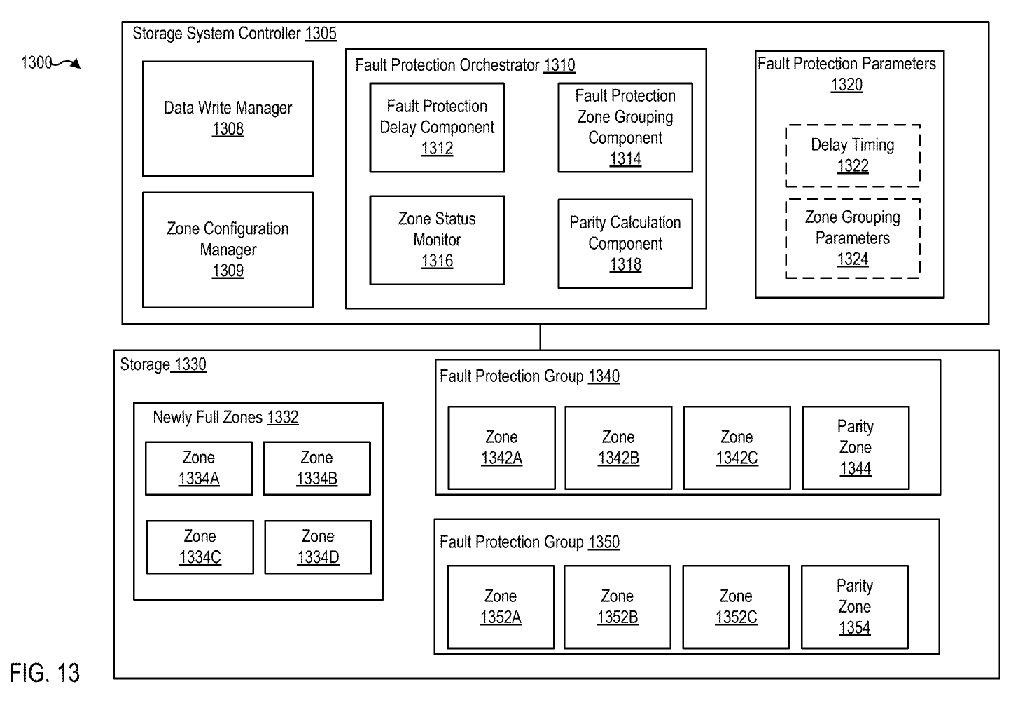

FIG. 13 is a block diagram illustrating a storage system 1300 for fault protection operations in a zone-based storage architecture, according to embodiments described herein. The storage system 1300 may include a storage system controller 1305 that corresponds to the storage system controller 1005 described with respect to FIG. 10. The storage system controller 1305 may include a data write manager 1308 and a fault protection orchestrator 1310. The fault protection orchestrator 1310 may include a fault protection delay component 1312, a fault protection zone grouping component 1314, a zone status monitor 1316, a parity calculation component 1318, and a zone configuration manager 1309.

In some embodiments, the data write manager 1308 may write data units to a plurality of zones within a storage 1330. Each zone may be written sequentially using a write pointer, and zones may be transitioned from an open state to a state in which the zone is indicated as full when a capacity of the zone is reached or when a finish operation is performed. Zones indicated as full may no longer accept additional writes and may be eligible for grouping into protected zone sets.

The fault protection delay component 1312 may delay generation of parity data based on fault parameters 1320. For example, the fault protection delay component 1312 may delay generation of parity data until zones are indicated as full and a sufficient number of zones are available for grouping. In some embodiments, delaying fault protection in this manner allows the storage system to accumulate zones that can be grouped across independent failure domains and reduces write amplification associated with immediate parity generation. For example, in some embodiments, the fault protection parameters 1320 may include delay timing 1322 and zone grouping parameters 1324. The delay timing 1322 may define when zones indicated as full are eligible for grouping, and the zone grouping parameters 1324 may define criteria for selecting zones to form protected zone sets. Newly full zones 1332 may represent zones that have transitioned to a full state and are candidates for inclusion in protected zone sets.

The fault protection zone grouping component 1314 may identify zones indicated as full, such as zones included in newly full zones 1332, and may group the zones into protected zone sets, such as fault protection groups 1340 and 1350. Each protected zone set may include a plurality of zones (e.g., zones 1342A-C of fault protection group 1340 and zones 1352A-C of fault protection group 1350) selected based on criteria such as time at which the zones were indicated as full, physical location of the zones within storage devices, or distribution of the zones across different storage devices or other failure domains. In some embodiments, zones and physical storage have a dynamic relationship. For example, a non-empty zone may be a logical address that is mapped to an erase block. The mapping may be a logical mapping and may be established when a zone is being written based on wear leveling, fault isolation, or any other rules an SSD may implement for flash management. In some embodiments, over time a zone, including an active or full zone, may be moved to a new physical erase block due to, for example, flash maintenance operations. As an example, QLC flash often needs to be rewritten every 60 days, which would result in a zone being migrated to new erase blocks. In other examples, a zone may be migrated as a result of a scrub identifying degraded but still recoverable blocks. In some examples, known flash issues, such as read disturb, may result in an erase block being flagged for a rewrite as a precautionary measure.

The parity calculation component 1318 may generate parity data based on data stored in zones of a protected zone set. The generated parity data may be written to a parity zone, such as parity zones 1344 and 1354, that is separate from the zones of the protected zone set. In some embodiments, storing parity data in a separate parity zone allows the storage system to decouple parity generation from the sequential write constraints of data zones.

The zone status monitor 1316 may detect when one or more zones of a protected zone set have been reset. A reset zone may be a zone that has been transitioned to an empty state such that data previously stored in the zone is logically invalidated and the zone may be reused. In response to a zone being reset, the storage system may delay erasure and reuse of the reset zone until remaining active zones of the protected zone set are assigned to a new protected zone set and protected through the new protected zone set.

In some embodiments, the new protected zone set may include remaining active zones from the prior protected zone set as well as zones that are newly indicated as full. The storage system may generate second parity data for the new protected zone set and store the second parity data in a new parity zone. By delaying reuse of reset zones until reassignment and reprotection of remaining zones is complete, the storage system maintains continuous fault protection coverage.

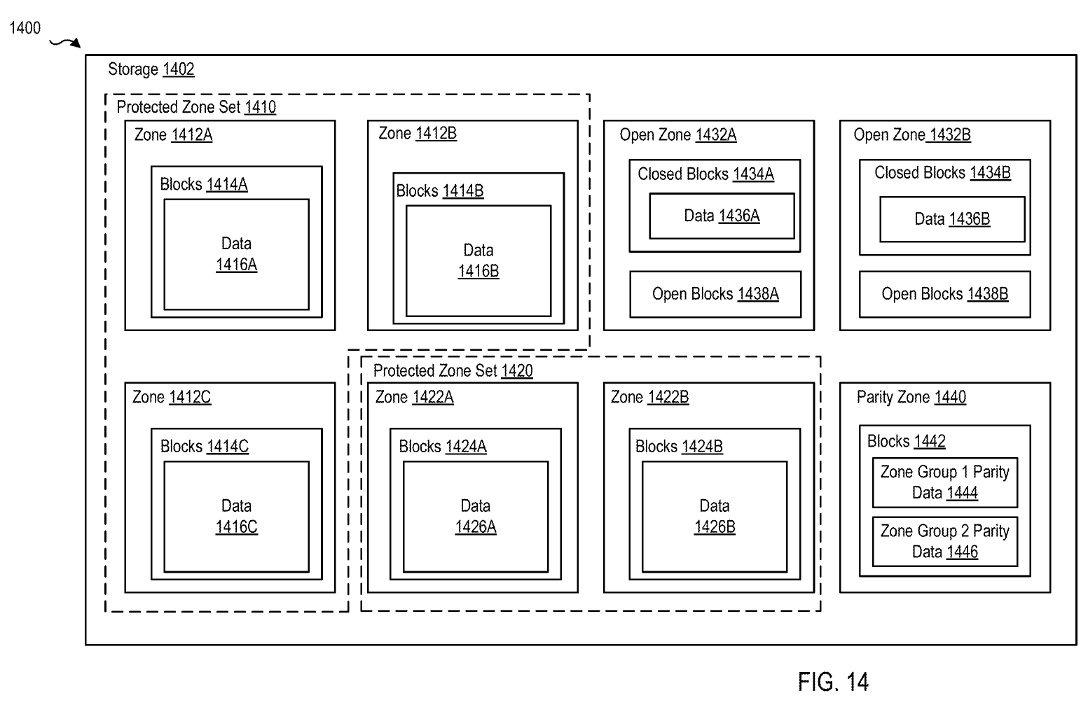

FIG. 14 is a diagram illustrating detailed examples of zone-based fault protection operations within a storage 1402. As depicted in FIG. 14, zones may be grouped into protected sets (e.g., zone groups) upon reaching a full status. Zones may be in varying states of their lifecycle, including zones that are indicated as full, zones that remain open for writing, and zones that have been reset.

Referring to FIG. 14, zones 1412A-C may represent zones that have been written and are indicated as full. Each of these zones may include blocks 1414A-C containing data 1416A-C that was written sequentially into the zone, such as by using a write pointer. Open zones 1432A and 1432B may represent zones that are not yet indicated as full and may include open blocks 1438A and 1438B that continue to receive data. In some embodiments, protected zone sets 1410 and 1420 represent groupings of zones indicated as full. Parity data 1444 and 1446 may be generated for the protected zone sets and stored in a parity zone 1440. Closed blocks 1434A and 1434B may represent portions of zones that are no longer being written, while open blocks 1438A and 1438B may represent portions of zones that are still receiving data.

In some embodiments, zones indicated as full are grouped for parity formation. For example, the storage system 1400 depicts a protected zone set 1410 created by grouping zones 1412A-C. The storage system may then generate parity data for the protected zone set (e.g., parity data 1444 for protected zone set 1410) and may store the parity data in a parity zone (e.g., parity zone 1440) that is separate from the zones of the group. The parity data 1444 may be used to reconstruct data stored in any one of the zones of the protected zone set 1410 in the event of a failure. Similarly, another protected zone set 1420 may be formed from zones 1422A and 1422B, and parity data 1446 may be generated for that group. In some embodiments, zone groups may be formed dynamically as zones are indicated as full, and grouping decisions may consider distribution across storage devices or other criteria to improve reliability.

In some embodiments, a zone of a protected zone set may be reset, resulting in invalidation of data within that zone. For example, a zone that was previously part of protected zone set 1410 may be reset and transitioned to an empty state. In response, the storage system may not immediately reuse the reset zone for new data. Instead, the storage system may identify remaining active zones from the prior zone group and may form a new zone group by combining those remaining zones with zones that are newly indicated as full.

In some embodiments, the storage system may generate new parity data for the new zone group prior to allowing reuse of the reset zone. This ensures that all active zones are associated with a protected zone set and that fault protection is maintained continuously. Only after reassignment and reprotection of remaining zones may the reset zone be reused for new data, thus providing continuous fault protection to the remaining zones.

In some embodiments, zones may be selected for grouping based on their location within different storage devices or based on other characteristics, such as wear level or reliability. Additionally, zones may be grouped across different times at which they were indicated as full, allowing the storage system to balance protection across older and newer data.

Accordingly, FIGS. 13 and 14 illustrate zone-based fault protection techniques in which zones are written sequentially, indicated as full upon reaching capacity, grouped into protected zone sets after being indicated as full, and protected using parity zones. These techniques further include delaying reuse of reset zones until reassignment and reprotection of remaining zones is complete, thereby maintaining continuous fault protection while accommodating the lifecycle constraints of zone-based storage systems.

It should be noted that in some embodiments, parity generated for protected zone sets, as described with respect to FIG. 14, may be used independently of parity generated within zones. In other embodiments, parity generated for protected zone sets may be combined with parity generated within individual zones to provide protection across multiple failure domains.

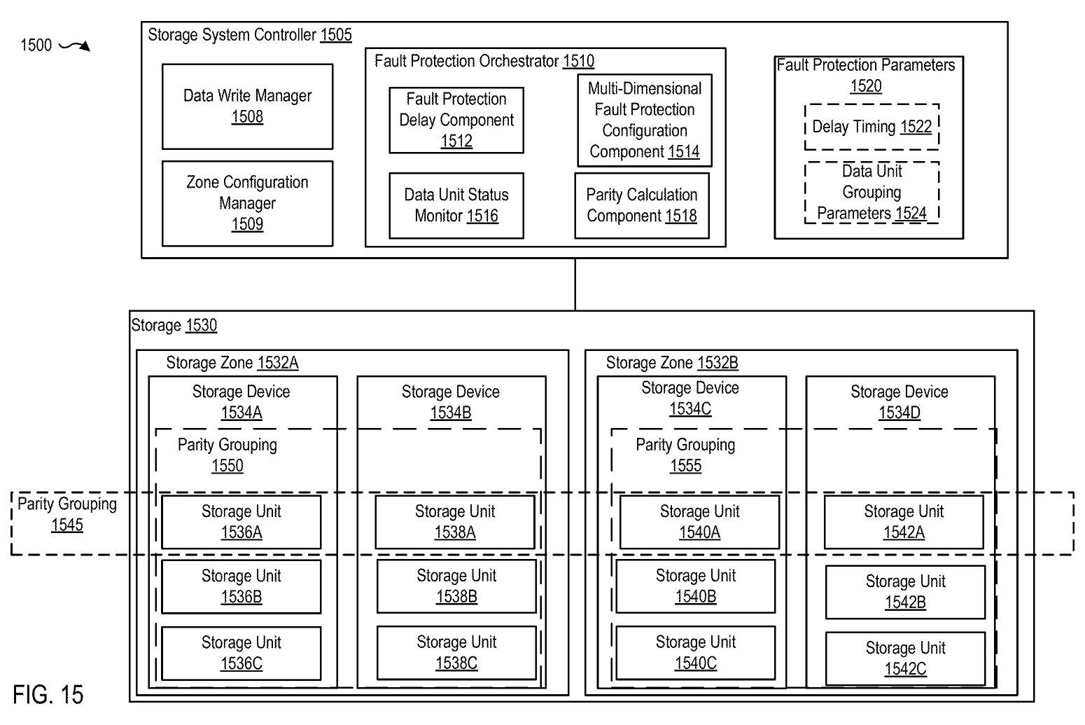

FIG. 15 is a block diagram illustrating a storage system 1500 for providing multi-dimensional fault protection using parity relationships defined across multiple groupings of data units in a zone-based storage architecture, according to embodiments described herein. The storage system 1500 may include a storage system controller 1505 that corresponds to the storage system controller 1005 described with respect to FIG. 10, and may include a data write manager 1508 and a fault protection orchestrator 1510. The fault protection orchestrator 1510 may include a fault protection delay component 1512, a multi-dimensional fault protection configuration component 1514, a data unit status monitor 1516, a parity calculation component 1518, and a zone configuration manager 1509.

In some embodiments, the storage system 1500 includes a storage 1530 organized into a plurality of storage zones, such as storage zones 1532A and 1532B. Each storage zone may include data stored across one or more storage devices, such as storage devices 1534A-D. Each storage device may include a plurality of storage units, such as storage units 1536A-C, 1538A-C, 1540A-C, and 1542A-C. As used herein, a storage unit may refer to a granularity of storage corresponding to a physical or logical unit, such as a flash memory page, a group of cells corresponding to an error correction code (ECC) block, or another unit of storage that may be independently written or read. In some embodiments, each storage device may include any number of storage units, and the illustrated groupings are provided for purposes of explanation.

In some embodiments, the data write manager 1508 may write data units across the plurality of zones 1532A-1532B and across the storage devices 1534A-1534D. The placement of data units may be configured such that data units are distributed across different storage devices and different regions of storage, thereby enabling fault protection across multiple failure domains. In some embodiments, the fault protection parameters 1520 may include delay timing 1522 and data unit grouping parameters 1524. The delay timing 1522 may define when parity is generated across one or more dimensions, and the data unit grouping parameters 1524 may define how data units are grouped into parity groupings across zones, within zones, or across storage units.

The multi-dimensional fault protection configuration component 1514 may define multiple groupings of data units along different dimensions. In some embodiments, a first dimension may correspond to a grouping of data units across a plurality of zones and across storage devices. For example, a first parity grouping 1545 may include data units drawn from multiple storage devices 1534A-1534D and from one or more zones, such that parity data generated for the first parity grouping 1545 provides protection against failures affecting an entire storage device or an entire zone.

In some embodiments, a second dimension may correspond to a grouping of data units within a zone. For example, a second parity grouping 1550 may include data units that are located within a single zone, such as storage zone 1532A, but distributed across multiple storage units within the zone. In some embodiments, the storage units within a zone may correspond to flash memory pages organized along word lines or planes. For example, a set of storage units that share similar physical characteristics or that are associated with a particular plane of a flash device may be grouped together for parity calculation. Parity data generated for the second parity grouping 1550 may provide protection against localized failures within a zone, such as failures affecting a subset of storage units within a storage device.

In some embodiments, a third dimension may also be defined. For example, a third parity grouping 1555 may include data units that span multiple zones and multiple storage devices but are grouped based on a different criterion, such as temporal ordering of writes, physical proximity within a flash device, or reliability characteristics of the storage units. In some embodiments, this third dimension may correspond to grouping data units across layers of storage or across sets of storage units that share similar wear characteristics or error rates.

In some embodiments, the parity calculation component 1518 may generate parity data for each of the parity groupings 1545, 1550, and 1555. Each data unit may be included in multiple parity groupings corresponding to different dimensions. For example, a data unit stored in storage unit 1538A may be included in a first parity grouping that spans storage devices, a second parity grouping within a zone, and a third parity grouping based on another dimension. By participating in multiple parity groupings, each data unit may be protected by multiple independent parity relationships. In some embodiments, different dimensions include different sets of data units such that a given data unit participates in different parity groupings across the different dimensions. In some embodiments, only one of the parity dimensions described herein is implemented, while in other embodiments two or more parity dimensions are implemented concurrently.

In some embodiments, the different dimensions of parity may correspond to different failure domains. For example, parity generated across storage devices may protect against device-level failures, while parity generated within a zone may protect against localized failures within a storage device, such as corruption of a flash memory page or a group of cells. Additional parity dimensions may protect against other types of failures, such as correlated errors across nearby storage units or degradation over time.

In some embodiments, parity data may be stored in various locations depending on the dimension. For example, parity data for groupings within a zone may be stored at the end of the zone, appended after the data units in the zone. In other embodiments, parity data for groupings across zones may be stored in separate zones or in dedicated parity storage regions. In some embodiments, parity data may be temporarily accumulated in a non-volatile random access memory (NVRAM) buffer and written to long-term storage after data units have been written.

In some embodiments, parity generation may be delayed and performed after zones have been closed or after sufficient data units have been accumulated. For example, parity data for a grouping within a zone may be generated after the zone is closed to writing, allowing all data units within the zone to be included in the grouping. Similarly, parity data for groupings across zones may be generated after a set of zones has been closed, enabling grouping of data units across zones without interfering with ongoing write operations.

In some embodiments, the stripe status monitor 1516 may detect when data units within one or more parity groupings become logically invalidated, such as due to zone reset or data relocation. When a data unit within a parity grouping is invalidated, the parity data associated with that grouping may no longer provide complete protection. In response, the storage system may form new parity groupings that include remaining valid data units and may generate new parity data for those groupings. In some embodiments, new parity groupings may include data units from multiple prior groupings as well as newly written data units.

In some embodiments, the multi-dimensional parity approach may be extended to use multiple parity units per grouping, enabling recovery from multiple failures within a grouping. For example, a grouping may include both a first parity unit and a second parity unit, allowing recovery from two simultaneous failures within the grouping. In some embodiments, the number of parity units and the structure of the parity calculations may be selected based on desired reliability and performance characteristics.

In some embodiments, the grouping of data units for each dimension may be selected to maximize independence between data units within a grouping. For example, data units may be selected from different physical regions of a flash device, different planes, or different storage devices to reduce the likelihood that multiple data units within the same grouping will fail simultaneously. Additionally, grouping may take into account known reliability characteristics of storage media, such as increased error rates in frequently accessed regions or in regions that have undergone many program and erase cycles.

In some embodiments, multi-dimensional parity may be used in conjunction with zone-based storage management to provide efficient and flexible fault protection. By decoupling parity generation from the write path and by grouping data units along multiple dimensions, the storage system 1500 may provide protection against a wide range of failure scenarios while minimizing write amplification and preserving storage efficiency.

Accordingly, FIG. 15 illustrates a storage system in which data units are organized into multiple parity groupings across different dimensions, including groupings across zones, within zones, and across other criteria. By generating parity data for each grouping, the storage system can provide multi-dimensional fault protection that addresses device-level failures, localized errors, and other failure modes in large-scale storage systems.

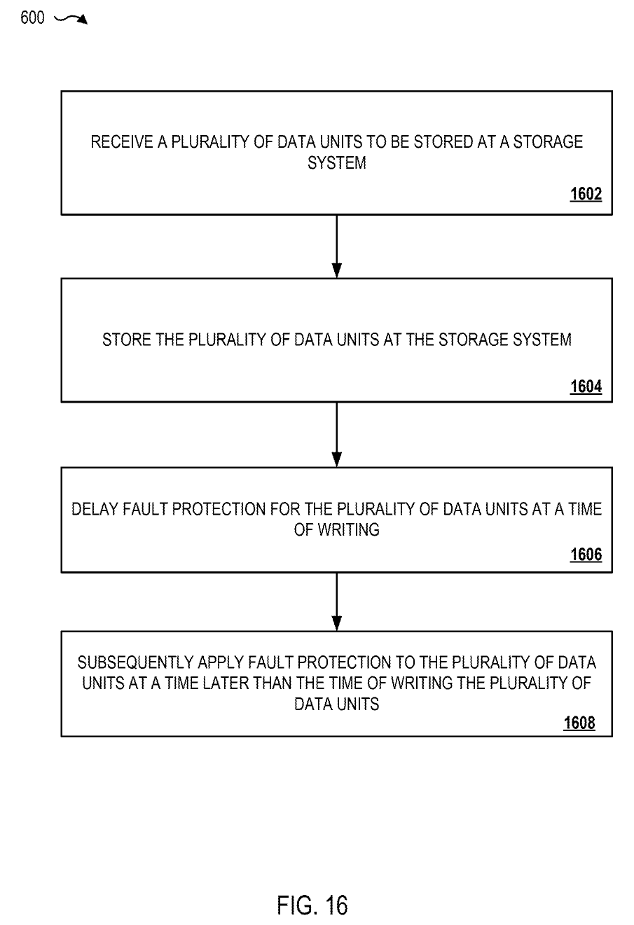

FIG. 16 is a flow diagram illustrating a method 1600 of performing delayed fault protection in a storage system. The method 1600 may be performed by processing logic that comprises hardware, software, or a combination thereof. In some embodiments, the method 1600 may be performed by a storage system controller, such as the storage system controller 1005, 1105, or 1305 described with respect to FIGS. 10-13.

At block 1602, processing logic receives a plurality of data units to be stored at a storage system. Receiving the plurality of data units may include accepting write requests from a client and buffering or otherwise preparing the data units for storage. In some embodiments, the plurality of data units may correspond to a plurality of data units, where each data unit represents a block, page, or other unit of data to be stored. The data units may be received sequentially or concurrently and may be associated with metadata that indicates logical addresses, physical placement preferences, or other attributes relevant to storage management.

In some embodiments, receiving the plurality of data units may include distributing the data units across multiple internal queues, buffers, or data structures maintained by the storage system controller. For example, the data write manager may organize incoming data units into queues based on priority, logical address ranges, or physical placement strategies. In some embodiments, receiving the plurality of data units may include preprocessing operations such as compression, deduplication, or encryption prior to storage.

At block 1604, processing logic stores the plurality of data units at the storage system. Storing the plurality of data units may include writing the data units to one or more storage devices, such as flash storage components, within the storage system. In some embodiments, storing the plurality of data units may include writing the data units to corresponding erase blocks of flash storage, where each erase block represents a unit of storage that can be erased and rewritten as a whole.

In some embodiments, storing the plurality of data units may include placing the data units into zones or other logical groupings of storage. For example, the storage system may organize storage into zones that are written sequentially, and the data units may be appended to zones according to a write pointer. In some embodiments, the data units may be distributed across multiple storage devices or multiple regions within a storage device to improve performance and fault tolerance.

In some embodiments, storing the plurality of data units may be performed without immediately generating fault protection data. For example, the data units may be written to storage without computing parity or other redundancy information at the time of writing. This allows the storage system to reduce write amplification and defer fault protection operations to a later time.

At block 1606, processing logic delays fault protection for the plurality of data units at a time of writing. Delaying fault protection may include deferring the generation and storage of redundancy units, such as parity data, until one or more conditions are satisfied. In some embodiments, delaying fault protection may include determining that fault protection is to be postponed until a threshold amount of data has been received by the storage system. For example, the storage system may wait until a sufficient number of data units or data units has been accumulated to form one or more fault protection groups.

In some embodiments, delaying fault protection may include deferring redundancy generation until an elapsed time since the time of writing has passed. For example, the storage system may delay fault protection operations for a predetermined period or until system resources are available. In some embodiments, delaying fault protection may include deferring redundancy generation based on an expected time at which storage regions associated with the data units become subject to garbage collection, relocation, reclamation, overwrite, or erase operations. For example, the storage system may predict when certain data units are likely to be erased or relocated due to a storage maintenance operation and may schedule fault protection operations accordingly.

In some embodiments, delaying fault protection may include maintaining metadata that tracks which data units have not yet been protected and scheduling future operations to apply fault protection. In some embodiments, delaying fault protection may be performed in a manner that allows a subset of data units to remain temporarily unprotected while ensuring that a desired level of overall system reliability is maintained.

At block 1608, processing logic subsequently applies fault protection to the plurality of data units at a time later than the time of writing the plurality of data units. Applying fault protection may include generating one or more redundancy units based on a subset of the plurality of data units and storing the redundancy units in the storage system. For example, the storage system may form one or more fault protection groups from stored data units and compute parity data for each group.

In some embodiments, generating redundancy units may include selecting data units from different storage devices, different zones, or different regions of storage to maximize independence between data units within a fault protection group. The redundancy units may include parity data generated using exclusive-or (XOR) operations, more complex erasure coding techniques, or other redundancy schemes. In some embodiments, multiple redundancy units may be generated for a fault protection group to enable recovery from multiple failures.

In some embodiments, applying fault protection may include storing the generated redundancy units in one or more storage locations, such as dedicated parity regions, parity zones, or separate storage devices. In some embodiments, redundancy units may be temporarily stored in non-volatile random access memory (NVRAM) before being written to long-term storage after successful completion of data writes.

In some embodiments, applying fault protection may include detecting that one or more data units have become subject to a storage management operation, such as garbage collection, data relocation, or overwrite of at least one data unit. In response to such detection, processing logic may reapply fault protection to at least a subset of the plurality of data units that are not subject to erasure. For example, the storage system may form new fault protection groups from remaining valid data units and generate new redundancy units for those groups.

In some embodiments, reapplying fault protection may be performed prior to erasing the one or more data units that have become subject to erasure (e.g., due to a storage maintenance operation, erasure, deletion, etc.), allowing the storage system to use the contents of the data that has become subject to erase but not yet erased to maintain redundancy and parity until generating new redundancy units. This can reduce the need for additional read operations or reconstruction from higher-level redundancy mechanisms.

In some embodiments, applying fault protection may be performed asynchronously with respect to write operations. For example, the storage system may perform fault protection operations in the background while continuing to service incoming write requests. In some embodiments, fault protection operations may be scheduled based on system load, resource availability, or priority of data units.

Accordingly, the method 1600 illustrated in FIG. 16 provides a flexible approach to fault protection in which redundancy generation is delayed and applied after data is written. This approach allows the storage system to balance performance and reliability by reducing write overhead while maintaining protection for stored data.

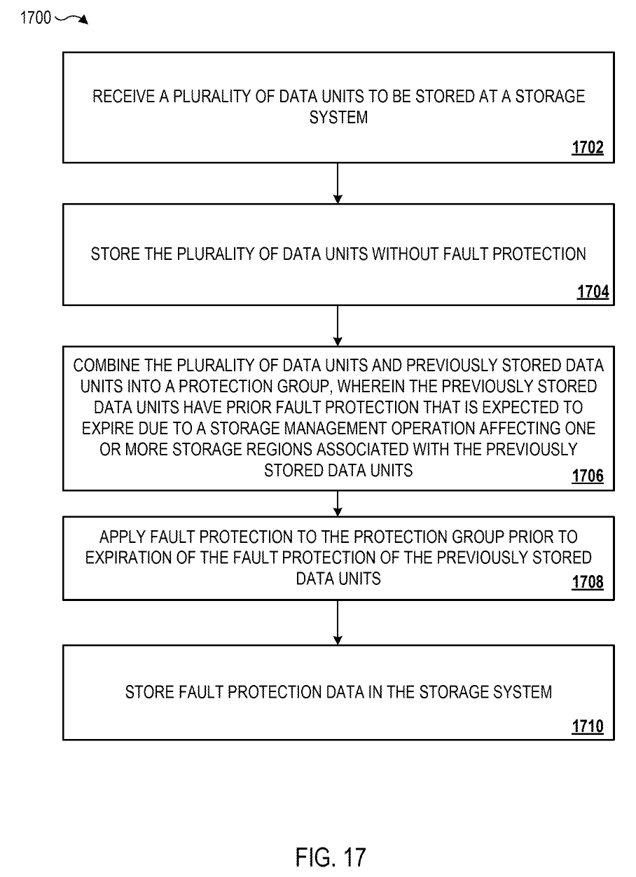

FIG. 17 is a flow diagram illustrating a method 1700 of performing delayed fault protection with regrouping of data units in response to invalidation and anticipated expiration of fault protection. The method 1700 may be performed by processing logic that comprises hardware, software, or a combination thereof. In some embodiments, the method 1700 may be performed by a storage system controller, such as the storage system controller 405, 505, or 705 described with respect to FIGS. 4-7.

At block 1702, processing logic receives a plurality of data units to be stored at a storage system. Receiving the plurality of data units may include accepting write requests from a client and preparing the data units for storage. In some embodiments, the plurality of data units may correspond to a plurality of data units, where each data unit represents a block, page, or other unit of storage. The data units may be associated with metadata that identifies logical addresses, physical placement, or grouping preferences. In some embodiments, receiving the plurality of data units may include distributing the data units across buffers, queues, or other data structures for subsequent storage and fault protection operations.

At block 1704, processing logic stores the plurality of data units without fault protection. Storing the plurality of data units without fault protection may include writing the data units to storage media, such as flash storage devices, without generating parity data or other redundancy at the time of writing. In some embodiments, the data units may be written to corresponding erase blocks or to zones that are written sequentially. By storing the data units without immediate fault protection, the storage system may reduce write amplification and defer redundancy operations until a later time when more efficient grouping may be performed.

In some embodiments, storing the plurality of data units without fault protection may include organizing the data units across multiple storage devices or storage regions to facilitate later grouping. For example, the data write manager may distribute data units across different zones or across different storage devices to improve the independence of data units that may later be grouped for fault protection.

At block 1706, processing logic combines the plurality of data units and previously stored data units into a protection group, wherein the previously stored data units have prior fault protection that is expected to expire due to a storage maintenance operation affecting one or more storage regions associated with the previously stored data units. Combining the plurality of data units and previously stored data units into a protection group may include selecting data units from different sources and forming a new grouping for which fault protection will be generated.

In some embodiments, the previously stored data units may be part of an existing fault protection group for which parity data has already been generated. However, if one or more storage locations (e.g., erase blocks) storing data units of the existing group have become scheduled for garbage collection, relocation, overwrite, reclamation, or erase, the effectiveness of the existing parity data may be reduced or eliminated. The storage system may determine that the prior fault protection is expected to expire, for example because the number of invalidated data units (e.g., data units that have been deleted or marked for deletion) within the group exceeds a threshold or because a storage management operation is scheduled to erase one or more data units in the group.

In some embodiments, combining the plurality of data units and previously stored data units may include selecting data units that remain valid from prior groups and combining them with newly written data units that have not yet been protected. This allows the storage system to reuse valid data units from existing groups while incorporating new data units into updated fault protection groups.

In some embodiments, the selection of data units for the new protection group may be based on criteria such as physical location, age of the data units, expected reliability of the storage media, or independence of failure domains. For example, data units from different storage devices or different zones may be selected to reduce the likelihood of correlated failures within the protection group.

At block 1708, processing logic applies fault protection to the protection group prior to expiration of the fault protection of the previously stored data units. Applying fault protection to the protection group may include generating redundancy units, such as parity data, based on the data units in the protection group. The redundancy units may be generated using techniques such as exclusive-or (XOR) operations or other erasure coding methods.

In some embodiments, applying fault protection prior to expiration may include scheduling parity generation before the data stored in the storage regions associated with the data units is erased. In some embodiments, applying fault protection may include generating second fault protection for remaining portions of a fault protection group prior to performing a data maintenance operation on a storage region associated with another portion of the fault protection group. For example, if a first erase block storing a first portion of a fault protection group is scheduled for garbage collection, relocation, overwrite, reclamation, wear leveling, or erase operations, the storage system may generate second fault protection for remaining portions of the fault protection group stored in one or more other erase blocks prior to performing the data maintenance operation on the first erase block. In some embodiments, this allows the storage system to maintain fault protection continuity for surviving portions of the fault protection group while reducing reliance on higher-level reconstruction mechanisms.

In some embodiments, applying fault protection may include generating multiple redundancy units for the protection group to provide protection against multiple failures. In some embodiments, the redundancy units may be temporarily stored in non-volatile random access memory (NVRAM) and later written to long-term storage after data writes have been successfully completed.

In some embodiments, applying fault protection may be performed asynchronously with respect to write operations. For example, the storage system may perform parity calculations in the background while continuing to accept new write requests. The timing of fault protection operations may be controlled based on system load, resource availability, or desired reliability levels.

At block 1710, processing logic stores fault protection data in the storage system. Storing fault protection data may include writing the generated redundancy units to one or more storage locations, such as dedicated parity regions, parity zones, or separate storage devices. In some embodiments, the fault protection data may be stored in a manner that is physically separated from the data units in the protection group to improve fault tolerance.

In some embodiments, storing fault protection data may include updating metadata that associates the redundancy units with the data units in the protection group. This metadata may be used to reconstruct data units in the event of data loss or corruption. In some embodiments, the storage system may maintain multiple versions of fault protection data over time as protection groups are updated and regrouped.

In some embodiments, the storage system may repeat the operations of combining, applying fault protection, and storing fault protection data as additional data units are written and as existing data units become associated with storage regions subject to storage management operations. This allows the storage system to continuously maintain fault protection coverage for stored data while adapting to changes in the data set.

Accordingly, the method 1700 illustrated in FIG. 17 provides a detailed example of delayed fault protection with regrouping, in which data units are initially stored without redundancy, combined with previously stored data units into protection groups, and protected prior to expiration of existing fault protection. This approach enables efficient and adaptive fault protection that maintains data reliability while reducing overhead associated with immediate redundancy generation.

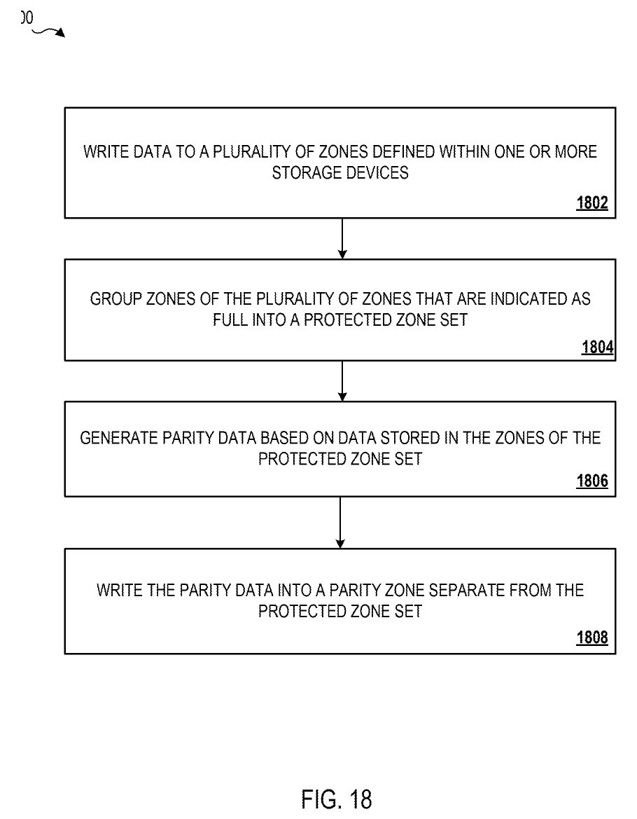

FIG. 18 is a flow diagram illustrating a method 1800 of performing fault protection in a zone-based storage system using protected zone sets and separate parity zones. The method 1800 may be performed by processing logic that comprises hardware, software, or a combination thereof. In some embodiments, the method 1800 may be performed by a storage system controller, such as the storage system controller 705 described with respect to FIG. 7.

At block 1802, processing logic writes data to a plurality of zones defined within one or more storage devices. Writing data to the plurality of zones may include receiving data units from a client and appending the data units sequentially to zones in accordance with a zone-based write model. As used herein, a zone may refer to a region of storage that is written sequentially and that is reset as a unit. Each zone may include one or more erase blocks or other storage units, and a write pointer may advance through the zone as data is written.

In some embodiments, writing data to the plurality of zones may include selecting zones based on availability, wear characteristics, or load balancing considerations. For example, the storage system may distribute data across zones located on different storage devices or across different regions of a storage device. In some embodiments, writing data to zones may be performed without generating parity data at the time of writing, allowing the storage system to defer fault protection operations.

In some embodiments, zones may be maintained in an open state while data is being written. An open zone may accept additional data until a closure condition is satisfied. A zone may be closed when it reaches a capacity limit, when a write pointer reaches an end of the zone, or based on a system-level decision, such as when the storage system determines that the zone should be finalized for subsequent fault protection operations.

At block 1804, processing logic groups zones of the plurality of zones that have been indicated as full into a protected zone set. Grouping zones that have been indicated as full and thus closed to writing may include identifying zones that are no longer accepting writes and selecting a subset of such zones to form a protected zone set. The grouping may be performed by a zone grouping component that uses zone grouping parameters to determine which zones to include in the protected zone set.

In some embodiments, grouping zones may include selecting zones based on time of closure, such that zones that were closed within a similar time window are grouped together. In some embodiments, grouping zones may include selecting zones based on physical location, such as ensuring that zones reside on different storage devices or in different regions of storage to improve independence of failure domains. In some embodiments, grouping zones may include selecting zones based on the number of closed zones available, such that a protected zone set is formed when a sufficient number of closed zones have been accumulated.

In some embodiments, zones may remain ungrouped and unprotected for a period of time after closure, depending on system conditions and desired fault protection policies. This delay may allow the storage system to accumulate a larger set of closed zones from which to select zones for grouping, thereby improving efficiency and flexibility in forming protected zone sets.

At block 1806, processing logic generates parity data based on data stored in the zones of the protected zone set. Generating parity data may include reading data from the zones in the protected zone set and computing one or more redundancy units, such as parity units, based on the data. In some embodiments, the parity data may be generated using exclusive-or (XOR) operations or more complex erasure coding techniques.

In some embodiments, generating parity data may include selecting data units from corresponding positions within each zone, such as corresponding pages or blocks, to form parity stripes across zones. In some embodiments, multiple parity units may be generated to provide protection against multiple failures within the protected zone set. In some embodiments, parity generation may be performed after all zones in the protected zone set have been closed, allowing the storage system to include all data in the zones in the parity calculation.

In some embodiments, generating parity data may be performed asynchronously with respect to write operations. For example, the storage system may perform parity calculations in the background while continuing to accept new write requests. The timing of parity generation may be controlled based on system load, resource availability, or delay parameters.

At block 1808, processing logic writes the parity data into a parity zone separate from the protected zone set. Writing the parity data into a parity zone may include selecting a zone that is designated for storing parity data and writing the parity data sequentially to that zone. The parity zone may be distinct from the zones in the protected zone set and may be located on a different storage device or in a different region of storage to improve fault tolerance.

In some embodiments, the parity zone may be managed similarly to data zones, including being written sequentially and later closed. In some embodiments, multiple parity zones may be used to store parity data for different protected zone sets or to provide multiple levels of redundancy. In some embodiments, the storage system may maintain metadata that associates the parity zone with the zones in the protected zone set, allowing reconstruction of data in the event of a failure.

In some embodiments, writing parity data to a separate parity zone decouples the generation of redundancy from the initial write path of data zones. This allows data to be written efficiently to zones without immediate parity generation, while still providing fault protection through subsequent parity operations.

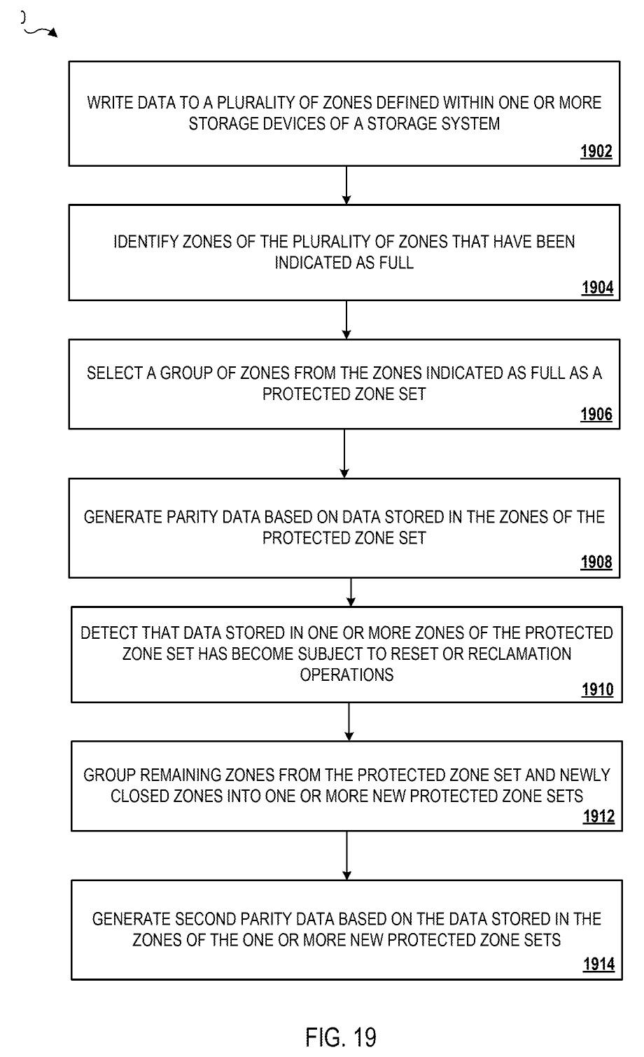

FIG. 19 is a flow diagram illustrating a method 1900 of maintaining fault protection in a zone-based storage system through regrouping of zones and regeneration of parity data in response to reset, reclamation, or reuse operations affecting the zones. The method 1900 may be performed by processing logic that comprises hardware, software, or a combination thereof. In some embodiments, the method 1900 may be performed by a storage system controller, such as the storage system controller 705 described with respect to FIG. 7.

At block 1902, processing logic writes data to a plurality of zones defined within one or more storage devices of a storage system. Writing data to the plurality of zones may be performed in a manner similar to that described with respect to block 1802, including sequentially appending data units to zones and maintaining zones in an open state until closure conditions are satisfied.

At block 1904, processing logic identifies zones of the plurality of zones that have been indicated as full. Identifying closed zones may include examining metadata associated with each zone to determine whether the zone is in a closed state. In some embodiments, the storage system may maintain a list or table of closed zones, which may be updated as zones transition from open to closed states. Closed zones may be eligible for inclusion in protected zone sets.

At block 1906, processing logic selects a group of zones from the zones indicated as full to create a protected zone set. Selecting the group of zones may include applying selection criteria similar to those described with respect to block 1804. For example, the storage system may select zones based on time of closure, physical location, or number of available closed zones. The selected zones may form a protected zone set for which parity data will be generated.

At block 1908, processing logic generates parity data based on data stored in the zones of the protected zone set. Generating parity data may be performed in a manner similar to that described with respect to block 1806, including computing redundancy units based on corresponding data units in the zones of the protected zone set.

At block 1910, processing logic detects that data stored in one or more zones of the protected zone set has become subject to reset or reclamation operations. Detecting data subject to reset or reclamation may include identifying zones that have been reset, zones that contain data that has been overwritten or relocated, or zones that are scheduled for garbage collection. In some embodiments, when a zone is reset, all data in the zone may be logically invalidated, and the parity data associated with the protected zone set may no longer provide valid protection for that zone after the zone is erased or overwritten. However, the parity data does provide protection up until the underlying flash memory of the zone is actually erased, therefore providing time for the other zones of the group to be reassigned to different protected zone sets for protection.

At block 1912, processing logic groups remaining zones from the protected zone set and newly closed zones into a new protected zone set. Grouping remaining zones and newly closed zones may include selecting zones that still contain valid data from the original protected zone set and combining them with zones that have been newly closed. This allows the storage system to form a new protected zone set that replaces the original set and maintains fault protection for the remaining valid data.

In some embodiments, grouping may be performed prior to erasing the invalidated zones, allowing the storage system to use the contents of the zones subject to reset or reclamation operations to maintain the validity of the parity data for the group. In some embodiments, grouping may be delayed until a sufficient number of new zones have been closed or until system conditions warrant regrouping.

At block 1914, processing logic generates second parity data based on the data stored in the zones of the new protected zone set. Generating second parity data may include computing new redundancy units for the new protected zone set and writing the parity data to a new parity zone. In some embodiments, the storage system may generate new parity data before erasing parity data associated with the prior protected zone set, thereby maintaining continuous fault protection.

In some embodiments, the operations of detecting invalidation, grouping zones, and generating new parity data may be performed iteratively as zones are reset and new zones are closed. This allows the storage system to continuously maintain fault protection coverage in a dynamic environment where zones are written, closed, and reset over time.

Accordingly, the methods illustrated in FIGS. 18 and 19 provide detailed examples of zone-based fault protection in which zones are grouped after closure, protected using parity zones, and dynamically regrouped as data within zones becomes subject to reset or reclamation operations. These methods enable efficient and flexible fault protection in zone-based storage systems by decoupling parity generation from the write path and allowing adaptive grouping of zones over time.

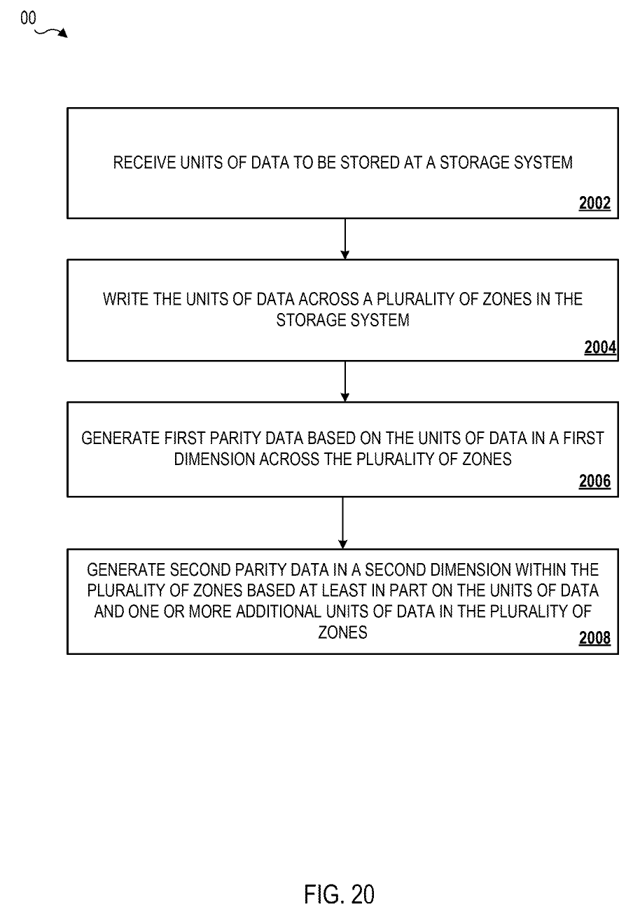

FIG. 20 is a flow diagram illustrating a method 2000 of performing multi-dimensional fault protection in a zone-based storage system. The method 2000 may be performed by processing logic that comprises hardware, software, or a combination thereof. In some embodiments, the method 2000 may be performed by a storage system controller, such as the storage system controller 1505 described with respect to FIG. 15.

At block 2002, processing logic receives units of data to be stored at a storage system. Receiving the units of data may include accepting write requests from a client and preparing the data units for storage. As used herein, a unit of data may refer to a block, page, or other unit of storage that can be written to a storage device. In some embodiments, the units of data may be associated with metadata indicating logical addresses, placement preferences, or grouping attributes.

In some embodiments, receiving the units of data may include distributing the data units across buffers, queues, or other data structures maintained by the storage system controller. For example, the data write manager may organize incoming data units into queues based on scheduling policies, priority levels, or target zones.

At block 2004, processing logic writes the units of data across a plurality of zones in the storage system. Writing the units of data across the plurality of zones may include selecting zones for placement of the data units and writing the data units sequentially within each zone. In some embodiments, the zones may be defined within one or more storage devices and may correspond to regions of storage that are written sequentially and reset as a unit.

In some embodiments, writing the units of data across the plurality of zones may include distributing the data units across different zones and different storage devices to improve performance and fault tolerance. For example, the storage system may place data units in zones that reside on different storage devices to ensure that the data units are distributed across independent failure domains.

At block 2006, processing logic generates first parity data based on the units of data in a first dimension across the plurality of zones. Generating first parity data in the first dimension may include grouping units of data that span two or more zones and computing parity data based on the grouped units. In some embodiments, the first dimension may correspond to grouping units of data across zones such that each group includes units of data from different zones and, in some embodiments, from different storage devices.

In some embodiments, generating first parity data may include selecting units of data from corresponding positions within zones, such as corresponding pages or blocks, to form parity stripes across zones. In some embodiments, the grouping may be selected to maximize independence between units of data within a group, such as by selecting units of data from different storage devices or different regions of storage.

In some embodiments, generating first parity data may include computing parity using exclusive-or (XOR) operations or more complex erasure coding techniques. In some embodiments, multiple parity units may be generated to provide protection against multiple failures within the group.

At block 2008, processing logic generates second parity data in a second dimension within the plurality of zones based at least in part on the units of data and one or more additional units of data in the plurality of zones. Generating second parity data in the second dimension may include grouping units of data within individual zones and computing parity data based on those groupings.

In some embodiments, the second dimension may correspond to grouping units of data within a single zone, such as grouping units of data stored in different storage units or pages within the zone. For example, units of data that share a common physical characteristic, such as being located in the same plane or word line of a flash memory device, may be grouped together for parity calculation.

In some embodiments, the second parity data may be based on the units of data written at block 2004 as well as one or more additional units of data that are stored within the same zones. This allows the storage system to form groupings that include both newly written data and previously stored data within the zones.

In some embodiments, generating second parity data may be performed after zones have been closed to writing, allowing all units of data within a zone to be included in the grouping. In other embodiments, second parity data may be generated incrementally as data is written within a zone.

In some embodiments, the first dimension and the second dimension correspond to different failure domains. For example, the first dimension may protect against failures affecting entire zones or storage devices, while the second dimension may protect against localized failures within a zone, such as corruption of individual storage units. By generating parity data in multiple dimensions, the storage system can provide protection against a wider range of failure scenarios.

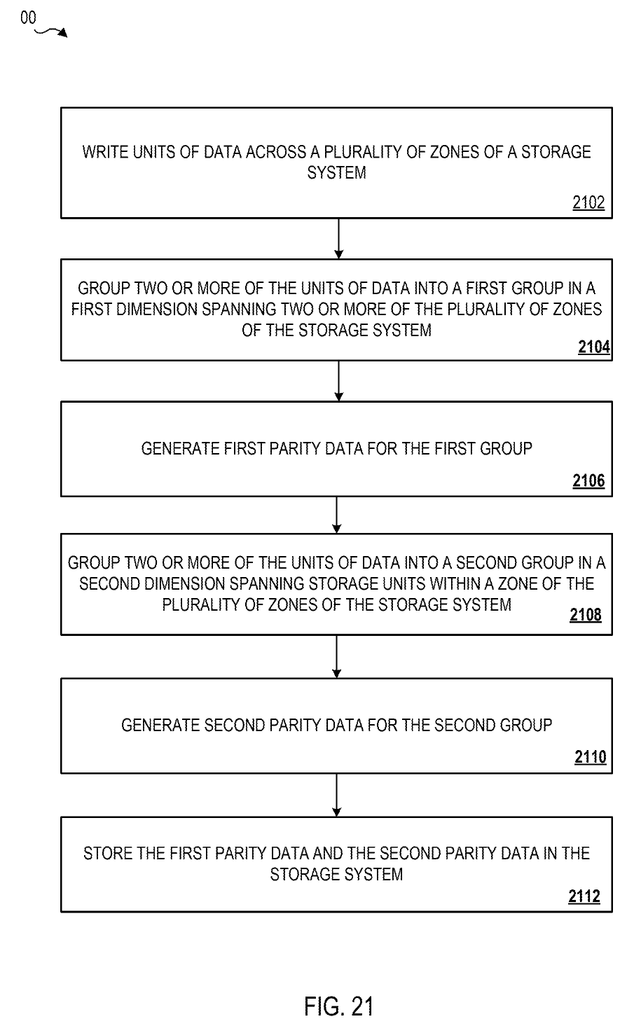

FIG. 21 is a flow diagram illustrating a method 2100 of grouping units of data into multiple groups corresponding to different dimensions and generating parity data for each group. The method 2100 provides a more detailed view of how multi-dimensional parity groupings are formed and used.

At block 2102, processing logic writes units of data across a plurality of zones of a storage system. Writing the units of data may be performed in a manner similar to that described with respect to block 2004, including distributing units of data across zones and storage devices.

At block 2104, processing logic groups two or more of the units of data into a first group in a first dimension spanning two or more of the plurality of zones of the storage system. Grouping units of data into the first group may include selecting units of data from different zones and, in some embodiments, from different storage devices, to form a grouping that spans multiple zones.

In some embodiments, the first group may correspond to a parity stripe that includes units of data from multiple zones. The grouping may be selected based on criteria such as physical location, timing of writes, or desired distribution across failure domains. For example, units of data from zones located on different storage devices may be grouped together to improve fault tolerance.

At block 2106, processing logic generates first parity data for the first group. Generating first parity data may include computing redundancy units based on the units of data in the first group using parity operations such as XOR or other erasure coding techniques. In some embodiments, the parity data may be stored in a location that is separate from the zones containing the units of data in the first group.

At block 2108, processing logic groups two or more of the units of data into a second group in a second dimension spanning storage units within a zone of the plurality of zones of the storage system. Grouping units of data into the second group may include selecting units of data that reside within a single zone and grouping them based on their location within the zone.

In some embodiments, the second group may include units of data that are located in different storage units, such as different pages or blocks, within the same zone. For example, units of data that correspond to the same word line across different planes of a flash memory device may be grouped together. In some embodiments, the grouping may be based on physical characteristics of the storage media, such as grouping units of data that are likely to experience similar error patterns.

At block 2110, processing logic generates second parity data for the second group. Generating second parity data may include computing redundancy units based on the units of data in the second group. In some embodiments, the second parity data may be stored within the same zone as the units of data in the second group, such as at the end of the zone after all data units have been written.

At block 2112, processing logic stores the first parity data and the second parity data in the storage system. Storing the parity data may include writing the first parity data and the second parity data to appropriate storage locations, such as separate parity zones for the first parity data and end-of-zone storage for the second parity data. In some embodiments, the storage system may maintain metadata that associates the parity data with the corresponding groups of data units.

In some embodiments, each unit of data may be included in both the first group and the second group, thereby participating in multiple parity calculations corresponding to different dimensions. This allows the storage system to provide multiple layers of fault protection for each unit of data.

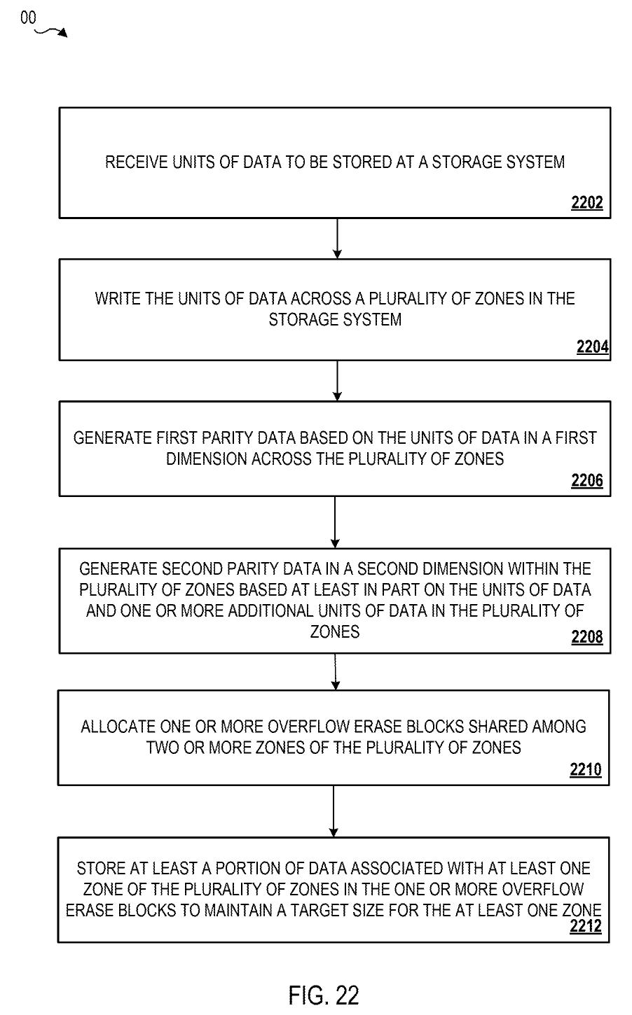

FIG. 22 is a flow diagram illustrating a method 2200 of performing multi-dimensional fault protection with support for overflow storage in a zone-based storage system. The method 2200 extends the operations described with respect to FIG. 20 by incorporating overflow erase blocks for storing data associated with zones.

At block 2202, processing logic receives units of data to be stored at a storage system. Receiving the units of data may be performed in a manner similar to that described with respect to block 2002.

At block 2204, processing logic writes the units of data across a plurality of zones in the storage system. Writing the units of data may be performed in a manner similar to that described with respect to block 2004.

At block 2206, processing logic generates first parity data based on the units of data in a first dimension across the plurality of zones. Generating first parity data may be performed in a manner similar to that described with respect to block 2006.

At block 2208, processing logic generates second parity data in a second dimension within the plurality of zones based at least in part on the units of data and one or more additional units of data in the plurality of zones. Generating second parity data may be performed in a manner similar to that described with respect to block 2008.

At block 2210, processing logic allocates one or more overflow erase blocks shared among two or more zones of the plurality of zones. Allocating overflow erase blocks may include selecting one or more erase blocks that are not dedicated to a single zone and designating them for use by multiple zones. In some embodiments, the overflow erase blocks may be located within one or more storage devices and may be managed as a shared resource.

In some embodiments, allocating overflow erase blocks may include maintaining metadata that identifies which zones are associated with each overflow erase block. The storage system may track available capacity within each overflow erase block and may allocate portions of the block to different zones as needed.

At block 2212, processing logic stores at least a portion of data associated with at least one zone of the plurality of zones in the one or more overflow erase blocks to maintain a target size for the at least one zone. Storing data in the overflow erase blocks may include writing data that exceeds the capacity of a zone to the overflow erase blocks. For example, if a zone reaches a capacity limit but additional data is associated with the zone, the storage system may store the additional data in an overflow erase block.

In some embodiments, storing data in overflow erase blocks may allow the storage system to maintain a uniform logical size for zones while accommodating variations in physical storage capacity. In some embodiments, data stored in overflow erase blocks may be included in parity calculations for both the first dimension and the second dimension, ensuring that the overflow data is protected.

In some embodiments, the storage system may manage overflow erase blocks in conjunction with zone lifecycle operations, such as zone closure and reset. For example, when a zone is reset, the storage system may also update or reclaim portions of overflow erase blocks associated with the zone.

Accordingly, FIGS. 20-22 illustrate multi-dimensional fault protection techniques in which data units are grouped across multiple dimensions and protected using parity data, and in which overflow erase blocks are used to manage data that exceeds zone capacity while maintaining fault protection.

In the figures, reference numerals that include alphabetical suffixes (e.g., 1534A-1534D, 1536A-1536C) are used to distinguish among multiple instances of similar elements and are not intended to limit the number of such elements. Any number of such elements may be present in various embodiments.

Advantages and features of the present disclosure can be further described by the following statements:
1. A method includes storing data at a storage system; delaying fault protection for the data at a time of writing; and subsequently applying fault protection to the data at a time later than the time of writing the data.
2. The method of statement 1, where the fault protection is delayed until a threshold amount of data has been received by the storage system or a threshold amount of time has elapsed since writing.
3. The method of either statement 1 or 2, wherein subsequently applying fault protection comprises: generating one or more redundancy units calculated from a subset of the data; and storing the one or more redundancy units in the storage system.
4. The method of any one of statements 1-3, further comprising: detecting that a first erase block storing a first portion of the data of a first fault protection group is scheduled for a storage management operation; and applying, prior to performing the storage management operation on the first erase block, second fault protection to a second portion of the data of the first fault protection group stored in one or more erase blocks other than the first erase block.
5. The method any one of statements 1-4, wherein the at least one storage management operation results in at least a portion of the data being selected for deletion and comprises at least one of garbage collection, data relocation, or overwrite of at least one data unit.
6. The method of any one of statements 1-5, wherein portions of the data are stored in corresponding erase blocks of flash storage, and wherein selecting the portion of the data for deletion comprises marking erase blocks containing the portion of data for garbage collection to allow for storing different data at the erase blocks.
7. The method of any one of statements 1-6, wherein the applying of fault protection to the data is delayed until at least one of: an elapsed time since the time of writing, accumulation of a number of data segments, or based on an expected time at which storage regions associated with the data become subject to a storage management operation.
8. A storage system comprising: one or more storage devices; and one or more processing devices configured to perform any one of statements 1-7.
9. A non-transitory computer readable storage medium having instructions stored thereon that, when executed by a process device, cause the processing device to perform any one of statements 1-7.
10. A method includes: receiving data to be written to a plurality of zones defined within one or more storage devices; grouping zones of the plurality of zones indicated as full into a protected zone set; generating parity data based on data stored in the zones of the protected zone set; and adding a parity zone to the protected zone set and writing the parity data into the parity zone.
11. The method of statement 10, wherein grouping zones of the plurality of zones indicated as full comprises: identifying zones of the plurality of zones indicated as full; and selecting a group of zones from the zones indicated as full based on at least one of time of closure, physical location of the zones indicated as full, or the number of zones indicated as full.
12. The method of either of statements 10 or 11, wherein the parity data is generated subsequent to the indication that the zones of the plurality zones are full.
13. The method of any one of statements 10-12, further comprising: in response to at least one zone of a protected zone set being reset, delaying erasure and reuse of reset zones until each remaining active zone of the protected set is assigned to a new protected zone set and protected through the new protected zone set.
14. The method of any one of statements 10-13, wherein the new protected zone set comprises active zones of other protected sets or zones that are newly indicated as full to create the new protected zone set.
15. The method of any one of statements 10-14, further comprising: calculating second parity data based on data stored in the zones of the new protected zone set; and adding a second parity zone to the new protected zone set separate from the rest of the new protected zone set and writing the parity data into a the second parity zone of the new protected zone set.
16. The method of any one of statements 10-15, wherein the regrouping the remaining closed zones from the protected zone set is performed prior to erasing the at least one zone of the protected zone set being reset.
17. A storage system comprising: one or more storage devices; and one or more processing devices configured to perform any one of statements 10-16.
18. A non-transitory computer readable storage medium having instructions stored thereon that, when executed by a process device, cause the processing device to perform any one of statements 10-16.
19. A method includes: receiving units of data to be stored at a storage system; writing the units of data across a plurality of zones in the storage system; generating first parity data based on the units of data in a first dimension across the plurality of zones; and generating second parity data in a second dimension within the plurality of zones based at least in part on the units of data and one or more additional units of data in the plurality of zones.
20. The method of statement 19, wherein generating the second parity data within the plurality of zones comprises grouping the units of data with other units of data within corresponding zones of the plurality of zones.
21. The method of either statement 19 or 20, further comprising: storing the second parity data at an end of a same zone of the plurality of zones as the units of data on which the second parity data is based.
22. The method of any one of statements 19-21, further comprising: storing the first parity data in non-volatile random access memory (NVRAM); and in response to successfully writing the units of data across the plurality of zones of the storage system, writing the first parity data to long term storage.
23. The method of any one of statements 19-22, wherein the first parity data and the second parity data are based on physically independent failure domains of the storage system.
24. The method of any one of statements 19-23, further comprising: storing the second parity data in a separate zone from the units of data on which the second parity data is based.
25. The method of any one of statements 19-24, further comprising: allocating one or more overflow erase blocks shared among two or more zones of the plurality of zones; and storing at least a portion of data associated with at least one zone of the plurality of zones in the one or more overflow erase blocks to maintain a target size for the at least one zone.

One or more embodiments may be described herein with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality.

To the extent used, the flow diagram block boundaries and sequence could have been defined otherwise and still perform the certain significant functionality. Such alternate definitions of both functional building blocks and flow diagram blocks and sequences are thus within the scope and spirit of the claims. One of average skill in the art will also recognize that the functional building blocks, and other illustrative blocks, modules and components herein, can be implemented as illustrated or by discrete components, application specific integrated circuits, processors executing appropriate software and the like or any combination thereof.

While particular combinations of various functions and features of the one or more embodiments are expressly described herein, other combinations of these features and functions are likewise possible. The present disclosure is not limited by the particular examples disclosed herein and expressly incorporates these other combinations.

What is claimed is:

1. A method comprising:
receiving units of data to be stored at a storage system;
writing the units of data across a plurality of zones in the storage system;
generating first parity data based on the units of data in a first dimension across the plurality of zones; and
generating second parity data in a second dimension within the plurality of zones based at least in part on the units of data and one or more additional units of data in the plurality of zones.

2. The method of claim 1, wherein generating the second parity data within the plurality of zones comprises grouping the units of data with other units of data within corresponding zones of the plurality of zones.

3. The method of claim 1, further comprising:
storing the second parity data at an end of a same zone of the plurality of zones as the units of data on which the second parity data is based.

4. The method of claim 1, further comprising:
storing the first parity data in non-volatile random access memory (NVRAM); and
in response to successfully writing the units of data across the plurality of zones of the storage system, writing the first parity data to long term storage.

5. The method of claim 1, wherein the first parity data and the second parity data are based on physically independent failure domains of the storage system.

6. The method of claim 1, further comprising:
storing the second parity data in a separate zone from the units of data on which the second parity data is based.

7. The method of claim 1, further comprising:
allocating one or more overflow erase blocks shared among two or more zones of the plurality of zones; and
storing at least a portion of data associated with at least one zone of the plurality of zones in the one or more overflow erase blocks to maintain a target size for the at least one zone.

8. A storage system comprising:
one or more storage devices; and
a processing device operatively coupled to the one or more storage devices, the one or more processing devices configured to:
receive units of data to be stored at the storage system;
write the units of data across a plurality of zones in the storage system;
generate first parity data based on the units of data in a first dimension across the plurality of zones; and
generate second parity data in a second dimension within the plurality of zones based at least in part on the units of data and one or more additional units of data in the plurality of zones.

9. The storage system of claim 8, wherein to generate the second parity data within the plurality of zones the processing device is configured to group the units of data with other units of data within corresponding zones of the plurality of zones.

10. The storage system of claim 8, wherein the processing device is further configured to:
store the second parity data at an end of a same zone of the plurality of zones as the units of data on which the second parity data is based.

11. The storage system of claim 8, wherein the processing device is further configured to:
store the first parity data in non-volatile random access memory (NVRAM); and
in response to successfully writing the units of data across the plurality of zones of the storage system, write the first parity data to long term storage.

12. The storage system of claim 8, wherein the first parity data and the second parity data are based on physically independent failure domains of the storage system.

13. The storage system of claim 8, wherein the processing device is further configured to:
store the second parity data in a separate zone from the units of data on which the second parity data is based.

14. The storage system of claim 8, wherein the processing device is further configured to:
allocate one or more overflow erase blocks shared among two or more zones of the plurality of zones; and
store at least a portion of data associated with at least one zone of the plurality of zones in the one or more overflow erase blocks to maintain a target size for the at least one zone.

15. A non-transitory computer readable storage medium having instructions stored thereon that, when executed by a processing device, cause the processing device to:
receive units of data to be stored at the storage system;
write the units of data across a plurality of zones in the storage system;
generate first parity data based on the units of data in a first dimension across the plurality of zones; and
generate second parity data in a second dimension within the plurality of zones based at least in part on the units of data and one or more additional units of data in the plurality of zones.

16. The non-transitory computer readable storage medium of claim 15, wherein to generate the second parity data within the plurality of zones the processing device is configured to group the units of data with other units of data within corresponding zones of the plurality of zones.

17. The non-transitory computer readable storage medium of claim 15, wherein the processing device is further configured to:
store the second parity data at an end of a same zone of the plurality of zones as the units of data on which the second parity data is based.

18. The non-transitory computer readable storage medium of claim 15, wherein the processing device is further configured to:
store the first parity data in non-volatile random access memory (NVRAM); and
in response to successfully writing the units of data across the plurality of zones of the storage system, write the first parity data to long term storage.

19. The non-transitory computer readable storage medium of claim 15, wherein the first parity data and the second parity data are based on physically independent failure domains of the storage system.

20. The non-transitory computer readable storage medium of claim 15, wherein the processing device is further configured to:
store the second parity data in a separate zone from the units of data on which the second parity data is based.
